(19) United States
(12) Patent Application Publication
(10) Pub. No.: US 2026/0075945 A1
(43) Pub. Date: Mar. 12, 2026

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Kenichi OKAZAKI, Atsugi (JP); Masataka NAKADA, Tochigi (JP); Yoshiaki OIKAWA, Atsugi (JP); Kensuke YOSHIZUMI, Atsugi (JP)

(21) Appl. No.: 19/133,268

(22) PCT Filed: Nov. 30, 2023
(86) PCT No.: PCT/IB2023/062041

§ 371 Date: May 28, 2025

(30) Foreign Application Priority Data
Dec. 7, 2022 (JP) 2022-195942
Dec. 9, 2022 (JP) 2022-197420
Jan. 20, 2023 (JP) 2023-007442

(51) Int. Cl. H10D 86/40; H10D 30/67; H10D 86/60

(52) U.S. Cl. CPC H10D 86/451; H10D 30/6731; H10D 30/6757; H10D 86/431; H10D 86/60

(57) ABSTRACT

A semiconductor device with a small occupation area is provided. The semiconductor device includes a first insulating layer, a second insulating layer, and a transistor. The transistor is provided over the first insulating layer and includes a semiconductor layer, a gate insulating layer, a gate electrode, a source electrode, and a drain electrode. The second insulating layer includes an opening reaching the first insulating layer. The source electrode and the drain electrode are provided over the second insulating layer. The semiconductor layer is provided in contact with a side surface of the second insulating layer in the opening, a top surface of the first insulating layer in the opening, and side surfaces of the source electrode and the drain electrode. The gate insulating layer is positioned over the semiconductor layer, the source electrode, and the drain electrode. The gate electrode overlaps with the opening and is positioned over the gate insulating layer.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display apparatus including a semiconductor device.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), driving methods of them, and manufacturing methods of them.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display apparatus, a light-emitting apparatus, a lighting device, and an electronic device themselves are semiconductor devices and each of them includes a semiconductor device in some cases.

### BACKGROUND ART

Semiconductor devices that include transistors are applied to a wide range of electronic devices. Uses for a display apparatus are diversified in recent years, and for example, the display apparatus is used for a portable information terminal, a television device (also referred to as a television receiver), digital signage, and a PID (Public Information Display). Examples of the display apparatus include a display apparatus including an organic EL (Electro Luminescence) element or a light-emitting diode (LED), a display apparatus including a liquid crystal element, and electronic paper performing display by an electrophoretic method.

In a display apparatus, when the area occupied by transistors is reduced, the pixel size can be reduced and definition can be increased. Furthermore, when the area occupied by transistors is reduced, the aperture ratio can be increased. Thus, minute transistors have been required.

As devices requiring high-definition display apparatuses, for example, devices for virtual reality (VR), augmented reality (AR), substitutional reality (SR), or mixed reality (MR) have been actively developed.

Patent Document 1 discloses a high-definition display apparatus using an organic EL element.

### REFERENCE

### Patent Document

[Patent Document 1] PCT International Publication No. 2016/038508

### SUMMARY OF THE INVENTION

### Problems to be Solved by the Invention

One object of one embodiment of the present invention is to provide a transistor having a minute size. Another object is to provide a transistor having a long channel length. Another object is to provide a transistor having a long channel length and a transistor having a short channel length. Another object is to provide a transistor having favorable electrical characteristics. Another object is to provide a semiconductor device that occupies a small area. Another object is to provide a semiconductor device having low wiring resistance. Another object is to provide a semiconductor device having low power consumption or a display apparatus having low power consumption. Another object is to provide a high reliable transistor, a high reliable semiconductor device, or a high reliable display apparatus. Another object is to provide a high-definition display apparatus. Another object is to provide a method for manufacturing a semiconductor device or a display apparatus at high productivity. Another object is to provide a novel transistor, a novel semiconductor device, a novel display apparatus, and manufacturing methods thereof.

Note that the description of these objects does not preclude the presence of other objects. One embodiment of the present invention does not need to achieve all of these objects. Other objects can be derived from the description of the specification, the drawings, and the claims.

### Means for Solving the Problems

One embodiment of the present invention is a semiconductor device including a first insulating layer, a second insulating layer, and a transistor. The transistor is provided over the first insulating layer. The transistor includes a semiconductor layer, a gate insulating layer, a first gate electrode, a source electrode, and a drain electrode. The second insulating layer includes an opening reaching the first insulating layer. The source electrode and the drain electrode are provided over the second insulating layer. The semiconductor layer is provided in contact with a side surface of the second insulating layer in the opening and side surfaces of the source electrode and the drain electrode. The gate insulating layer is positioned over the semiconductor layer, the source electrode, and the drain electrode. The first gate electrode overlaps with the opening and is positioned over the gate insulating layer.

One embodiment of the present invention is a semiconductor device including a first insulating layer, a second insulating layer, and a transistor. The transistor is provided over the first insulating layer. The transistor includes a semiconductor layer, a gate insulating layer, a first gate electrode, a source electrode, and a drain electrode. The second insulating layer includes an opening reaching the first insulating layer. The source electrode and the drain electrode are provided over the second insulating layer. The semiconductor layer includes a first region in contact with a side surface of the second insulating layer, a second region in contact with a side surface of the source electrode, and a third region in contact with a side surface of the drain electrode in the opening. In the semiconductor layer, the first region is positioned between the second region and the third region. The gate insulating layer is positioned over the semiconductor layer, the source electrode, and the drain electrode. The first gate electrode overlaps with the opening and is positioned over the gate insulating layer.

One embodiment of the present invention is a semiconductor device including a first insulating layer, a second insulating layer, and a transistor. The transistor is provided over the first insulating layer. The transistor includes a semiconductor layer, a gate insulating layer, a first gate electrode, a source electrode, and a drain electrode. The second insulating layer includes an opening reaching the first insulating layer. The source electrode and the drain electrode are provided over the second insulating layer. The semiconductor layer is provided in contact with a side surface of the second insulating layer in the opening, a top surface of the first insulating layer in the opening, and side surfaces of the source electrode and the drain electrode. The gate insulating layer is positioned over the semiconductor layer, the source electrode, and the drain electrode. The first gate electrode overlaps with the opening and is positioned over the gate insulating layer.

In the semiconductor devices described above, the semiconductor layer is preferably in contact with one or both of a top surface of the source electrode and a top surface of the drain electrode.

In the semiconductor devices described above, the first insulating layer and the gate insulating layer preferably include portions that are in contact with each other in a bottom portion of the opening.

In the semiconductor devices described above, the semiconductor layer preferably includes a portion in contact with a top surface of the second insulating layer.

The semiconductor devices preferably each include a second gate electrode. The second gate electrode is preferably covered with the second insulating layer. A part of the second insulating layer is preferably positioned between a side surface of the second gate electrode and the semiconductor layer.

In the semiconductor devices described above, a third insulating layer is preferably provided between the first insulating layer and the second gate electrode.

In the semiconductor devices described above, a contour shape of the opening is preferably any of a circular shape, an elliptical shape, a quadrangular shape with rounded corners, a regular polygonal shape, a polygonal shape other than the regular polygonal shape, a concave polygonal shape, an elliptical shape, a polygonal shape with rounded corners, and a closed curve in which a straight line and a curve are combined.

In the semiconductor devices described above, the opening preferably includes a plurality of extending portions and at least one or more bent portions. The extending portion preferably has a shape extending in one direction in a top view. One of the extending portions and another of the extending portions preferably are connected to each other through the bent portion.

One embodiment of the present invention is a semiconductor device including a first insulating layer, a second insulating layer, a first transistor, and a second transistor. The first transistor is provided over the first insulating layer. The first transistor includes a first semiconductor layer, a gate insulating layer, a first gate electrode, a first source electrode, and a first drain electrode. The second insulating layer includes a first opening reaching the first insulating layer. The first source electrode and the first drain electrode are provided over the second insulating layer. The first semiconductor layer is provided in contact with a side surface of the second insulating layer in the first opening, a top surface of the first insulating layer in the first opening, and side surfaces of the first source electrode and the first drain electrode. The gate insulating layer is positioned over the first semiconductor layer, the first source electrode, and the first drain electrode. The first gate electrode overlaps with the first opening and is positioned over the gate insulating layer. The second transistor includes a second semiconductor layer, the gate insulating layer, a second gate electrode, a second source electrode, and a second drain electrode. The second source electrode and the second drain electrode are positioned at different levels. The second insulating layer includes a second opening reaching one of the second source electrode and the second drain electrode. The other of the second source electrode and the second drain electrode is provided over the second insulating layer. The second semiconductor layer is provided in contact with a side surface of the second insulating layer in the second opening, a top surface of one of the second source electrode and the second drain electrode, and a side surface of the other of the second source electrode and the second drain electrode. The gate insulating layer is positioned over the second semiconductor layer, the second source electrode, and the second drain electrode. The second gate electrode overlaps with the second opening and is positioned over the gate insulating layer.

In the semiconductor device described above, the first semiconductor layer is preferably in contact with one or both of a top surface of the first source electrode and a top surface of the first drain electrode.

In the semiconductor device described above, the first insulating layer and the gate insulating layer preferably include portions that are in contact with each other in a bottom portion of the first opening.

In the semiconductor device described above, the first semiconductor layer preferably includes a portion in contact with a top surface of the second insulating layer.

In the semiconductor device described above, a contour shape of the first opening is preferably any of a circular shape, an elliptical shape, a quadrangular shape with rounded corners, a regular polygonal shape, a polygonal shape other than the regular polygonal shape, a concave polygonal shape, an elliptical shape, a polygonal shape with rounded corners, and a closed curve in which a straight line and a curve are combined.

In the semiconductor device described above, the first opening preferably includes a plurality of extending portions and at least one or more bent portions. The extending portion preferably has a shape extending in one direction in a top view. One of the extending portions and another of the extending portions are preferably connected to each other through the bent portion.

### Effect of the Invention

According to one embodiment of the present invention, a transistor having a minute size can be provided. A transistor having a long channel length can be provided. A transistor having a long channel length and a transistor having a short channel length can be provided. A transistor having favorable electrical characteristics can be provided. A semiconductor device that occupies a small area can be provided. A semiconductor device having low wiring resistance can be provided. A semiconductor device having low power consumption or a display apparatus having low power consumption can be provided. A high reliable transistor, a high reliable semiconductor device, or a high reliable display apparatus can be provided. A high-definition display apparatus can be provided. A method for manufacturing a semiconductor device or a display apparatus at high productivity can be provided. A novel transistor, a novel semiconductor device, a novel display apparatus, and manufacturing methods thereof can be provided.

Note that the description of these effects does not preclude the presence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a schematic perspective view of a transistor. FIG. 1B is a schematic cross-sectional view of the transistor.

FIG. 2A and FIG. 2B are schematic perspective views of transistors.

FIG. 3A to FIG. 3C are schematic perspective views of transistors.

FIG. 4A and FIG. 4B are schematic perspective views of transistors.

FIG. 5A is a schematic perspective view of a transistor. FIG. 5B is a schematic cross-sectional view of the transistor.

FIG. 6 is a schematic perspective view of a transistor.

FIG. 7A and FIG. 7B are schematic perspective views of transistors.

FIG. 8A and FIG. 8B are schematic perspective views of transistors.

FIG. 9A is a schematic top view of a transistor. FIG. 9B is a schematic cross-sectional view of the transistor.

FIG. 10A is a schematic perspective view of a transistor. FIG. 10B is a schematic top view of the transistor.

FIG. 11A to FIG. 11E are schematic top views of transistors.

FIG. 12A is a top view illustrating an example of a semiconductor device. FIG. 12B is a cross-sectional view illustrating an example of the semiconductor device.

FIG. 13A is a top view illustrating an example of a semiconductor device. FIG. 13B is a cross-sectional view illustrating an example of the semiconductor device.

FIG. 14A is a top view illustrating an example of a semiconductor device. FIG. 14B is a cross-sectional view illustrating an example of the semiconductor device.

FIG. 15A is a top view illustrating an example of a semiconductor device. FIG. 15B is a cross-sectional view illustrating an example of the semiconductor device.

FIG. 16A is a top view illustrating an example of a semiconductor device. FIG. 16B is a cross-sectional view illustrating an example of the semiconductor device.

FIG. 17A is a top view illustrating an example of a semiconductor device. FIG. 17B is a cross-sectional view illustrating an example of the semiconductor device.

FIG. 18A is a top view illustrating an example of a semiconductor device. FIG. 18B is a cross-sectional view illustrating an example of the semiconductor device.

FIG. 19A and FIG. 19B are diagrams each illustrating an example of a semiconductor device.

FIG. 20A to FIG. 20E are cross-sectional views illustrating an example of a method for manufacturing a semiconductor device.

FIG. 21A to FIG. 21D are cross-sectional views illustrating an example of a method for manufacturing a semiconductor device.

FIG. 22A to FIG. 22D are cross-sectional views illustrating an example of a method for manufacturing a semiconductor device.

FIG. 23A and FIG. 23B are cross-sectional views illustrating an example of a method for manufacturing a semiconductor device.

FIG. 24A and FIG. 24B are top views illustrating an example of a method for manufacturing a semiconductor device.

FIG. 25A and FIG. 25B are top views illustrating an example of a method for manufacturing a semiconductor device.

FIG. 26A to FIG. 26D are cross-sectional views illustrating an example of a method for manufacturing a semiconductor device.

FIG. 27A to FIG. 27D are cross-sectional views illustrating an example of a method for manufacturing a semiconductor device.

FIG. 28A to FIG. 28D are cross-sectional views illustrating an example of a method for manufacturing a semiconductor device.

FIG. 29A and FIG. 29B are top views illustrating an example of a method for manufacturing a semiconductor device.

FIG. 30A and FIG. 30B are top views illustrating an example of a method for manufacturing a semiconductor device.

FIG. 31A is a perspective view illustrating an example of a display apparatus. FIG. 31B is a block diagram illustrating an example of the display apparatus.

FIG. 32A is a circuit diagram of a latch circuit. FIG. 32B is a circuit diagram of an inverter circuit.

FIG. 33A and FIG. 33B are each a circuit diagram of a pixel circuit. FIG. 33C is a cross-sectional view illustrating an example of a pixel circuit.

FIG. 34 is a cross-sectional view illustrating an example of a pixel circuit.

FIG. 35 is a schematic cross-sectional view illustrating a structure example of a display apparatus.

FIG. 36A and FIG. 36B are diagrams illustrating a structure example of an electronic device.

FIG. 37A and FIG. 37B are diagrams illustrating structure examples of electronic devices.

FIG. 38A and FIG. 38B are diagrams illustrating a structure example of a display apparatus.

FIG. 39 is a diagram illustrating a structure example of a display apparatus.

FIG. 40A to FIG. 40C are each a perspective view of a display module.

FIG. 41A and FIG. 41B are diagrams illustrating a structure example of a display apparatus.

FIG. 42A to FIG. 42D are diagrams each illustrating a structure example of a display apparatus.

FIG. 43A to FIG. 43D are diagrams each illustrating a structure example of a display apparatus.

FIG. 44A and FIG. 44B are diagrams illustrating a structure example of a display apparatus.

FIG. 45A to FIG. 45D are diagrams illustrating structure examples of a display apparatus.

FIG. 46A to FIG. 46C are diagrams illustrating a structure example of a display apparatus.

FIG. 47A to FIG. 47F are diagrams illustrating examples of electronic devices.

FIG. 48A to FIG. 48G are diagrams illustrating examples of electronic devices.

FIG. 49A is a diagram illustrating a sub-display portion. FIG. 49B1 to FIG. 49B7 are diagrams illustrating structure examples of pixels.

FIG. 50A to FIG. 50G are diagrams illustrating structure examples of pixels.

FIG. 51A to FIG. 51D are diagrams each illustrating a structure example of a light-emitting device.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and description thereof is not repeated. The same hatching pattern is used to show portions having similar functions, and the portions are not especially denoted by reference numerals in some cases.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

The position, size, range, and the like of each component illustrated in drawings do not represent the actual position, size, range, and the like in some cases for easy understanding. Thus, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). The ordinal number added to a component in a part of this specification may be different from the ordinal number added to the component in another part of this specification or the scope of claims.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

A transistor is a kind of semiconductor elements and can have a function of amplifying current or voltage, perform a switching operation for controlling conduction or non-conduction, and the like. An IGFET (Insulated Gate Field Effect Transistor) and a thin film transistor (TFT) are included in the category of a transistor in this specification and the like.

Functions of a “source” and a “drain” are sometimes switched when a transistor of opposite polarity is used or when the direction of current is changed in circuit operation, for example. Thus, the terms “source” and “drain” are interchangeable in this specification and the like. Note that a source and a drain of a transistor can also be referred to as a source terminal and a drain terminal, a source electrode and a drain electrode, or the like as appropriate depending on the circumstances.

A “gate” and a “back gate” can be interchanged with each other. Thus, the terms “gate” and “back gate” can be interchangeable in this specification and the like. Note that the gate and the back gate of a transistor can also be referred to as a gate electrode and a back gate electrode, for example, as appropriate depending on the situation.

In this specification and the like, the term “electrically connected” includes the case where components are connected to each other through an “object having any electric action”. There is no particular limitation on an “object having any electric function” as long as electric signals can be transmitted and received between components that are connected through the object. Examples of the “object having any electric function” include a switching element such as a transistor, a resistor, a coil, and other elements with a variety of functions as well as an electrode and a wiring.

Unless otherwise specified, off-state current in this specification and the like refers to leakage current between a source and a drain of a transistor in an off state (also referred to as a non-conduction state or a cut-off state). Unless otherwise specified, the off state refers to a state where voltage V_{gs} between a gate and a source is lower than threshold voltage Vₜₕ in an n-channel transistor (higher than Vₜₕ in a p-channel transistor).

In this specification and the like, the expression “top surface shapes are substantially the same” means that at least outlines of stacked layers partly overlap with each other. For example, the case of processing an upper layer and a lower layer with the use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “top surface shapes are substantially the same” in some cases. The state of “having the same top surface shape” or “having substantially the same top surface shapes” can be rephrased as the state where “end portions are aligned with each other” or “end portions are substantially aligned with each other”.

In this specification and the like, a tapered shape refers to such a shape that at least part of the side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the component are not necessarily completely flat and may be substantially flat with a slight curvature or substantially flat with slight unevenness.

In this specification and the like, a device formed using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure. Note that a device having the MML structure can be manufactured without using a metal mask, and thus can break through the resolution limit due to alignment accuracy of the metal mask. Furthermore, the manufacturing facilities for metal masks and washing process for metal masks can be unnecessary in the MML structure. A device having the MML structure can reduce manufacturing costs, and thus is suitable for mass production.

In this specification and the like, a structure in which at least light-emitting layers of light-emitting devices (also referred to as light-emitting elements) having different emission wavelengths are separately formed is sometimes referred to as an SBS (Side By Side) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting device includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (may be referred to as a mask layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

### Embodiment 1

In this embodiment, structure examples of a semiconductor device of one embodiment of the present invention are described. Here, a structure including a transistor will be described specifically.

### Structure Example 1

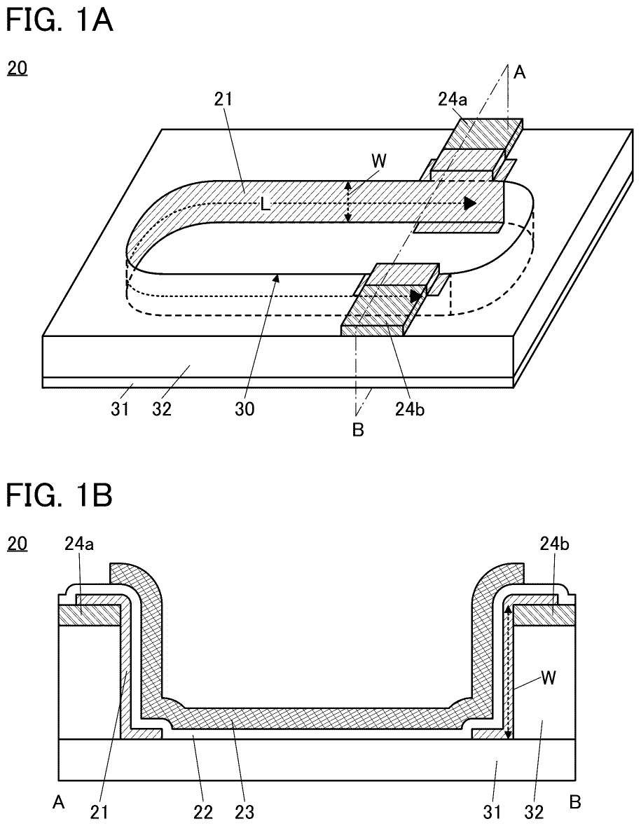

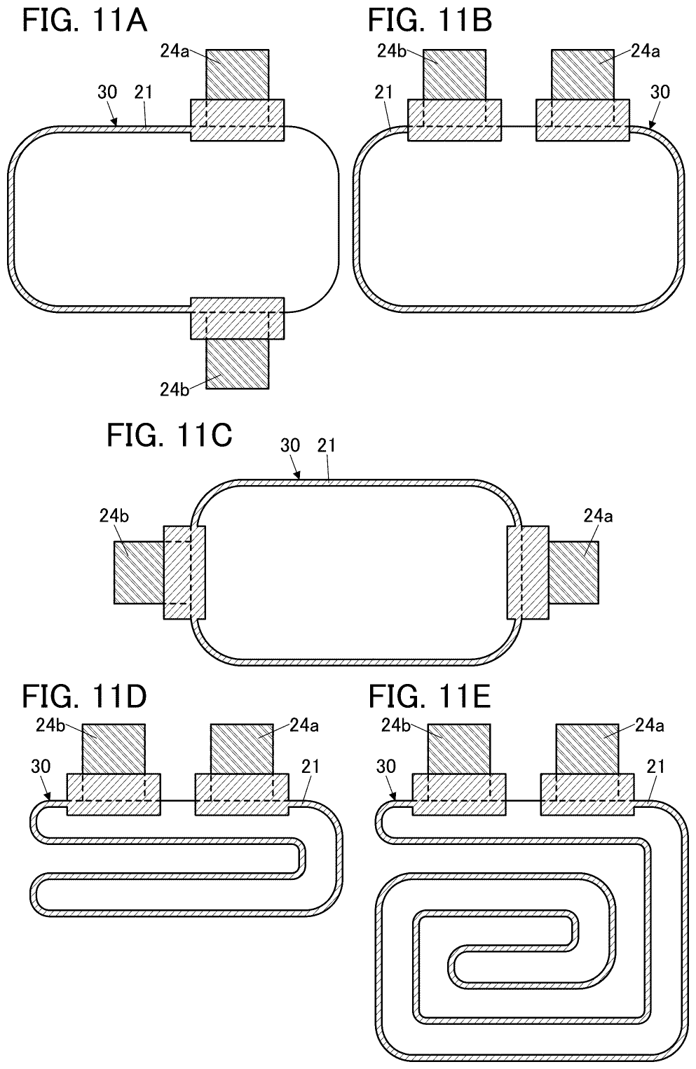

FIG. 1A is a schematic perspective view of a transistor 20. FIG. 1B is a schematic cross-sectional view of a plane sectioned along the dashed-dotted line A-B in FIG. 1A. FIG. 11A is a schematic top view (also referred to as a schematic plan view) of the transistor 20. Note that some components (e.g., a gate electrode 23 and a gate insulating layer 22) are omitted in FIG. 1A and FIG. 11A.

The transistor 20 is provided over an insulating layer 31 and includes a semiconductor layer 21, the gate insulating layer 22, the gate electrode 23, a source electrode 24a, and a drain electrode 24b.

An insulating layer 32 is provided over the insulating layer 31, and the insulating layer 32 includes an opening 30 reaching the insulating layer 31. The source electrode 24a and the drain electrode 24b are provided over the insulating layer 32. The semiconductor layer 21 is provided in contact with the side surface of the insulating layer 32 in the opening 30. The gate insulating layer 22 is provided to cover the semiconductor layer 21, the insulating layer 31, the source electrode 24a, the drain electrode 24b, and the like. The gate electrode 23 overlaps with the opening 30 and is provided to cover the gate insulating layer 22. The semiconductor layer 21 is provided in contact with the source electrode 24a and the drain electrode 24b. Here is shown an example of the semiconductor layer 21 provided in contact with the side surfaces and parts of the top surfaces of the source electrode 24a and the drain electrode 24b.

As illustrated in FIG. 1A and FIG. 1B, the semiconductor layer 21 is provided along the sidewall of the opening 30 (which sometimes refers to the side surface of the opening 30 or the side surface of the insulating layer 32 in the opening 30). It can also be said that the semiconductor layer 21 is provided in a sidewall shape along the sidewall of the opening 30. Here, the channel length L of the transistor 20 corresponds to the distance that is along the sidewall of the opening 30 between the source electrode 24a and the drain electrode 24b. In FIG. 1A, the channel length L is indicated by a double-headed arrow. Meanwhile, the channel width W of the transistor 20 is the width of the semiconductor layer 21 along the depth direction of the opening 30. Thus, the channel width W can be controlled by the thickness of the insulating layer 32 and the depth of the opening 30, so that the transistor can have an extremely short channel width. For example, it is possible to form a transistor with an extremely short channel width that cannot be achieved with a light-exposure apparatus for mass production. Moreover, a transistor with a channel width of less than 10 nm can also be formed without using an extremely expensive light-exposure apparatus used in the cutting-edge LSI technology. In FIG. 1A and FIG. 1B, the channel width W is indicated by a double-headed arrow.

A more complicated contour shape (also referred to as a top surface shape or a planar shape) of the opening 30 can increase the channel length L. Here, the contour shape of the opening 30 is a rectangular shape with rounded corners; however, a variety of shapes can be employed without being limited to the rectangular shape. For example, a circular shape, an elliptical shape, or a quadrangular shape with rounded corners can be employed. Alternatively, a regular polygonal shape such as a regular triangular shape, a square shape, or a regular pentagonal shape or a polygonal shape other than the regular polygonal shape may be employed. By employing a concave polygon in which at least one interior angle is greater than 180°, such as a star polygonal shape, the channel length L can be increased. Alternatively, an elliptical shape, a polygonal shape with rounded corners, a closed curve in which a straight line and a curve are combined, or the like can be employed.

With such a structure, the channel width W of the transistor can be precisely controlled by the thickness of the insulating layer 32; thus, a variation in the channel width W can be extremely small. Furthermore, a transistor with an extremely small channel width W can be achieved.

Here, as an index showing the characteristics of the transistor, the ratio of a channel width W to a channel length L (W/L ratio) is used in some cases. In a conventional transistor, the minimum values of channel length and channel width depend on the light exposure limit of a light-exposure apparatus; thus, in order to reduce the W/L ratio, L needs to be increased and the area occupied by the transistor is increased disadvantageously. However, in the transistor of one embodiment of the present invention, the channel width W can be smaller than the light exposure limit of a light-exposure apparatus; thus, the transistor can have an extremely low W/L ratio without an increase in the area occupied by the transistor.

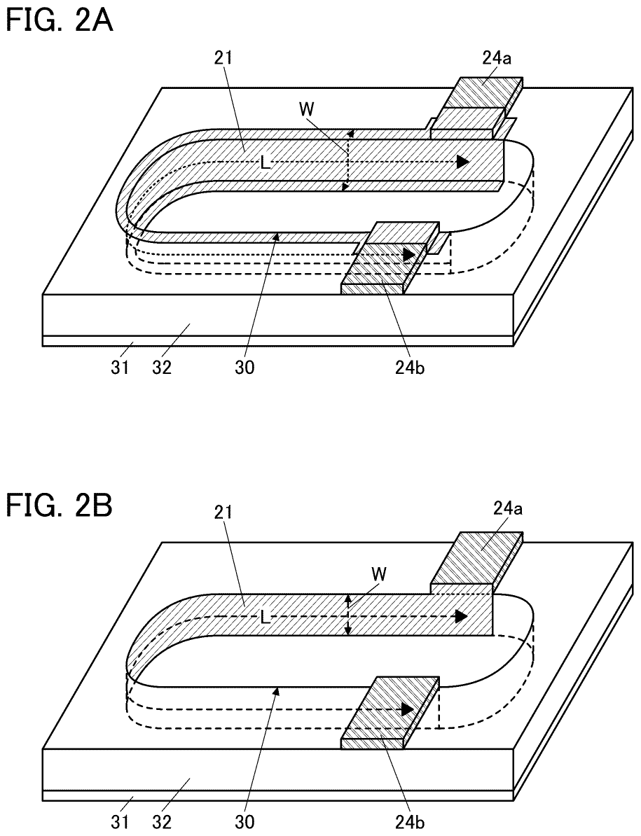

FIG. 2A illustrates an example in which the semiconductor layer 21 is provided on the top surface of the insulating layer 32 and the top surface of the insulating layer 31 positioned in the opening 30 as well as on the sidewall of the opening 30. In the structure illustrated in FIG. 2A, the channel width W of the transistor is the sum of the width of a portion of the semiconductor layer 21 that is positioned on the sidewall of the opening 30, the width of a portion of the semiconductor layer 21 that is positioned on the insulating layer 32, and the width of a portion of the semiconductor layer 21 that is positioned on the top surface of the insulating layer 31.

Although FIG. 1A, FIG. 1B, and FIG. 2A illustrate structures in which the semiconductor layer 21 covers both the source electrode 24a and the drain electrode 24b and the semiconductor layer 21 is in contact with the top surface of the source electrode 24a and the top surface of the drain electrode 24b, the present invention is not limited to the structures. For example, a structure may be employed in which the semiconductor layer 21 covers one of the source electrode 24a and the drain electrode 24b and the semiconductor layer 21 is in contact with one of the top surface of the source electrode 24a and the top surface of the drain electrode 24b. Alternatively, for example, the semiconductor layer 21 may be in contact with neither the top surface of the source electrode 24a nor the top surface of the drain electrode 24b without covering the source electrode 24a or the drain electrode 24b.

FIG. 2B illustrates an example in which the semiconductor layer 21 is in contact with the side surface of the source electrode 24a and the side surface of the drain electrode 24b and is in contact with neither the top surface of the source electrode 24a nor the top surface of the drain electrode 24b. For example, when a semiconductor film to be the semiconductor layer 21 is processed by an anisotropic etching method, the semiconductor layer 21 can be formed along the sidewall of the opening 30.

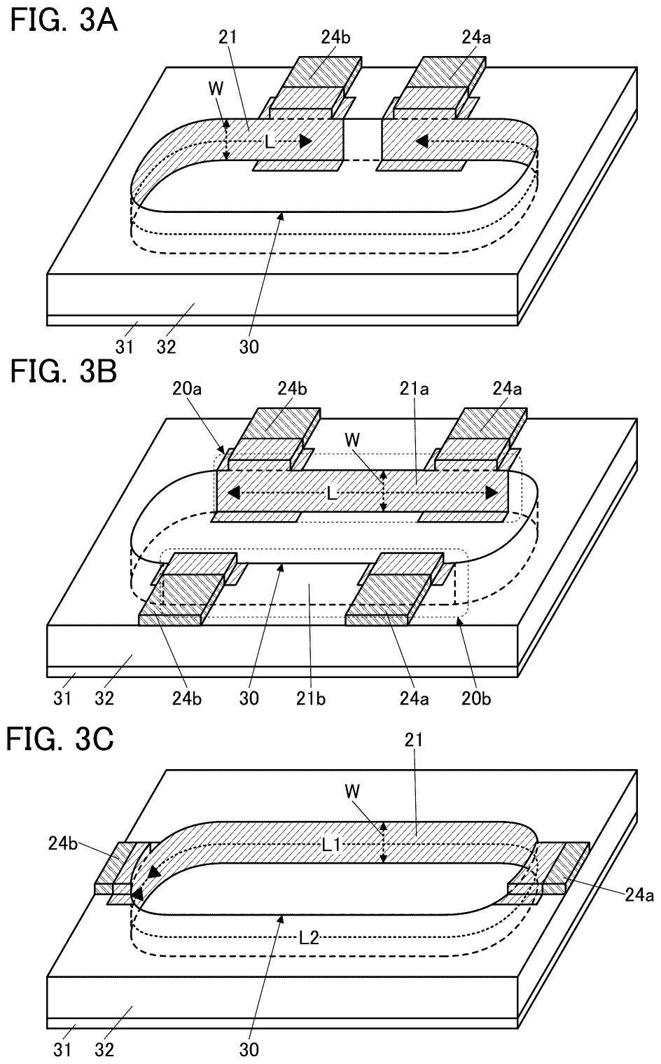

FIG. 3A illustrates an example in which the source electrode 24a and the drain electrode 24b are provided side by side. A schematic top view is illustrated in FIG. 11B. In this structure, the channel length L of the transistor can be close to the perimeter of the opening 30, so that the transistor can have a long channel length L. For example, the channel length L is preferably 70% or more, 80% or more, or 90% or more of the perimeter of the opening 30.

FIG. 3B illustrates an example in which two transistors are placed in one opening 30. Here, a semiconductor layer 21a and a semiconductor layer 21b are provided along the sidewall of the opening 30 without being in contact with each other. Thus, a transistor 20a including the semiconductor layer 21a and a transistor 20b including the semiconductor layer 21b are provided to share one opening 30. The transistor 20a and the transistor 20b have the same channel width W. Note that the channel lengths L of the transistor 20a and the transistor 20b may be different from each other. Although the example in which two transistors are provided in one opening 30 is described here, three or more transistors may be provided.

FIG. 3C illustrates an example in which an annular semiconductor layer 21 is provided along the entire sidewall of the opening 30. A schematic top view is illustrated in FIG. 11C. The source electrode 24a is provided in contact with part of the annular semiconductor layer 21, and the drain electrode 24b is provided in contact with another part of the annular semiconductor layer 21. In this case, as illustrated in FIG. 3C, there are two paths in the semiconductor layer 21 that connect the source electrode 24a and the drain electrode 24b, and the length of one of them can be referred to as a channel length L1 and the length of the other can be referred to as a channel length L2. In particular, the source electrode 24a and the drain electrode 24b are preferably placed symmetrically with respect to the opening 30 so that the channel length L1 and the channel length L2 can be equal to each other.

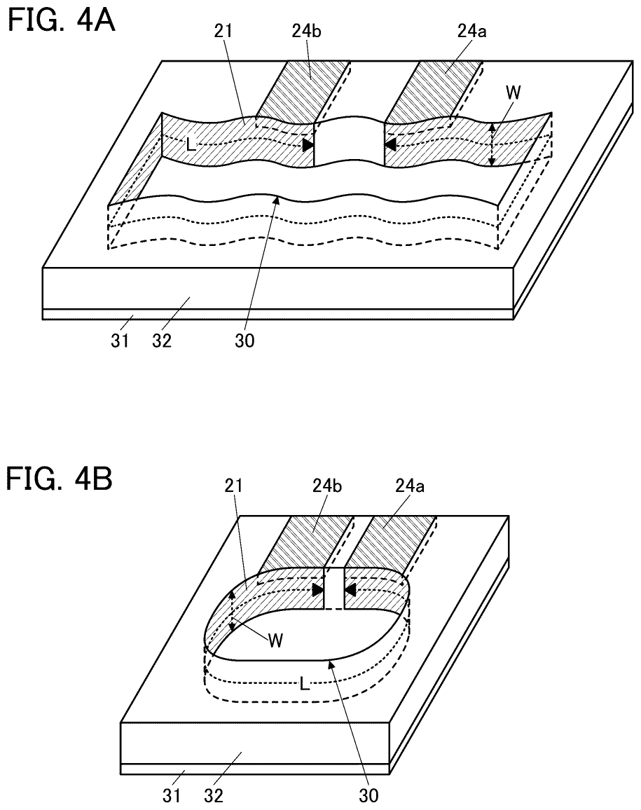

FIG. 4A and FIG. 4B each illustrate a structure example in which the opening 30 has a shape different from the above-described shape.

FIG. 4A illustrates an example of the case where part of the contour of the opening 30 has a wave shape. Thus, the channel length L can be increased without increasing the area occupied by the opening 30.

FIG. 4B illustrates an example in which the contour shape of the opening 30 is substantially circular. In this manner, the area occupied by the transistor can be reduced. In addition, since the shape of the opening 30 is simple, a variation in shape of the opening 30 can be reduced, so that a variation in electrical characteristics of the transistor can be inhibited.

FIG. 4A and FIG. 4B each illustrate an example in which the source electrode 24a and the drain electrode 24b are provided to be embedded in an upper portion of the insulating layer 32, and the top surfaces of the source electrode 24a and the drain electrode 24b and the top surface of the insulating layer 32 are positioned on the same level.

### Structure Example 2

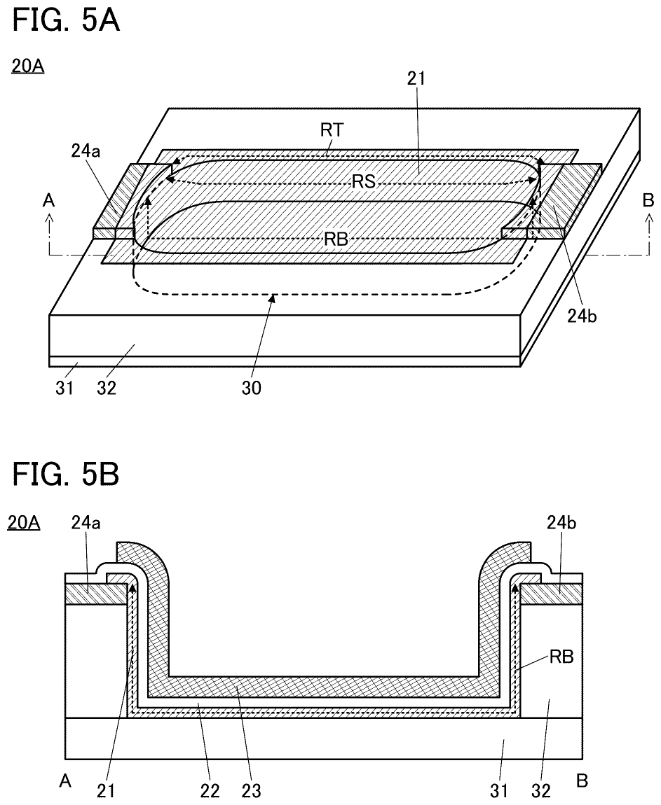

FIG. 5A and FIG. 5B illustrate a structure example different from the structure example 1. FIG. 5A is a perspective view of the transistor 20A, and FIG. 5B is a schematic cross-sectional view of a plane sectioned along the dashed-dotted line A-B in FIG. 5A.

The transistor 20A is different from the transistor described in the structure example 1 mainly in that the semiconductor layer 21 is also provided in the bottom portion of the opening 30.

The semiconductor layer 21 is provided in contact with the side surface of the insulating layer 32 and the top surface of the insulating layer 31 in the opening 30 and the top surface of the insulating layer 32 outside the opening 30.

As illustrated in FIG. 5A, the transistor 20A includes mainly three kinds of paths of current flowing through the semiconductor layer 21 between the source electrode 24a and the drain electrode 24b. The first one is a path RB from the source electrode 24a to the drain electrode, sequentially passing through a portion of the semiconductor layer 21 positioned on the sidewall of the opening 30, a portion of the semiconductor layer 21 positioned on the bottom portion of the opening 30, and a portion of the semiconductor layer 21 positioned on the sidewall of the opening 30. The second one is a path RS from the source electrode 24a to the drain electrode, passing through a portion of the semiconductor layer 21 positioned on the sidewall of the opening 30. The last one is a path RT from the source electrode 24a to the drain electrode 24b, passing through a portion of the semiconductor layer 21 positioned over the insulating layer 32.

In the transistor 20A, the path through which current flows most easily depends on the shape, thickness, or the like of each component. Specifically, current flows easily through the shortest distance path of the above three paths, in which case the current density increases. For example, in order to make a structure in which a large amount of current flows through the path RS, the depth of the opening 30 is increased to make a longer distance of the path RB and the widths of the source electrode 24a and the drain electrode 24b are made smaller than the width of the opening 30 to make a longer distance of the path RT, for example.

With such a structure including a plurality of current paths, the amount of current that can flow in an on state can be increased.

Note that the structure of the semiconductor layer 21 described here can also be applied to other structure examples.

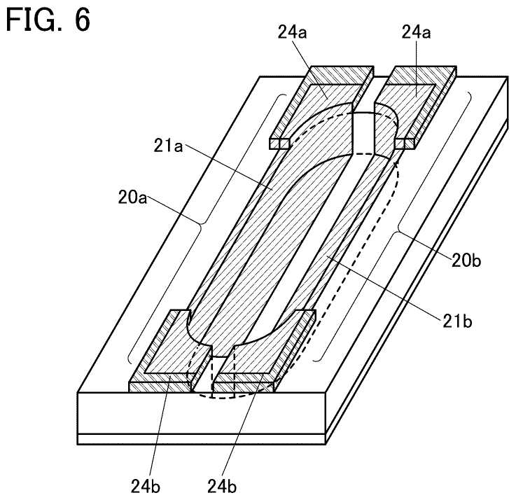

FIG. 6 illustrates an example in which two transistors are provided in one opening 30. Here, the semiconductor layer 21a and the semiconductor layer 21b are in contact with the sidewall and the bottom portion of the opening 30 and the top surface of the insulating layer 32 but are not in contact with each other. The semiconductor layer 21a and the semiconductor layer 21b can be formed using the same semiconductor film. Although the example in which two transistors are provided in one opening 30 is described here, three or more transistors may be provided.

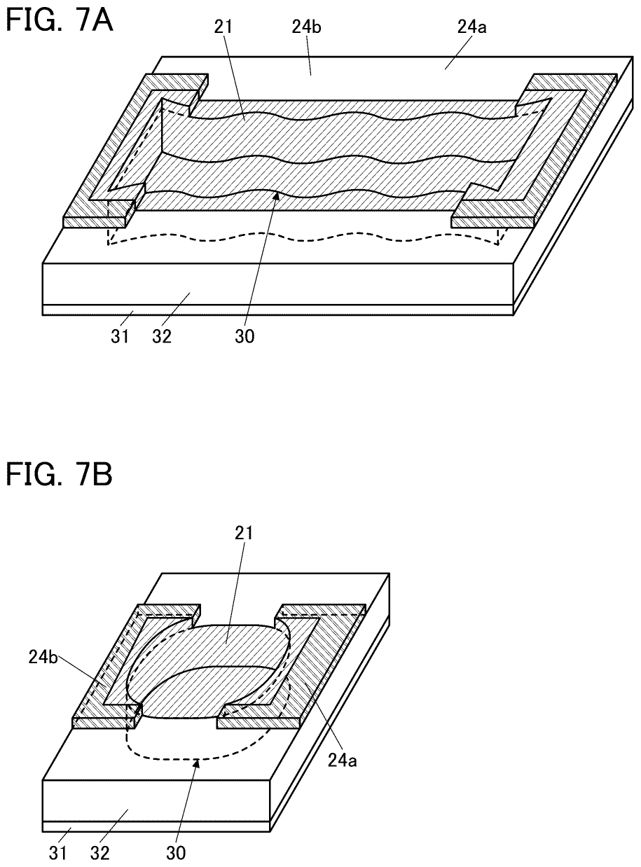

FIG. 7A and FIG. 7B each illustrate an example in which the opening 30 has a shape different from the above-described shape.

FIG. 7A illustrates an example of the case where part of the contour of the opening 30 has a wave shape as in FIG. 4A. Thus, the channel length can be increased.

FIG. 7B illustrates an example in which the opening 30 is substantially circular as in FIG. 4B. In this manner, the area occupied by the transistor can be reduced. In addition, since the shape of the opening 30 is simple, a variation in shape of the opening 30 can be reduced, so that a variation in electrical characteristics of the transistor can be inhibited.

Note that the structure of the opening 30 described here can also be applied to other structure examples.

### Structure Example 3

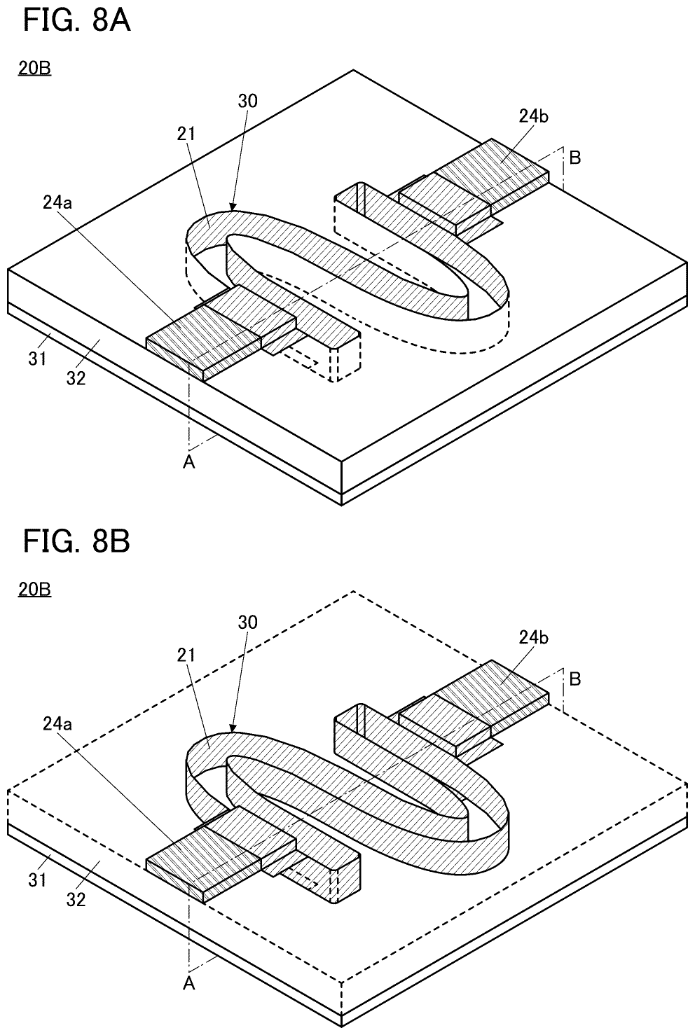

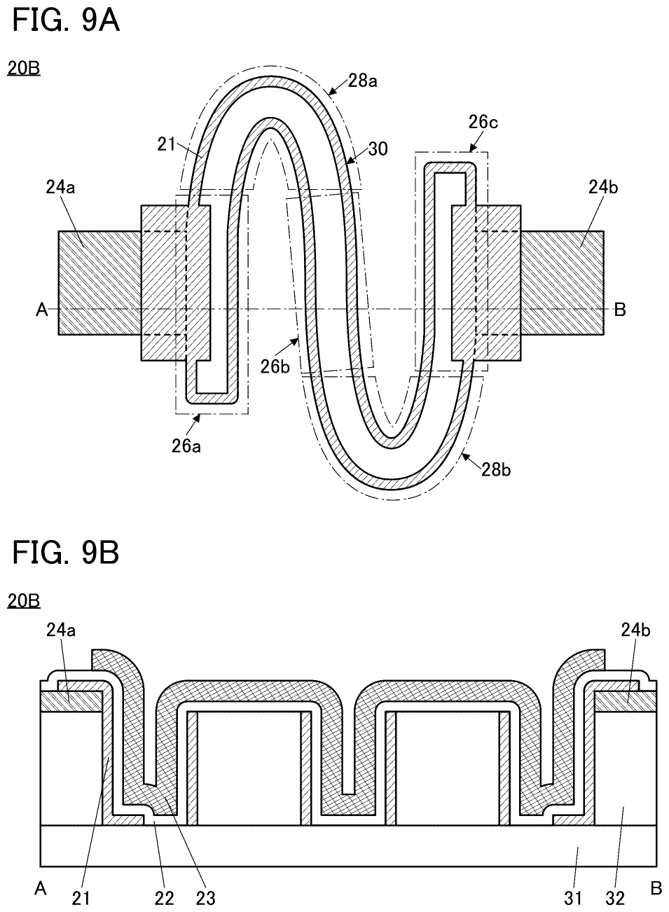

A structure example different from the structure example 1 is illustrated in FIG. 8A, FIG. 8B, FIG. 9A, and FIG. 9B. FIG. 8A and FIG. 8B are schematic perspective views of the transistor 20B, and FIG. 9A is a schematic top view of the transistor 20B. FIG. 9B is a schematic cross-sectional view of a plane sectioned along the dashed-dotted line A-B illustrated in FIG. 8A, FIG. 8B, and FIG. 9A. Note that some components (the gate electrode 23, the gate insulating layer 22, and the like) are omitted in FIG. 8A, FIG. 8B, and FIG. 9A. Furthermore, the insulating layer 32 is illustrated to be seen through, and its outline is indicated by a dashed line in FIG. 8B.

As illustrated in FIG. 8A, FIG. 8B, and FIG. 9A, the transistor 20B is different from the transistor 20 illustrated in the structure example 1 mainly in that the opening 30 has a contour shape with an extending portion and a bent portion. Here, the contour shape of the opening 30 formed by combining the extending portion and the bent portion can be referred to as a serpentine shape, a winding shape, a bending shape, or a meander shape.

As illustrated in FIG. 9A, the opening 30 includes an extending portion 26a, an extending portion 26b, an extending portion 26c, a bent portion 28a, and a bent portion 28b. The contour shape of the opening 30 can be regarded as a shape in which the extending portion 26a and the extending portion 26b are connected to each other through the bent portion 28a and the extending portion 26b and the extending portion 26c are connected to each other through the bent portion 28b.

As illustrated in FIG. 9B, the semiconductor layer 21 is provided along the side surface of the insulating layer 32 in the opening 30. Furthermore, the semiconductor layer 21 includes a region in contact with the source electrode 24a and a region in contact with the drain electrode 24b. In the opening 30, the semiconductor layer 21 is provided to face the gate electrode 23 with the gate insulating layer 22 therebetween.

FIG. 9A and the like illustrate an example in which the semiconductor layer 21 is in contact with the source electrode 24a in the extending portion 26a and in contact with the drain electrode 24b in the extending portion 26c. In addition, the semiconductor layer 21 may be in contact with the source electrode 24a or the drain electrode 24b in the bent portion. For example, the semiconductor layer 21 may be in contact with the source electrode 24a in the bent portion 28a and in contact with the drain electrode 24b in the bent portion 28b.

When the two extending portions are connected to each other with one bent portion, a folded structure can be formed in the opening 30. By forming one or more of such folded shapes, the length of the opening 30 can be significantly larger than the distance between the source electrode 24a and the drain electrode 24b. Thus, the channel length L can be increased without increasing the area occupied by the transistor. The transistor with the long channel length L can have high saturation characteristics. In addition, the transistor can have an extremely low ratio of the channel width W to the channel length L (W/L ratio).

In this specification and the like, the state where the change in current is small in the saturation region of the I_{d}-V_{d} characteristics of a transistor is sometimes described using the expression “high saturation characteristics”.

Note that the structure of the opening 30 described here can also be applied to other structure examples.

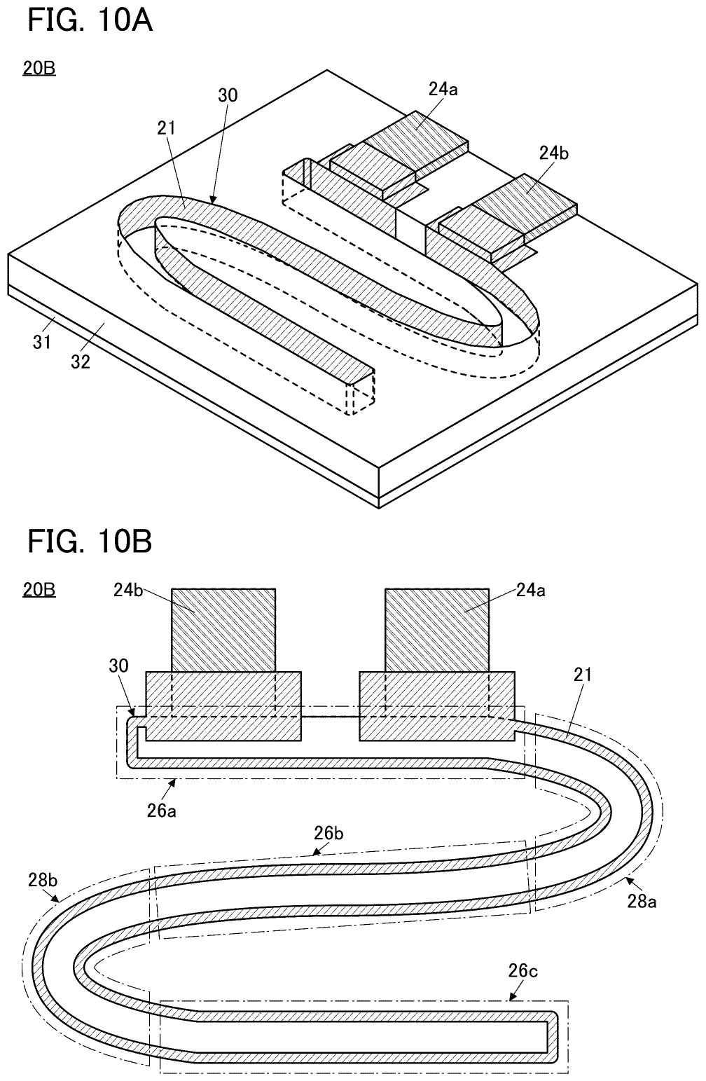

FIG. 10A and FIG. 10B illustrate a structure example in which the semiconductor layer 21 is not provided on part of the sidewall of the opening 30. FIG. 10A is a schematic perspective view of the transistor 20B, and FIG. 10B is a schematic top view thereof.

FIG. 10A and FIG. 10B illustrate a structure example in which the source electrode 24a and the drain electrode 24b are provided to be adjacent to each other and the semiconductor layer 21 is not provided on the sidewall of the opening 30 between the source electrode 24a and the drain electrode 24b. With such a structure, the channel length L of the transistor can be close to the perimeter of the opening 30, so that the channel length L can be increased.

Although FIG. 10A and the like illustrate an example in which the semiconductor layer 21 is in contact with the source electrode 24a and the drain electrode 24b in the extending portion 26a, one embodiment of the present invention is not limited to the example. The semiconductor layer 21 may be in contact with the source electrode 24a and the drain electrode 24b in the bent portion. Alternatively, the semiconductor layer 21 may be in contact with one of the source electrode 24a and the drain electrode 24b in the bent portion and may be in contact with the other in the extending portion.

Although FIG. 9A, FIG. 10B, and the like illustrate the structure in which the opening 30 includes the extending portion 26a, the extending portion 26b, the extending portion 26c, the bent portion 28a, and the bent portion 28b, the present invention is not limited to the structure. The opening 30 preferably has a plurality of extending portions and at least one or more bent portions. Here, the number of bent portions is preferably smaller than that of the extending portions by one. For example, as illustrated in FIG. 11D, the opening 30 may have two extending portions and one bent portion. For another example, the opening 30 may have four or more extending portions and three or more bent portions. Note that as illustrated in FIG. 11E, the contour shape of the opening 30 may be a roll shape.

Although the contour shape of the opening 30 is a shape with rounded corners in FIG. 9A and the like, one embodiment of the present invention is not limited to the shape, and the corners of the extending portion and the bent portion may be angular. In this case, the contour shape of the opening 30 can also be referred to as a zigzag shape.

Note that the structure of the semiconductor layer 21 described here can also be applied to other structure examples.

At least part of this embodiment can be implemented in combination with any of the other embodiments described in this specification as appropriate.

### Embodiment 2

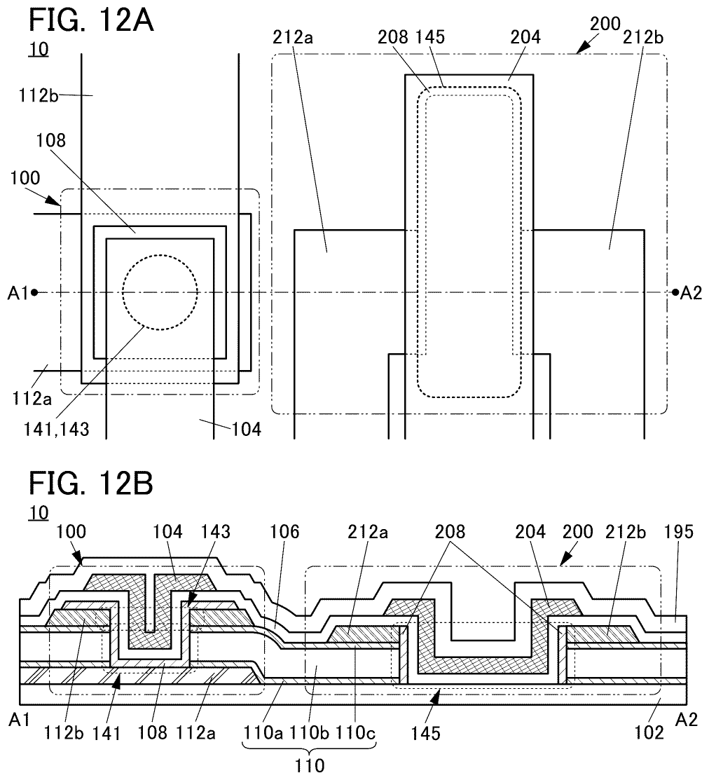

In this embodiment, a semiconductor device of one embodiment of the present invention is described with reference to FIG. 12 to FIG. 19B.

### Structure Example 1

FIG. 12A is a top view (also referred to as a plan view) of a semiconductor device 10. FIG. 12B is a cross-sectional view of a plane sectioned along the dashed-dotted line A1-A2 in FIG. 12A. Note that in FIG. 12A, some components (e.g., an insulating layer) of the semiconductor device 10 are not illustrated. Some components are not illustrated in top views of semiconductor devices in the drawings hereinafter, as in FIG. 12A.

The semiconductor device 10 includes the transistor 100, a transistor 200, and an insulating layer 110. The transistor 100, the transistor 200, and the insulating layer 110 are provided over the substrate 102. In addition, an insulating layer serving as a base film may be provided over the substrate 102. In that case, the transistor 100, the transistor 200, and the insulating layer 110 are provided over an insulating layer serving as a base film. Thus, the expression “top surface of the substrate 102” also includes the top surface of the insulating layer serving as the base film over the substrate 102 hereinafter.

The transistor 100 has a structure different from the structure of the transistor 200. Some of the formation steps of the transistor 100 can be the same as some of the formation steps of the transistor 200. In the case where the semiconductor device 10 is used for a display apparatus, preferably, the transistor 100 is used as a selection transistor of a pixel and the transistor 200 is used as a driving transistor. Specifically, since it is preferable that the driving transistor have high saturation characteristics, the transistor 200 with a long channel length can be suitably used. As described above, the semiconductor device of one embodiment of the present invention has an excellent effect that transistors with different channel lengths over the same substrate can be freely designed by the thickness of an insulating layer and by pattern forming.

A structure of the transistor 200 will be described. Here, an example in which the above-described structure of the transistor 20 is employed for the transistor 200 is described.

The transistor 200 includes a conductive layer 204, a conductive layer 212a, a conductive layer 212b, an insulating layer 106, and a semiconductor layer 208. In the transistor 200, the conductive layer 204 functions as a gate electrode, and part of the insulating layer 106 functions as a gate insulating layer. The conductive layer 212a functions as one of the source electrode and the drain electrode, and the conductive layer 212b functions as the other. The layers included in the transistor 200 may each have a single-layer structure or a stacked-layer structure. For the conductive layer 204, the conductive layer 212a, the conductive layer 212b, the insulating layer 106, and the semiconductor layer 208, the above description of the gate electrode 23, the source electrode 24a, the drain electrode 24b, the gate insulating layer 22, and the semiconductor layer 21 can be referred to.

The insulating layer 110 includes an opening 145. The conductive layer 212a and the conductive layer 212b are provided over the insulating layer 110. End portions of part of the conductive layer 212a and part of the conductive layer 212b are preferably aligned with end portions of the insulating layer 110 on the opening 145 side. The conductive layer 212a and the conductive layer 212b can be formed with the same material. The conductive layer 212a and the conductive layer 212b can be formed in the same process. For example, a film to be the conductive layer 212a and the conductive layer 212b is formed and the film is processed, whereby the conductive layer 212a and the conductive layer 212b can be formed. For the insulating layer 110 and the opening 145, the above description of the insulating layer 32 and the opening 30 can be referred to.

The semiconductor layer 208 is provided in a sidewall shape in contact with the sidewall of the opening 145 (which sometimes refers to the side surface of the opening 145 or the side surface of the insulating layer 110 in the opening 145). The semiconductor layer 208 is provided in contact with the side surface of the conductive layer 212a, the side surface of the conductive layer 212b, and the side surface of the insulating layer 110. As illustrated in FIG. 12B, the bottom surface of the semiconductor layer 208 may be in contact with the top surface of the substrate 102. Note that the semiconductor layer 208 is provided not to cover the substrate 102 in the bottom portion of the opening 145. That is, a region where the semiconductor layer 208 is not formed is provided in the bottom portion of the opening 145, and the top surface of the substrate 102 and the insulating layer 106 are in contact with each other in the region.

In the semiconductor layer 208, the region in contact with the conductive layer 212a functions as one of a source region and a drain region, and the region in contact with the conductive layer 212b functions as the other of the source region and the drain region. In the semiconductor layer 208, the channel formation region is provided between the source region and the drain region.

The insulating layer 106 is provided to cover the opening 145. The insulating layer 106 is provided over the semiconductor layer 208, the conductive layer 212a, the conductive layer 212b, and the insulating layer 110. The insulating layer 106 includes a region in contact with the top surface and the side surface of the semiconductor layer 208, the top surface and the side surface of the conductive layer 212a, the top surface and the side surface of the conductive layer 212b, the side surface of the insulating layer 110, and the top surface of the substrate 102. The insulating layer 106 has a shape along the shapes of the top surface and the side surface of the semiconductor layer 208, the top surface and the side surface of the conductive layer 212a, the top surface and the side surface of the conductive layer 212b, the side surface of the insulating layer 110, and the top surface of the substrate 102.

The conductive layer 204 is provided over the insulating layer 106 and includes a region in contact with the top surface of the insulating layer 106. The conductive layer 204 includes a region overlapping with the semiconductor layer 208 with the insulating layer 106 therebetween. The conductive layer 204 has a shape along the top surface and the side surface of the insulating layer 106.

Next, the structure of the transistor 100 will be described.

The transistor 100 includes a conductive layer 104, the insulating layer 106, a semiconductor layer 108, a conductive layer 112a, and a conductive layer 112b. In the transistor 100, the conductive layer 104 serves as a gate electrode (also referred to as a first gate electrode), and part of the insulating layer 106 serves as a gate insulating layer (also referred to as a first gate insulating layer). The conductive layer 112a functions as one of a source electrode and a drain electrode, and the conductive layer 112b functions as the other of the source and the drain electrode. The layers included in the transistor 100 may each have a single-layer structure or a stacked-layer structure.

The conductive layer 112a is provided over the substrate 102, and the insulating layer 110 is provided over the conductive layer 112a. The insulating layer 110 is provided so as to cover the top surface and the side surface of the conductive layer 112a. The insulating layer 110 has the opening 141 reaching the conductive layer 112a. It can be said that the conductive layer 112a is exposed in the opening 141.

The conductive layer 112b is provided over the insulating layer 110. The conductive layer 112b includes a region overlapping with the conductive layer 112a with the insulating layer 110 therebetween. The conductive layer 112b has an opening 143 in a region overlapping with the conductive layer 112a. The opening 143 is provided in a region overlapping with the opening 141. The conductive layer 112b can be formed using the same material as that for the conductive layer 212a and the conductive layer 212b. The conductive layer 112b can be formed in the same steps as the conductive layer 212a and the conductive layer 212b. For example, a film to be the conductive layer 112b, the conductive layer 212a, and the conductive layer 212b is formed and the film is processed, whereby the conductive layer 112b, the conductive layer 212a, and the conductive layer 212b can be formed.

The semiconductor layer 108 is provided to cover the opening 141 and the opening 143. The semiconductor layer 108 can be formed using the same material as the semiconductor layer 208. The semiconductor layer 108 can be formed in the same step as the semiconductor layer 208. For example, a film to be the semiconductor layer 108 and the semiconductor layer 208 is formed and the film is processed, whereby the semiconductor layer 108 and the semiconductor layer 208 can be formed.

The semiconductor layer 108 includes a region in contact with the top surface and the side surface of the conductive layer 112b, the side surface of the insulating layer 110, and the top surface of the conductive layer 112a. The semiconductor layer 108 is electrically connected to the conductive layer 112a via the opening 141 and the opening 143. The semiconductor layer 108 has a shape along the shapes of the top surface and the side surface of the conductive layer 112b, the side surface of the insulating layer 110, and the top surface of the conductive layer 112a. The semiconductor layer 108 includes a region overlapping with the conductive layer 112a with the insulating layer 110 therebetween. It can be said that the insulating layer 110 includes a region interposed between the conductive layer 112a and the semiconductor layer 108.

In the semiconductor layer 108, the region in contact with the conductive layer 112a functions as one of a source region and a drain region, and the region in contact with the conductive layer 112b functions as the other of the source region and the drain region. In the semiconductor layer 108, the channel formation region is provided between the source region and the drain region.

The insulating layer 106 is provided to cover the opening 141 and the opening 143. The insulating layer 106 is provided over the semiconductor layer 108, the conductive layer 112b, and the insulating layer 110. The insulating layer 106 includes a region in contact with the top surface and the side surface of the semiconductor layer 108, the top surface and the side surface of the conductive layer 112b, and the top surface of the insulating layer 110. The insulating layer 106 has a shape along the shapes of the top surface and the side surface of the semiconductor layer 108, the top surface and the side surface of the conductive layer 112b, and the top surface of the insulating layer 110.

The conductive layer 104 is provided over the insulating layer 106 and includes a region in contact with the top surface of the insulating layer 106. The conductive layer 104 includes a region overlapping with the semiconductor layer 108 with the insulating layer 106 therebetween. The conductive layer 104 has a shape along the top surface and the side surface of the insulating layer 106. The conductive layer 104 can be formed using the same material as the conductive layer 204. The conductive layer 104 can be formed in the same step as the conductive layer 204. For example, a film to be the conductive layer 104 and the conductive layer 204 is formed and the film is processed, whereby the conductive layer 104 and the conductive layer 204 can be formed.

The transistor 100 is what is called a top-gate transistor including the gate electrode above the semiconductor layer 108. Furthermore, since the bottom surface of the semiconductor layer 108 is in contact with the conductive layer 112a and the conductive layer 112b functioning the source electrode and the drain electrode, the transistor 100 can be referred to as a TGBC (Top Gate Bottom Contact) transistor. In the transistor 100, the source electrode and the drain electrode are positioned at different heights from the surface of the substrate 102 over which the transistor 100 is formed, and drain current flows in a direction perpendicular or substantially perpendicular to the surface of the substrate 102. It can be also said that drain current flows in the vertical direction or the substantially vertical direction in the transistor 100. Accordingly, the transistor of one embodiment of the present invention can be referred to as a vertical-channel transistor or a vertical field-effect transistor (VFET). The transistor 200 has a structure in which current flows in both the vertical direction and the lateral direction; thus, the transistor 200 can be referred to as a VLFET (Vertical Lateral Field Effect Transistor).

The channel length of the transistor 100 can be controlled by the thickness of the insulating layer 110 (specifically, the insulating layer 110b) provided between the conductive layer 112a and the conductive layer 112b. Accordingly, a transistor with a channel length smaller than the resolution limit of a light exposure apparatus used for manufacturing the transistor can be manufactured with high accuracy. Furthermore, variations in characteristics among a plurality of the transistors 100 are also reduced. Accordingly, the operation of the semiconductor device including the transistor 100 can be stabilized and the reliability thereof can be improved. When the variations in characteristics are reduced, the circuit design flexibility is increased and the operation voltage of the semiconductor device can be reduced. Thus, power consumption of the semiconductor device can be reduced.

In the transistor 100, the source electrode, the layer including the channel formation region, and the drain electrode can be provided to overlap with each other in the vertical direction; thus, the area occupied by the transistor can be significantly reduced as compared with what is called a planar transistor in which a layer including a channel formation region is provided in a planar shape.

The conductive layer 112a, the conductive layer 112b, and the conductive layer 104 can function as wirings, and the transistor 100 can be provided in a region where these wirings overlap with each other. That is, the areas occupied by the transistor 100 and the wirings can be reduced in the circuit including the transistor 100 and the wirings. Accordingly, the area occupied by the circuit can be reduced, which makes it possible to provide a small-size semiconductor device. The transistor 100 with a short channel length and the transistor 200 with a long channel length can be formed over the same substrate by some common steps. For example, when the transistor 100 is used as the transistor required to have a high on-state current and the transistor 200 is used as the transistor required to have high saturation characteristics, a high-performance semiconductor device can be provided.

The conductive layer 112a and the conductive layer 112b functioning as the source electrode and the drain electrode of the transistor 100 are provided on different planes. Specifically, the conductive layer 112a is provided over the substrate 102, the conductive layer 112b is provided over the insulating layer 110, and the insulating layer 110 is sandwiched between the conductive layer 112a and the conductive layer 112b. On the other hand, the conductive layer 212a and the conductive layer 212b functioning as the source electrode and the drain electrode of the transistor 200 are provided on the same plane. Specifically, the conductive layer 212a and the conductive layer 212b are provided over the insulating layer 110. It can be rephrased that one of the source electrode and the drain electrode of the transistor 100 is provided on a plane different from the plane provided with the source electrode and the drain electrode of the transistor 200, and the other is provided on the same plane as the source electrode and the drain electrode of the transistor 200.

When the semiconductor device of one embodiment of the present invention is used for a pixel circuit of a display apparatus, the area occupied by the pixel circuit can be reduced and a high-definition display apparatus can be provided, for example. When the semiconductor device of one embodiment of the present invention is used for a driver circuit (e.g., one or both of a gate line driver circuit and a source line driver circuit) of a display apparatus, the area occupied by the driver circuit can be reduced and the display apparatus can have a narrow bezel.

An insulating layer 195 is provided to cover the transistor 100 and the transistor 200. The insulating layer 195 functions as a protective layer of the transistor 100 and the transistor 200.

Next, the structures of the transistor 100 and the transistor 200 are described in detail.

There is no particular limitation on semiconductor materials used for the semiconductor layer 108 and the semiconductor layer 208. For example, a single-element semiconductor or a compound semiconductor can be used. Examples of the single-element semiconductor include silicon and germanium. Examples of the compound semiconductor include gallium arsenide and silicon germanium. Other examples of the compound semiconductor include an organic semiconductor, a nitride semiconductor, and an oxide semiconductor (OS). These semiconductor materials may include an impurity as a dopant.

There is no particular limitation on the crystallinity of the semiconductor material used for each of the semiconductor layer 108 and the semiconductor layer 208, and any of an amorphous semiconductor, a single crystal semiconductor, and a semiconductor having other crystallinity than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

For each of the semiconductor layer 108 and the semiconductor layer 208, silicon can be used. Examples of silicon include single crystal silicon, polycrystalline silicon, microcrystalline silicon, and amorphous silicon. An example of polycrystalline silicon is low-temperature polysilicon (LTPS). A transistor including amorphous silicon in a channel formation region can be formed over a large glass substrate, and can be manufactured at low cost. A transistor including polycrystalline silicon in a channel formation region has high field-effect mobility and enables high-speed operation. A transistor including microcrystalline silicon in a channel formation region has higher field-effect mobility and enables higher speed operation than a transistor including amorphous silicon.

Each of the semiconductor layer 108 and the semiconductor layer 208 preferably includes a metal oxide exhibiting semiconductor characteristics (also referred to as an oxide semiconductor).

The band gap of a metal oxide used for each of the semiconductor layer 108 and the semiconductor layer 208 is preferably 2.0 eV or more, further preferably 2.5 eV or more.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be retained for a long period. Furthermore, the power consumption of the semiconductor device can be reduced with the OS transistor.

The insulating layer 110 preferably includes one or more inorganic insulating films. Examples of a material that can be used for the inorganic insulating film include an oxide, a nitride, an oxynitride, and a nitride oxide. Examples of the oxide include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of the nitride include silicon nitride and aluminum nitride. Examples of the oxynitride include silicon oxynitride, aluminum oxynitride, gallium oxynitride, yttrium oxynitride, and hafnium oxynitride. Examples of the nitride oxide include silicon nitride oxide and aluminum nitride oxide.

Note that in this specification and the like, an oxynitride refers to a material that contains more oxygen than nitrogen in its composition. A nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

In the transistor 200, a region of the semiconductor layer 208 in contact with the insulating layer 110 can function as the channel formation region. In the transistor 100, a region of the semiconductor layer 108 in contact with the insulating layer 110 can function as the channel formation region. In the case where metal oxides are used for the semiconductor layer 108 and the semiconductor layer 208, at least part of a region of the insulating layer 110 that is in contact with the semiconductor layer 108 and at least part of a region of the insulating layer 110 that is in contact with the semiconductor layer 208 preferably contain oxygen in order to improve the properties of the interface between the semiconductor layer 108 and the insulating layer 110 and the interface between the insulating layer 208 and the insulating layer 110. Specifically, the region of the insulating layer 110 that is in contact with the channel formation region in the semiconductor layer 108 and the region of the insulating layer 110 that is in contact with the channel formation region in the semiconductor layer 208 preferably contain oxygen. One or more of an oxide and an oxynitride can be used suitably for the region of the insulating layer 110 that is in contact with the channel formation region in the semiconductor layer 108 and the region of the insulating layer 110 that is in contact with the channel formation region in the semiconductor layer 208.

The insulating layer 110 preferably has a stacked-layer structure. FIG. 12B and the like illustrate an example in which the insulating layer 110 has a stacked-layer structure of an insulating layer 110a, an insulating layer 110b over the insulating layer 110a, and an insulating layer 110c over the insulating layer 110b.

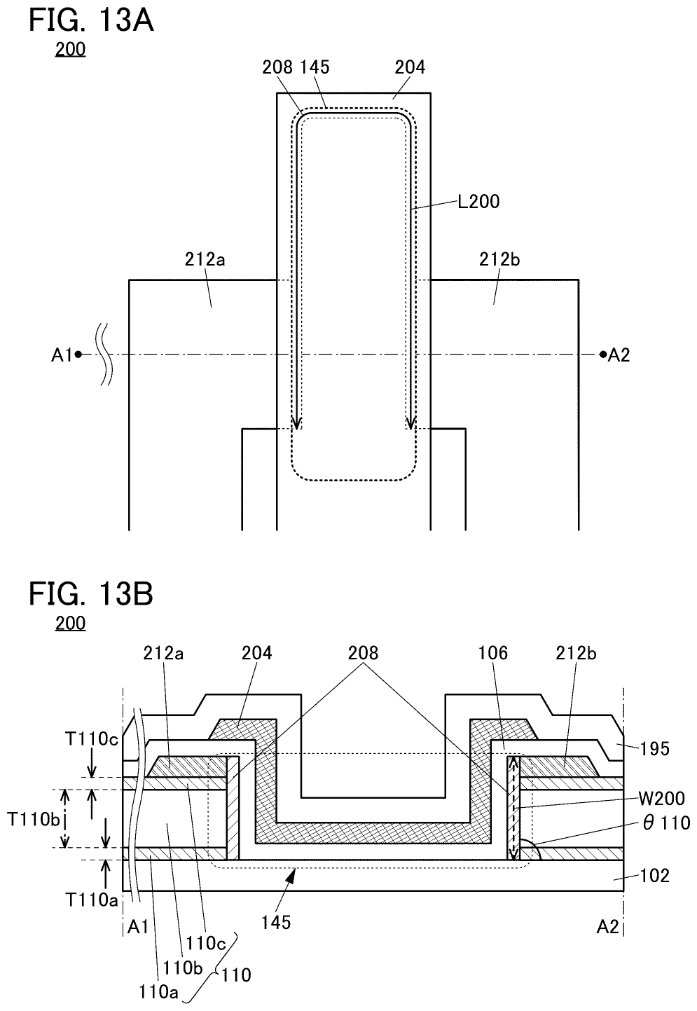

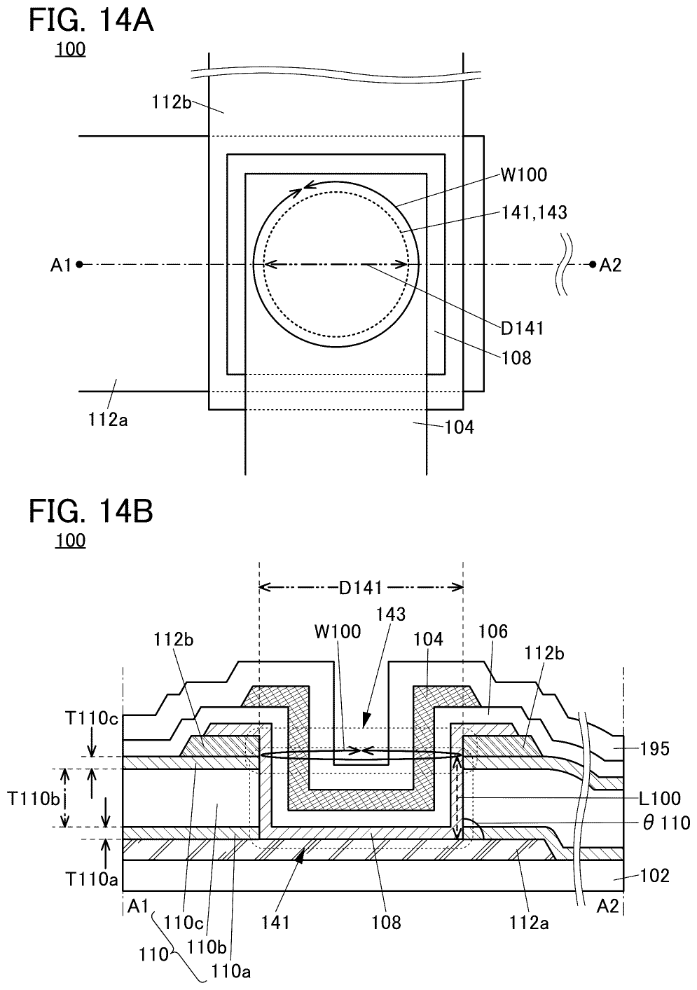

FIG. 13A and FIG. 13B are enlarged views of the transistor 200 illustrated in FIG. 12A and FIG. 12B. FIG. 14A and FIG. 14B are enlarged views of the transistor 100.

The insulating layer 110b preferably contains oxygen, and any one or more of the oxide and oxynitride described above are preferably used. Specifically, one or both of silicon oxide and silicon oxynitride can be suitably used for the insulating layer 110b. Accordingly, at least a region of the semiconductor layer 208 that is in contact with the insulating layer 110b and a region of the semiconductor layer 108 that is in contact with the insulating layer 110b can each function as a channel formation region.

It is further preferable that a film from which oxygen is released by heating be used as the insulating layer 110b. When the insulating layer 110b releases oxygen by heat applied during the manufacturing process of the transistor 100, the oxygen can be supplied to the semiconductor layer 108. Supplying oxygen from the insulating layer 110b to the semiconductor layer 108, particularly to the channel formation region, can repair oxygen vacancies (V_{O}) and thud reduce the oxygen vacancies (V_{O}). In addition, defects generated by entry of hydrogen into an oxygen vacancy (V_{O}) (hereinafter also referred to as V_{O}H) can be reduced by oxygen supply. Thus, the transistor can have favorable electrical characteristics and high reliability.

For example, the insulating layer 110b can be supplied with oxygen when heat treatment in an atmosphere containing oxygen or plasma treatment in an atmosphere containing oxygen is performed. Alternatively, an oxide film may be formed over the top surface of the insulating layer 110b by a sputtering method in an atmosphere containing oxygen to supply oxygen. After that, the oxide film may be removed. In addition, Embodiment 3 described later will give an example in which oxygen is supplied to the insulating layer 110b by forming a metal oxide layer 137.

The insulating layer 110b is preferably formed by a film formation method such as a sputtering method or a plasma-enhanced chemical vapor deposition (PECVD) method. In particular, by a sputtering method not using a gas containing hydrogen as a film formation gas, a film having an extremely low hydrogen content can be formed. Consequently, supply of hydrogen to the channel formation region is inhibited and the electrical characteristics of the transistor 100 can be stabilized.

In the insulating layer 110b, a substance (e.g., an atom, a molecule, and an ion) is preferably easily diffused. In other words, the diffusion coefficient of a substance in the insulating layer 110b is preferably high. Preferably, oxygen is easily diffused into the insulating layer 110b, in particular. That is, the diffusion coefficient of oxygen in the insulating layer 110b is preferably high. Oxygen contained in the insulating layer 110b is diffused into the insulating layer 110b, and is supplied to the semiconductor layer 108 through the interface between the insulating layer 110b and the semiconductor layer 108 and supplied to the semiconductor layer 208 through the interface between the insulating layer 110b and the semiconductor layer 208.

Here, the use of materials having high conductivity for the semiconductor layer 108 and the semiconductor layer 208 enables the transistor to have a high on-state current. However, the use of a material having high conductivity facilitates the formation of oxygen vacancies (V_{O}); the increased oxygen vacancies (V_{O}) in the channel formation region results in an increase of V_{O}H, which sometimes causes a shift of the threshold voltage of the transistor and an increase in a drain current flowing at a gate voltage of 0 V (hereinafter also referred to as cut-off current). For example, a shift of the threshold voltage in the negative direction increases the cut-off current in the case of an n-channel transistor in some cases. By providing the insulating layer 110b, oxygen is supplied to at least the region of the semiconductor layer 108 that is in contact with the insulating layer 110b and the region of the semiconductor layer 208 that is in contact with the insulating layer 110b, that is, the channel formation regions of the transistor 100 and the transistor 200, so that oxygen vacancies (V_{O}) and V_{O}H in the channel formation regions can be reduced. This inhibits a shift of the threshold voltage and allows the transistor to have both a low cut-off current and a high on-state current. Consequently, a semiconductor device that achieves both low power consumption and high performance can be provided.

The region of the semiconductor layer 108 in contact with the conductive layer 112a functions as one of a source region and a drain region of the transistor 100, and the region of the semiconductor layer 108 in contact with the conductive layer 112b functions as the other of the source region and the drain region. The source region and the drain region have lower electric resistance than the channel formation region. In other words, the source region and the drain region are regions having a higher carrier concentration or regions having a higher oxygen vacancy density than the channel formation region.

The insulating layer 110a is provided between the insulating layer 110b and the conductive layer 112a. The insulating layer 110c is provided between the insulating layer 110b and the conductive layer 112b. Preferably, the insulating layer 110a and the insulating layer 110c each release a small amount of impurities (e.g., hydrogen and water) and are less likely to transmit impurities. Thus, the impurities contained in the insulating layer 110a and the insulating layer 110c can be inhibited from being diffused into the channel formation region. Thus, the transistor can have favorable electrical characteristics and high reliability.

As each of the insulating layer 110a and the insulating layer 110c, a film which is less likely to transmit oxygen is preferably used. This can inhibit oxygen contained in the insulating layer 110b from being diffused into the conductive layer 112a through the insulating layer 110a. Similarly, oxygen contained in the insulating layer 110b can be inhibited from being diffused into the conductive layer 112b through the insulating layer 110c. This can inhibit the conductive layer 112a and the conductive layer 112b from being oxidized and thus having high electric resistance. At the same time, oxygen contained in the insulating layer 110b is inhibited from being diffused to the insulating layer 110a and the insulating layer 110c side, which increases the amount of oxygen supplied from the insulating layer 110b to the channel formation region, reducing oxygen vacancies (V_{O}) and V_{O}H in the channel formation region.

When a film that does not easily allow diffusion of oxygen is used for each of the insulating layer 110a and the insulating layer 110c, oxygen can be effectively supplied from the insulating layer 110b to the channel formation region. A structure may be employed in which one or both of the insulating layer 110a and the insulating layer 110c are not necessarily provided.

The insulating layer 110a and the insulating layer 110c each preferably contain nitrogen, and any one or more of the nitride and nitride oxide described above are preferably used. For example, silicon nitride or silicon nitride oxide can be suitably used for each of the insulating layer 110a and the insulating layer 110c. Alternatively, any one or more of an oxide and an oxynitride may be used for one or both of the insulating layer 110a and the insulating layer 110c. Aluminum oxide can be suitably used for each of the insulating layer 110a and the insulating layer 110c, for example. Note that for the insulating layer 110a and the insulating layer 110c, the same material or different materials may be used.

Note that in this specification and the like, different materials mean materials, the constituent elements of which are partially or entirely different from each other, or materials having the same constituent elements and different compositions.

For example, a thickness T110a of the insulating layer 110a can be greater than or equal to 3 nm, greater than or equal to 5 nm, greater than or equal to 10 nm, greater than or equal to 20 nm, greater than or equal to 50 nm, or greater than or equal to 70 nm and can be less than 1 μm, less than or equal to 500 nm, less than or equal to 400 nm, less than or equal to 300 nm, less than or equal to 200 nm, less than or equal to 150 nm, or less than or equal to 120 nm. As illustrated in FIG. 14B, the thickness T110a can be the shortest distance between the formation surface of the insulating layer 110a (here, the top surface of the conductive layer 112a) and the top surface of the insulating layer 110a in the cross-sectional view.

If the thickness T110a of the insulating layer 110a is large, a large amount of impurities might be released from the insulating layer 110a, resulting in an increase in the amount of impurities diffused into the channel formation region. Meanwhile, if the thickness T110a is small, oxygen contained in the insulating layer 110b might be diffused into the conductive layer 112a side through the insulating layer 110a, resulting in a reduction in oxygen supplied to the channel formation region. With the thickness T110a within the above range, the oxygen vacancies (V_{O}) and V_{O}H in the channel formation region can be reduced. This can inhibit the conductive layer 112a from being oxidized and having higher electric resistance due to oxygen contained in the insulating layer 110b.

A thickness T110c of the insulating layer 110c can be, for example, greater than or equal to 3 nm, greater than or equal to 5 nm, greater than or equal to 10 nm, greater than or equal to 15 nm, or greater than or equal to 20 nm and can be less than or equal to 1 μm, less than or equal to 500 nm, less than or equal to 300 nm, less than or equal to 200 nm, less than or equal to 150 nm, less than or equal to 120 nm, or less than or equal to 100 nm. As illustrated in FIG. 14B, the thickness T110c can be the shortest distance between the formation surface of the insulating layer 110c (here, the top surface of the insulating layer 110b) and the top surface of the insulating layer 110c in the cross-sectional view.

If the thickness T110c of the insulating layer 110c is large, a large amount of impurities might be released from the insulating layer 110c, resulting in an increase in the amount of impurities diffused into the channel formation region. On the other hand, if the thickness T110c is small, oxygen contained in the insulating layer 110b might be diffused into the conductive layer 112b side through the insulating layer 110c, resulting in a reduction in oxygen supplied to the channel formation region. With the thickness T110c within the above range, the oxygen vacancies (V_{O}) and V_{O}H in the channel formation region can be reduced. This can inhibit the conductive layer 112b from being oxidized and having higher electric resistance due to oxygen contained in the insulating layer 110b.

At least one of the region of the semiconductor layer 108 in contact with the insulating layer 110a and the region of the semiconductor layer 108 in contact with the insulating layer 110c may be a region having lower resistance than the channel formation region (hereinafter, also referred to as a low-resistance region). In other words, the region has a higher carrier concentration or a higher oxygen vacancy density than the channel formation region. When a material that releases an impurity (e.g., water and hydrogen) is used for the insulating layer 110a, the region of the semiconductor layer 108 that is in contact with the insulating layer 110a can be a low-resistance region. In the semiconductor layer 108, the low-resistance region can be formed between the channel formation region and the region in contact with the conductive layer 112a (one of a source region and a drain region). Similarly, when a material that releases an impurity is used for the insulating layer 110c, the region of the semiconductor layer 108 that is in contact with the insulating layer 110c can be a low-resistance region. In the semiconductor layer 108, the low-resistance region can be formed between the channel formation region and the region in contact with the conductive layer 112b (the other of the source region and the drain region). The low-resistance region can serve as a buffer region for relieving a drain electric field. Note that the low-resistance region may function as the source region or the drain region.

The low-resistance region provided between the drain region and the channel formation region inhibits generation of a high electric field in the vicinity of the drain region, so that generation of hot carriers is inhibited to inhibit the degradation of the transistor. For example, in the case where the conductive layer 112a serves as a drain electrode, the conductive layer 112b serves as a source electrode, and the region of the semiconductor layer 108 that is in contact with the insulating layer 110a serves as the low-resistance region, a high electric field is not easily generated in the vicinity of the drain region, and generation of hot carriers and degradation of the transistor can be inhibited. In the case where the conductive layer 112a serves as the source electrode, the conductive layer 112b serves as the drain electrode, and the region of the semiconductor layer 108 that is in contact with the insulating layer 110c serves as the low-resistance region, a high electric field is not easily generated in the vicinity of the drain region, and generation of hot carriers and degradation of the transistor can be inhibited.

As described above, if an excessive amount of impurities is released from the insulating layer 110a and the insulating layer 110c, impurities might be diffused into the channel formation region. Even when a material that releases impurities is used for the insulating layer 110a and the insulating layer 110c, the amount of released impurities is preferably small.

The insulating layer 110 preferably includes at least the insulating layer 110b. For example, a structure in which one or both of the insulating layer 110a and the insulating layer 110c are not provided may be employed. The insulating layer 110 may have a single-layer structure or a stacked-layer structure of two layers or four or more layers.

There is no limitation on the top-view shapes of the opening 145, the opening 141 and the opening 143, and the shapes can be polygons such as a circle, an ellipse, a triangle, a tetragon (including a rectangle, a rhombus, and a square), and a pentagon; and polygons with rounded corners, for example. Note that the polygonal shape can be either a concave polygonal shape (a polygonal shape at least one of the interior angles of which is greater than 180°) or a convex polygonal shape (a polygonal shape all the interior angles of which are less than or equal to 180°). The top-view shapes of the opening 141 and the opening 143 are preferably circular as illustrated in FIG. 12A and the like. When the top surface shape of the opening is a circular shape, processing accuracy at the time of formation of the opening can be high, whereby the opening can be formed to have a minute size. Note that in this specification and the like, the term “circular shape” is not limited to a perfect circular shape.

In this specification and the like, the top surface shape of the opening 145 refers to the shape of an end portion of the top surface of the insulating layer 110 on the opening 145 side. The top-view shape of the opening 141 refers to the shape of the end portion of the top surface of the insulating layer 110 on the opening 141 side. The top-view shape of the opening 143 refers to the shape of the end portion of the bottom surface of the conductive layer 112b on the opening 143 side.

As illustrated in FIG. 12A and the like, the opening 141 and the opening 143 can have the same or substantially the same top-view shapes. In that case, it is preferable that the end portion of the bottom surface of the conductive layer 112b on the opening 143 side be aligned with or substantially aligned with the end portion of the top surface of the insulating layer 110 on the opening 141 side as illustrated in FIG. 12B and the like. The bottom surface of the conductive layer 112b refers to the surface thereof on the insulating layer 110 side. The top surface of the insulating layer 110 refers to the surface thereof on the conductive layer 112b side.

In addition, it is acceptable that the top surface shapes of the opening 141 and the opening 143 are not identical. In the case where the top-view shapes of the opening 141 and the opening 143 are circular, the opening 141 and the opening 143 may be concentrically arranged, but not necessarily concentrically arranged.

The channel length and the channel width of the transistor 200 will be described with reference to FIG. 13A and FIG. 13B.

In FIG. 13A, the channel length L200 of the transistor 200 is indicated by a solid double-headed arrow. The channel length L200 corresponds to the distance along the sidewall of the opening 145 between the conductive layer 212a and the conductive layer 212b. In FIG. 13B, the channel length W200 of the transistor 200 is indicated by a dashed double-headed arrow. The channel width W200 is the width of the semiconductor layer 208 along the depth direction of the opening 145.

The channel length and the channel width of the transistor 100 will be described with reference to FIG. 14A and FIG. 14B.

In FIG. 14B, a channel length L100 of the transistor 100 is indicated by a dashed double-headed arrow. The channel length L100 of the transistor 100 corresponds to the length of the side surface of the insulating layer 110b on the opening 141 side in a cross-sectional view. In other words, the channel length L100 depends on the thickness T110b of the insulating layer 110b and the angle θ110 formed by the side surface of the insulating layer 110b on the opening 141 side and the formation surface of the insulating layer 110b (which is the top surface of the insulating layer 110a here). Thus, the channel length L100 can be a value smaller than the resolution limit of the light exposure apparatus, which enables the transistor to have a minute size. Specifically, it is possible to form a transistor with an extremely short channel length that cannot be achieved with a conventional light-exposure apparatus for mass production of flat panel displays (the minimum line width: approximately 2 μm or approximately 1.5 μm, for example). Moreover, a transistor with a channel length of less than 10 nm can also be formed without using an extremely expensive light-exposure apparatus used in the cutting-edge LSI technology.

The channel length L100 can be, for example, greater than or equal to 5 nm, greater than or equal to 7 nm, or greater than or equal to 10 nm and can be less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 μm.

The reduction in the channel length L100 can increase the on-state current of the transistor 100. With use of the transistor 100, a circuit capable of high-speed operation can be manufactured. Furthermore, the area occupied by the circuit can be reduced. Thus, a small semiconductor device can be obtained. The use of the semiconductor device of one embodiment of the present invention in a large display apparatus or a high-definition display apparatus can reduce signal delay in wirings and reduce display unevenness even if the number of wirings is increased, for example. In addition, since the area occupied by the circuit can be reduced, the bezel of the display apparatus can be narrowed.

By adjusting the thickness T110b of the insulating layer 110b and the angle θ110, the channel length L100 can be controlled. In FIG. 14B, the thickness T110b of the insulating layer 110b is indicated by a dashed-dotted double-headed arrow.

The thickness T110b of the insulating layer 110b can be, for example, greater than or equal to 5 nm, greater than or equal to 7 nm, or greater than or equal to 10 nm and can be less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm.

The side surface of the insulating layer 110 on the opening 141 side preferably has a vertical shape or a tapered shape. The angle θ110 is preferably 90° or less. By reducing the angle θ110, the coverage with a layer (e.g., the semiconductor layer 108) formed over the insulating layer 110 can be improved. The smaller the angle θ110 is, the longer the channel length L100 is. The larger the angle θ110 is, the shorter the channel length L100 is.

The angle θ110 can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 70° and less than or equal to 90°, less than or equal to 85°, or less than or equal to 80°. The angle θ110 may be less than or equal to 75°, less than or equal to 70°, less than or equal to 65°, or less than or equal to 60°.

Although FIG. 14B and the like illustrate the structure in which the side surface of the insulating layer 110 on the opening 141 side is linear in the cross-sectional view, one embodiment of the present invention is not limited to the structure. In the cross-sectional view, the side surface of the insulating layer 110 on the opening 141 side may be curved, or the side surface may include both a linear region and a curved region.

It is preferable that the conductive layer 112b not be provided inside the opening 141. Specifically, it is preferable that the conductive layer 112b not include a region in contact with the side surface of the insulating layer 110 on the opening 141 side. If the conductive layer 112b is also provided inside the opening 141, the channel length L100 of the transistor 100 is shorter than the length of the side surface of the insulating layer 110b and the channel length L100 is difficult to control in some cases. Accordingly, it is preferable that the top surface shape of the opening 143 match with the top surface shape of the opening 141, or the opening 143 cover the opening 141 completely in the top view (also referred to as a plan view).

In FIG. 14A and FIG. 14B, a width D141 of the opening 141 is indicated by a dashed double-dotted double-headed arrow. FIG. 14A illustrates an example in which the top surface shape of the opening 141 is a circular shape. In this case, the width D141 corresponds to the diameter of the circle and a channel width W100 of the transistor 100 is the length of the circumference of the circle. That is, the channel width W100 is xx D141. Accordingly, in the case where the top surface shape of the opening 141 is a circular shape, the channel width W100 of the transistor can be smaller than in the case where the opening 141 has any other shape.

The width D141 of the opening 141 sometimes varies in the depth direction. As the width D141 of the opening 141, for example, the average value of the following three diameters can be used: the diameter at the highest level of the insulating layer 110b (or the insulating layer 110) in a cross-sectional view, the diameter at the lowest level of the insulating layer 110b (or the insulating layer 110) in a cross-sectional view, and the diameter at the midpoint between these levels. For another example, any of the diameter at the highest level of the insulating layer 110b (or the insulating layer 110) in a cross-sectional view, the diameter at the lowest level of the insulating layer 110b (or the insulating layer 110) in a cross-sectional view, and the diameter at the midpoint between these levels can be used as the diameter of the opening 141.

In the case where the opening 141 is formed by a photolithography method, the width D141 of the opening 141 is larger than or equal to the resolution limit of a light-exposure apparatus. The width D141 can be, for example, greater than or equal to 200 nm, greater than or equal to 300 nm, greater than or equal to 400 nm, or greater than or equal to 500 nm and can be less than 5 μm, less than or equal to 4.5 μm, less than or equal to 4 μm, less than or equal to 3.5 μm, less than or equal to 3 μm, less than or equal to 2.5 μm, less than or equal to 2 μm, less than or equal to 1.5 μm, or less than or equal to 1 μm.

When the channel length L100 of the transistor 100 is short, materials that release a smaller amount of hydrogen are preferably used for the insulating layer 110a and the insulating layer 110c. In the case where materials that release even a small amount of hydrogen are used for the insulating layer 110a and the insulating layer 110c, their thicknesses are preferably small. For example, when the channel length L100 is less than or equal to 100 nm, the thickness T110a of the insulating layer 110a and the thickness T110c of the insulating layer 110c are each preferably greater than or equal to 1 nm, greater than or equal to 3 nm, or greater than or equal to 5 nm and less than or equal to 50 nm, less than or equal to 40 nm, less than or equal to 30 nm, less than or equal to 20 nm, less than or equal to 15 nm, or less than or equal to 10 nm. Accordingly, the amount of impurities diffused into the channel formation region can be reduced, and the transistor can have favorable electrical characteristics and high reliability even with the short channel length L100.

Although the structure in which the region of the semiconductor layer 108 that is in contact with the insulating layer 110b functions as the channel formation region is described as an example, one embodiment of the present invention is not limited to the structure. The region of the semiconductor layer 108 that is in contact with the insulating layer 110a may also function as the channel formation region. Similarly, the region that is in contact with the insulating layer 110c may also function as the channel formation region.

Although the semiconductor layer 108, the insulating layer 106, and the conductive layer 104 cover the opening 141 and the opening 143 in the transistor 100 in FIG. 12B and the like, one embodiment of the present invention is not limited thereto. A step may be formed between the insulating layer 110 and the conductive layer 112a, and the semiconductor layer 108, the insulating layer 106, and the conductive layer 104 may be provided along the step.

The detailed structure of the transistor 200 is described with reference to FIG. 13A and FIG. 13B. FIG. 13A and FIG. 13B are enlarged views of the transistor 200 illustrated in FIG. 12A and FIG. 12B.

As described above, the channel length L100 of the transistor 100 can have a value smaller than that of the resolution limit of the light-exposure apparatus, and the channel length L200 of the transistor 200 can have a value larger than or equal to that of the resolution limit of the light-exposure apparatus. For example, when the transistor 100 is used as the transistor required to have a high on-state current and the transistor 200 is used as the transistor required to have high saturation characteristics, the semiconductor device 10 can have high performance by utilizing the advantages of the transistors. Some of the formation steps of the transistor 100 can be the same as some of the formation steps of the transistor 200. Specifically, the semiconductor layer 108 and the semiconductor layer 208 can be formed in the same steps. One part of the insulating layer 106 serves as the gate insulating layer of the transistor 100 and another part of the insulating layer 106 serves as the gate insulating layer of the transistor 200. The conductive layer 104 and the conductive layer 204 can be formed in the same steps. The conductive layer 112b, the conductive layer 212a, and the conductive layer 212b can be formed in the same steps. This allows higher productivity and lower manufacturing cost of the semiconductor device 10.

### [Semiconductor Layer 108 and Semiconductor Layer 208]

Metal oxides that can be used for the semiconductor layers 108 and the semiconductor layer 208 are specifically described. Examples of the metal oxide include indium oxide, gallium oxide, and zinc oxide. The metal oxide preferably contains at least indium or zinc. The metal oxide preferably contains two or three elements selected from indium, an element M, and zinc. The element Mis a metal element or metalloid element that has a high bonding energy with oxygen, or a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably any one or more kinds of the above elements, further preferably one or more kinds selected from aluminum, gallium, tin, and yttrium, and still further preferably one or more kinds of gallium and tin. In this specification and the like, a metal element and a metalloid element may be collectively referred to as a “metal element”, and a “metal element” in this specification and the like may refer to a metalloid element.

For example, for each of the semiconductor layer 108 and the semiconductor layer 208, an indium zinc oxide (In—Zn oxide), an indium tin oxide (also referred to as In—Sn oxide or ITO), an indium titanium oxide (In—Ti oxide), an indium gallium oxide (In—Ga oxide), an indium tungsten oxide (also referred to as In—W oxide or IWO), an indium gallium aluminum oxide (In—Ga—Al oxide), an indium gallium tin oxide (also referred to as In—Ga—Sn oxide), a gallium zinc oxide (also referred to as Ga—Zn oxide or GZO), an aluminum zinc oxide (also referred to as Al—Zn oxide or AZO), an indium aluminum zinc oxide (also referred to as In—Al—Zn oxide or IAZO), an indium tin zinc oxide (also referred to as In—Sn—Zn oxide or ITZO (registered trademark)), an indium titanium zinc oxide (In—Ti—Zn oxide), an indium gallium zinc oxide (also referred to as In—Ga—Zn oxide or IGZO), an indium gallium tin zinc oxide (also referred to as In—Ga—Sn—Zn oxide or IGZTO), or an indium gallium aluminum zinc oxide (also referred to as In—Ga—Al—Zn oxide, IGAZO, IGZAO, or IAGZO) can be used. Alternatively, an indium tin oxide containing silicon (also referred to as ITSO), gallium tin oxide (Ga—Sn oxide), an aluminum tin oxide (Al—Sn oxide), or the like can be used.

When the proportion of the number of indium atoms in the total number of atoms of all the metal elements contained in the metal oxide is increased, the field-effect mobility of the transistor can be increased. In addition, the transistor can have a high on-state current.

Note that the metal oxide may contain, instead of indium or in addition to indium, one or more kinds of metal elements belonging to a period of a higher number in the periodic table. A larger overlap between orbits of metal elements tends to increase the carrier conductivity of the metal oxide. Thus, a transistor including a metal element with a larger period number in the periodic table can have higher field-effect mobility in some cases. Examples of the metal element belonging to a period of a higher number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Incidentally, lanthanum, cerium, praseodymium, neodymium, promethium, samarium, and europium are called light rare-earth elements.

The metal oxide may contain one or more kinds of nonmetallic elements. By containing a nonmetallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of element M atoms in the total number of atoms of all the metal elements contained in the metal oxide, oxygen vacancies (V_{O}) can be inhibited from being formed in the metal oxide. Accordingly, generation of carriers due to oxygen vacancies (V_{O}) is inhibited, which makes the off-state current of the transistor low. Furthermore, a change in electrical characteristics of the transistor can be inhibited, and the reliability of the transistor can be increased.

Electrical characteristics and reliability of a transistor depend on the composition of the metal oxide used for each of the semiconductor layer 108 and the semiconductor layer 208. Thus, by varying the composition of the metal oxide in accordance with the electrical characteristics and reliability required for the transistor, the semiconductor device can have both good electrical characteristics and high reliability.

When a metal oxide is In-M-Zn oxide, the atomic proportion of In is preferably higher than or equal to the atomic proportion of the element M in the In-M-Zn oxide. Examples of the atomic ratio of the metal elements of such In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8, In:M:Zn=5:2:5, In:M:Zn=10:1:10, In:M:Zn=20:1:10, and In:M:Zn=40:1:10 and a composition in the neighborhood of any of these atomic ratios. Note that a composition in the neighborhood includes the range of ±30% of an intended atomic ratio. By increasing the atomic proportion of indium in the metal oxide, the on-state current, field-effect mobility, or the like of the transistor can be increased.

The atomic proportion of In may be lower than the atomic proportion of the element M in the In-M-Zn oxide. Examples of the atomic ratio of the metal elements in such In-M-Zn oxide include In:M:Zn=1:3:2, In:M:Zn=1:3:3, and In:M:Zn=1:3:4 and a composition in the neighborhood of any of these atomic ratios. By increasing the atomic proportion of M in the metal oxide, generation of oxygen vacancies (V_{O}) can be inhibited.

In the case where a plurality of metal elements are contained as the element M, the sum of the proportions of the numbers of atoms of the metal elements can be the proportion of the number of element M atoms.

In this specification and the like, the proportion of the number of indium atoms in the total number of atoms of all the metal elements contained is sometimes referred to as the content percentage of indium. The same applies to other metal elements.

The use of a material with a high content percentage of indium for each of the semiconductor layer 108 and the semiconductor layer 208 enables an increase in the on-state current, field-effect mobility, or the like of the transistor. Furthermore, with the element M, generation of oxygen vacancies (V_{O}) can be inhibited. The content percentage of the element M (the proportion of the number of element M atoms in the total number of atoms of all the metal elements contained) is preferably greater than or equal to 0.1% and less than or equal to 3%, further preferably greater than or equal to 0.1% and less than or equal to 2%. Accordingly, the transistor can have favorable electrical characteristics. For example, a metal oxide with In:M:Zn=40:1:10 or the neighborhood thereof is preferably used. The element M is preferably any one or more kinds of the above elements, further preferably one or more kinds selected from aluminum, gallium, tin, and yttrium. Specifically, a metal oxide with In:Sn:Zn=40:1:10 or the neighborhood thereof can be suitably used. Alternatively, a metal oxide with In:Al:Zn=40:1:10 or the neighborhood thereof can be suitably used.

Here, in the case where a metal oxide having a polycrystalline structure is used for each of the semiconductor layer 108 and the semiconductor layer 208, the crystal grain boundary becomes a recombination center and captures carriers and thus decreases the on-state current of the transistor in some cases. In the case where a metal oxide with a composition that tends to form a polycrystalline structure is used, the metal oxide preferably contains an element that hinders crystallization. For example, indium tin oxide containing silicon (ITSO) is less likely to have a polycrystalline structure than indium tin oxide (ITO) and can be suitably used for each of the semiconductor layer 108 and the semiconductor layer 208. In the case where ITSO is used, the content percentage of silicon (the proportion of the number of silicon atoms in the total number of atoms of all the metal elements contained) is preferably greater than or equal to 1% and less than or equal to 20%, further preferably greater than or equal to 3% and less than or equal to 20%, further preferably greater than or equal to 3% and less than or equal to 15%, still further preferably greater than or equal to 5% and less than or equal to 15%. Specifically, a metal oxide with In:Sn:Si=45:5:4 or In:Sn:Si=95:5:8 or a composition in the neighborhood thereof can be suitably used.

For analysis of the composition of the semiconductor layer 108 and the semiconductor layer 208, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used, for example. Alternatively, some of such analysis methods may be performed in combination. Note that as for an element whose content percentage is low, the actual content percentage may be different from the content percentage obtained by analysis because of the influence of the analysis accuracy. In the case where the content percentage of the element Mis low, for example, the content percentage of the element M obtained by analysis may be lower than the actual content percentage.

A sputtering method or an atomic layer deposition (ALD) method can be suitably used to form the metal oxide. In the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The semiconductor layer 108 and the semiconductor layer 208 may each have a stacked-layer structure of two or more metal oxide layers. The two or more metal oxide layers included in each of the semiconductor layer 108 and the semiconductor layer 208 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in each of the semiconductor layer 108 and the semiconductor layer 208 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. In addition, it is particularly preferable to use gallium, aluminum, or tin as the element M. The elements M in the first metal oxide layer and the second metal oxide layer may be the same or different. For example, the first metal oxide layer and the second metal oxide layer may be IGZO layers having different compositions.

For example, a stacked-layer structure of a first metal oxide layer having In:Zn=4:1 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed.

For example, a stacked-layer structure of any one selected from indium oxide, indium gallium oxide, and IGZO, and any one selected from IAZO, IAGZO, and ITZO (registered trademark) may be employed.

Note that when the first metal oxide layer containing a first metal oxide and the second metal oxide layer containing a second metal oxide form a stacked-layer structure and the first metal oxide and the second metal oxide have the same or substantially the same compositions, the boundary (interface) between the first metal oxide layer and the second metal oxide layer cannot clearly be observed in some cases.

It is preferable that the semiconductor layer 108 and the semiconductor layer 208 each include a metal oxide having crystallinity. Examples of the structure of a metal oxide having crystallinity include a CAAC (c-axis aligned crystal) structure, a polycrystalline structure, and a nano-crystal (nc) structure. With use of a metal oxide having crystallinity, the density of defect states in the semiconductor layer 108 and the semiconductor or layer 208 can be reduced, which enables the semiconductor device to have high reliability.

The semiconductor layer 108 and the semiconductor layer 208 are each preferably formed using a CAAC-OS or an nc-OS.

The CAAC-OS includes a plurality of layered crystals. The c-axes of the crystals are aligned in the normal direction of the formation surface. The semiconductor layer 108 and the semiconductor layer 208 each preferably include layered crystals parallel or substantially parallel to the formation surface. For example, the semiconductor layer 108 preferably includes layered crystals parallel or substantially parallel to the top surface of the conductive layer 112b in a region in contact with the top surface of the conductive layer 112b, and layered crystals parallel or substantially parallel to the side surface of the conductive layer 112b in a region in contact with the side surface of the conductive layer 112b. In particular, the semiconductor layer 108 preferably includes layered crystals parallel or substantially parallel to the side surface of the insulating layer 110, which is the formation surface, in the opening 141. With this structure, the layered crystals of the semiconductor layer 108 are formed substantially parallel to the channel length direction of the transistor 100, so that the on-state current of the transistor can be increased. Similarly, the semiconductor layer 208 preferably includes layered crystals parallel or substantially parallel to the formation surface (here, the side surface of the insulating layer 110, the side surface of the conductive layer 212a, and the side surface of the conductive layer 212b). In particular, the semiconductor layer 208 preferably includes layered crystals parallel or substantially parallel to the side surface of the insulating layer 110, which is the formation surface, in a region overlapping with the conductive layer 204.

When a metal oxide having high crystallinity is used for the channel formation region, the density of defect states in the channel formation region can be reduced. By contrast, when a metal oxide having low crystallinity is used, a transistor through which a large amount of current can flow can be achieved.

As the substrate temperature at the time of formation of the metal oxide is higher, the crystallinity of the formed metal oxide can be increased. For example, the substrate temperature at the time of formation can be adjusted by the temperature of the stage on which the substrate is placed at the time of formation. As the proportion of the flow rate of an oxygen gas to the total flow rate of the film formation gas used for formation (hereinafter also referred to as the oxygen flow rate ratio) is higher or the oxygen partial pressure in a processing chamber is higher, the crystallinity of the formed metal oxide can be increased.

The crystallinity of the semiconductor layer 108 and the semiconductor layer 208 can be analyzed with X-ray diffraction (XRD), a transmission electron microscope (TEM), electron diffraction (ED), or the like, for example. Alternatively, such kinds of analysis methods may be performed in combination.

In the case where a metal oxide is used for each of the semiconductor layer 108 and the semiconductor layer 208, V_{O}H in the channel formation region is preferably reduced as much as possible so that each of the semiconductor layer 108 and the semiconductor layer 208 becomes a highly purified intrinsic or substantially highly purified intrinsic layer. In order to obtain such a metal oxide with sufficiently reduced V_{O}H, it is important to remove impurities such as water and hydrogen in the metal oxide (this treatment is sometimes referred to as dehydration or dehydrogenation treatment) and supply oxygen to the metal oxide to repair an oxygen vacancy (V_{O}). When a metal oxide with sufficiently reduced impurities such as V_{O}H is used for a channel formation region of a transistor, the transistor can have stable electrical characteristics. Supplying oxygen to the metal oxide to repair an oxygen vacancy (V_{O}) is sometimes referred to as oxygen adding treatment.

When a metal oxide is used for each of the semiconductor layer 108 and the semiconductor layer 208, the carrier concentration in the region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration of the channel formation region is not particularly limited and can be, for example, 1×10⁻⁹ cm⁻³.

A change in electrical characteristics of an OS transistor due to radiation irradiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

The semiconductor layer 108 and the semiconductor layer 208 may each include a layered material functioning as a semiconductor. The layered substance is a general term of a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered material has high electrical conductivity in a unit layer, that is, high two-dimensional electrical conductivity. When a material that functions as a semiconductor and has a high two-dimensional electrical conduction property is used for a channel formation region, a transistor having high on-state current can be provided.

Examples of the layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a channel formation region of a transistor include molybdenum sulfide (typically MoS₂), molybdenum selenide (typically MoSe₂), molybdenum telluride (typically MoTez), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

[Conductive Layer 112a, Conductive Layer 112b, Conductive Layer 104, Conductive Layer 204, Conductive Layer 212a, and Conductive Layer 212b]

The conductive layer 112a, the conductive layer 112b, the conductive layer 104, the conductive layer 204, the conductive layer 212a, and the conductive layer 212b may each have a single-layer structure or a stacked-layer structure of two or more layers. As a material that can be used for each of the conductive layer 112a, the conductive layer 112b, the conductive layer 104, the conductive layer 204, the conductive layer 212a, and the conductive layer 212b, for example, one or more of chromium, copper, aluminum, gold, silver, zinc, tantalum, titanium, tungsten, manganese, nickel, iron, cobalt, molybdenum, and niobium, or an alloy containing one or more of these metals as its components can be given. For each of the conductive layer 112a, the conductive layer 112b, the conductive layer 104, the conductive layer 204, the conductive layer 212a, and the conductive layer 212b, a conductive material with low resistance that contains one or more of copper, silver, gold, and aluminum can be suitably used. Copper or aluminum, which is advantageous for mass production, is particularly preferable.

For each of the conductive layer 112a, the conductive layer 112b, the conductive layer 104, the conductive layer 204, the conductive layer 212a, and the conductive layer 212b, a conductive metal oxide (an oxide conductor) can be used. Examples of an oxide conductor (OC) include indium oxide, zinc oxide, In—Sn oxide (ITO), In—Zn oxide, In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. An oxide conductor containing indium is particularly preferable because of its high conduction property.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus the metal oxide becomes a conductor. The metal oxide having become a conductor can be referred to as an oxide conductor.

The conductive layer 112a, the conductive layer 112b, the conductive layer 104, the conductive layer 204, the conductive layer 212a, and the conductive layer 212b may each have a stacked-layer structure of a conductive film containing the above-described oxide conductor (metal oxide) and a conductive film containing a metal or an alloy. The use of the conductive film including a metal or an alloy can reduce the wiring resistance.

A Cu—X alloy film (X is Mn, Ni, Cr, Fe, Co, Mo, Ta, or Ti) may be used as each of the conductive layer 112a, the conductive layer 112b, the conductive layer 104, the conductive layer 204, the conductive layer 212a, and the conductive layer 212b. The use of a Cu—X alloy film leads to a reduction in manufacturing cost because the Cu—X alloy film can be processed by a wet etching method.

Note that the conductive layer 112a, the conductive layer 112b, the conductive layer 104, the conductive layer 204, the conductive layer 212a, and the conductive layer 212b may be formed using the same material or may be formed using different materials.

Each of the conductive layer 112a and the conductive layer 112b has a region that is in contact with the semiconductor layer 108. Each of the conductive layer 212a and the conductive layer 212b has a region that is in contact with the semiconductor layer 208. When the semiconductor layer 108 is formed using a metal oxide and the conductive layer 112a and the conductive layer 112b are formed using a metal that is likely to be oxidized (e.g., aluminum), an insulating oxide (e.g., aluminum oxide) is formed between the conductive layer 112a and the semiconductor layer 108 and between the conductive layer 112b and the semiconductor layer 108, which might prevent electrical continuity between the conductive layer 112a or 112b and the semiconductor layer 108. Similarly, when the semiconductor layer 208 is formed using a metal oxide and the conductive layer 212a and the conductive layer 212b are formed using a metal that is likely to be oxidized, an insulating oxide is formed between the conductive layer 212a and the semiconductor layer 208 and between the conductive layer 212b and the semiconductor layer 208, which might inhibit continuity between the conductive layer 212a or 212b and the semiconductor layer 208. Accordingly, a conductive material that is less likely to be oxidized, a conductive material that maintains low electric resistance even after being oxidized, or an oxide conductor is preferably used for the conductive layer 112a, the conductive layer 112b, the conductive layer 212a, and the conductive layer 212b.

For each of the conductive layer 112a, the conductive layer 112b, the conductive layer 112a, and the conductive layer 112b, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or materials that maintain low electric resistance even when being oxidized.

The conductive layer 112a, the conductive layer 112b, the conductive layer 212a, and the conductive layer 212b can each be formed using any of the above-described oxide conductors. Specifically, an oxide conductor such as indium oxide, zinc oxide, ITO, In—Zn oxide, In—W oxide, In—W—Zn oxide, In—Ti oxide, In—Ti—Sn oxide, In—Sn oxide containing silicon, or zinc oxide to which gallium is added can be used.

A nitride conductor may be used for each of the conductive layer 112a, the conductive layer 112b, the conductive layer 212a, and the conductive layer 212b. Examples of the nitride conductor include tantalum nitride and titanium nitride.

The conductive layer 112a, the conductive layer 112b, the conductive layer 104, the conductive layer 212a, the conductive layer 212b, and the conductive layer 204 may each have a stacked-layer structure. In that case, a conductive material that is less likely to be oxidized, a conductive material that maintains low electric resistance even when being oxidized, or an oxide conductor is preferably used for at least the region in contact with the semiconductor layer 108 and the region in contact with the semiconductor layer 208. A material with low electrical resistivity is preferably used for a region that is in contact with neither the semiconductor layer 108 nor the semiconductor layer 208. This can reduce the electric resistance of the conductive layer. For example, In—Sn—Si oxide (ITSO) can be suitably used for each of the region in contact with the semiconductor layer 108 and the region in contact with the semiconductor layer 208, and copper or tungsten can be suitably used for the region in contact with neither the semiconductor layer 108 nor the semiconductor layer 208.

### [Insulating Layer 106]

The insulating layer 106 may have either a single-layer structure or a stacked-layer structure of two or more layers. The insulating layer 106 preferably includes one or more inorganic insulating films. Examples of a material that can be used as the inorganic insulating film include an oxide, a nitride, an oxynitride, and a nitride oxide. For the insulating layer 106, a material that can be used for the insulating layer 110 can be used.

The insulating layer 106 includes a region that is in contact with the semiconductor layer 108 and the semiconductor layer 208. In the case where the semiconductor layer 108 and the semiconductor layer 208 are each formed using a metal oxide, at least the film that is included in the insulating layer 106 and in contact with the semiconductor layer 108 and the semiconductor layer 208 is preferably any of the above-described oxides and oxynitrides. It is further preferable that a film from which oxygen is released by heating be used as the insulating layer 106.

Specifically, in the case where the insulating layer 106 has a single-layer structure, an oxide or an oxynitride is preferably used for the insulating layer 106. Specifically, silicon oxide or silicon oxynitride can be suitably used for the insulating layer 106.

In the case where the insulating layer 106 has a stacked-layer structure, it is preferable that the insulating film in contact with the semiconductor layer 108 and the semiconductor layer 208 contain an oxide or an oxynitride and the insulating film in contact with the conductive layer 104 and the conductive layer 204 contain a nitride or a nitride oxide. As the oxide or the oxynitride, for example, silicon oxide or silicon oxynitride can be suitably used. As the nitride or the nitride oxide, silicon nitride or silicon nitride oxide can be suitably used.

Silicon nitride and silicon nitride oxide release a smaller amount of impurities (e.g., water and hydrogen) and are less likely to transmit oxygen and hydrogen, and thus can be suitably used for the insulating layer 106. Diffusion of impurities from the insulating layer 106 to the semiconductor layer 108 and the semiconductor layer 208 is inhibited, whereby the transistor can have favorable electrical characteristics and high reliability.

A transistor having a minute size and including a thin gate insulating layer may have a large leakage current. When a material having a high relative permittivity (also referred to as a high-k material) is used for the gate insulating layer, the voltage at the time of operation of the transistor can be reduced while the physical thickness is maintained. Examples of the high-k material that can be used for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

### [Insulating Layer 195]

It is preferable to use a material that does not easily allow diffusion of impurities for the insulating layer 195 functioning as a protective layer of the transistor 100 and the transistor 200. Providing the insulating layer 195 can effectively inhibit diffusion of impurities into the transistors from the outside and increase the reliability of the semiconductor device. Examples of the impurities include water and hydrogen.

The insulating layer 195 can be an insulating layer containing an inorganic material or an insulating layer containing an organic material. For example, an inorganic material such as an oxide, an oxynitride, a nitride oxide, or a nitride can be suitably used for the insulating layer 195. More specifically, one or more of silicon nitride, silicon nitride oxide, silicon oxynitride, aluminum oxide, aluminum oxynitride, aluminum nitride, hafnium oxide, and hafnium aluminate can be used. As the organic material, for example, one or more of an acrylic resin and a polyimide resin can be used. As the organic material, a photosensitive material may be used. A stack including two or more of the above insulating films may also be used. The insulating layer 195 may have a stacked-layer structure of an insulating layer containing an inorganic material and an insulating layer containing an organic material.

### [Substrate 102]

Although there is no great limitation on a material of the substrate 102, the substrate needs to have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. Note that the shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100 and the like. With the separation layer, part or the whole of a semiconductor device formed thereover can be separated from the substrate 102 and transferred onto another substrate. In such a case, the transistor 100 and the like can be transferred to a substrate having low heat resistance or a flexible substrate as well.

As the substrate 102, the above-described substrate over which an insulating layer is stacked may be used.

A structure example of a semiconductor device whose structure is partly different from that of Structure example 1 shown above will be described below. Note that description of the same portions as those in Structure example 1 shown above is omitted below in some cases. Furthermore, in drawings mentioned below, the same hatching pattern is applied to portions having functions similar to those in Structure example 1 shown above, and the portions are not denoted by reference numerals in some cases.

### Structure Example 2

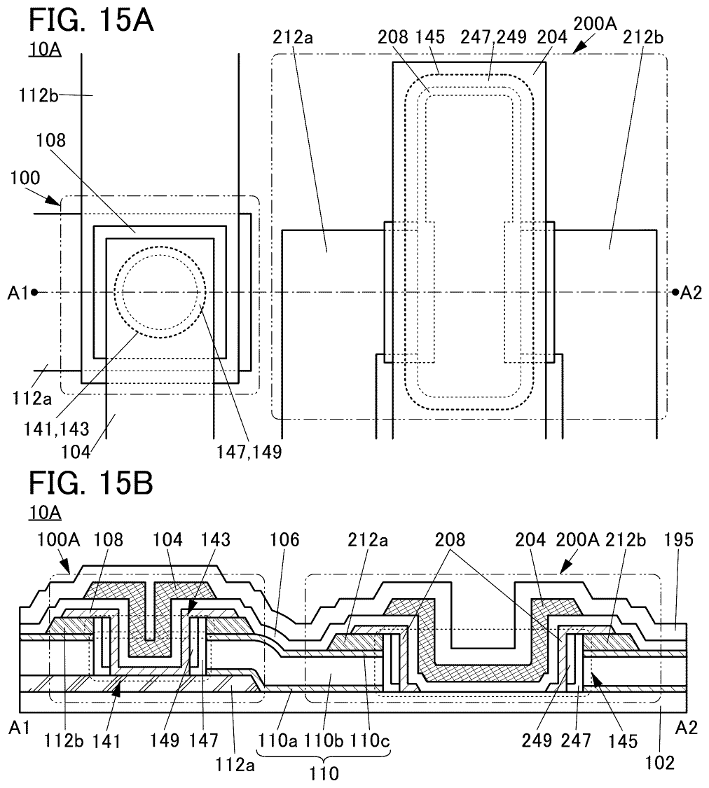

FIG. 15A is a top view of a semiconductor device 10A of one embodiment of the present invention. FIG. 15B is a cross-sectional view of a plane sectioned along the dashed-dotted line A1-A2 in FIG. 15A.

The semiconductor device 10A includes a transistor 100A, a transistor 200A, and the insulating layer 110. The transistor 100A is different from the transistor 100 illustrated in FIG. 12A and the like mainly in including insulating layer 147 and an insulating layer 149. The transistor 200A is different from the transistor 200 illustrated in FIG. 12A and the like mainly in including an insulating layer 247 and an insulating layer 249.

In the transistor 200A, the insulating layer 247 and the insulating layer 249 are provided between the insulating layer 110 and the semiconductor layer 208, between the conductive layer 212a and the semiconductor layer 208, and between the conductive layer 212b and the semiconductor layer 208.

The insulating layer 247 is in contact with the side surface of the insulating layer 110, the side surface of the conductive layer 212a, the side surface of the conductive layer 212b, the top surface of the substrate 102, the side surface and the bottom surface of the semiconductor layer 208, and the side surface and the bottom surface of the insulating layer 249. As illustrated in FIG. 15B, a protruding portion is formed in a portion of the insulating layer 247 that is in contact with the top surface of the substrate 102 in a cross-sectional view. An end portion of the protruding portion of the insulating layer 247 is in contact with the semiconductor layer 208. The protruding portion of the insulating layer 247 protrudes toward the center of the opening 145 more than the other portion of the insulating layer 247.

The insulating layer 247 preferably has a barrier property against hydrogen, and preferably has high capability of inhibiting diffusion of hydrogen, in particular. For the insulating layer 247, one or more of aluminum oxide, magnesium oxide, hafnium oxide, gallium oxide, indium gallium zinc oxide, silicon nitride, and silicon nitride oxide can be used, for example. For example, silicon nitride can be suitably used for the insulating layer 247. Providing the insulating layer 247 can inhibit diffusion of hydrogen into the semiconductor layer 208 from the outside of the transistor 200A through the insulating layer 247.

In this specification and the like, a barrier property means one or both of a function of hindering diffusion of a target substance and thereby inhibiting transmission of the target substance (also referred to as low permeability) and a function of capturing or fixing (also referred to as gettering) a target substance.

The insulating layer 249 is in contact with the side surface of the insulating layer 247, the top surface of the protruding portion of the insulating layer 247, and the side surface and the bottom surface of the semiconductor layer 208. As illustrated in FIG. 15B, the side surface of the insulating layer 249 is flush with the side end portion of the protruding portion of the insulating layer 247 in the cross-sectional view in some cases.

The insulating layer 249 preferably has a barrier property against hydrogen, and preferably has high capability of capturing or fixing (also referred to as gettering) hydrogen, in particular. For the insulating layer 249, one or more of an oxide containing magnesium and an oxide containing one or both of aluminum and hafnium can be used, for example. These oxides preferably have an amorphous structure. In such an oxide having an amorphous structure, an oxygen atom has a dangling bond and sometimes has a property of capturing or fixing hydrogen with the dangling bond. Note that these metal oxides preferably have an amorphous structure, but a crystal region may be partly formed. As the insulating layer 249, hafnium oxide can be suitably used, for example. With the insulating layer 249, hydrogen contained in the semiconductor layer 208 or the insulating layer 106 can be captured or fixed by the insulating layer 249, for example.

The semiconductor layer 208 is provided in contact with the top surface of the conductive layer 212a, the top surface of the conductive layer 212b, the top surface and the side surface of the insulating layer 247, and the top surface and the side surface of the insulating layer 249. As illustrated in FIG. 15B, the bottom surface of the semiconductor layer 208 may be in contact with the top surface of the substrate 102.

In the case where an oxide semiconductor is used for the semiconductor layer 208, providing the insulating layer 247 and the insulating layer 249 in the transistor 200A enables hydrogen, water, and the like that would be mixed into the oxide semiconductor to be removed, whereby a highly reliable semiconductor device can be provided.

In the transistor 100A, the insulating layer 147 and the insulating layer 149 are provided between the insulating layer 110 and the semiconductor layer 108 and between the conductive layer 112b and the semiconductor layer 108.

The insulating layer 147 is in contact with the side surface of the insulating layer 110, the side surface of the conductive layer 112b, the top surface of the conductive layer 112a, the side surface and the bottom surface of the semiconductor layer 108, and the side surface and the bottom surface of the insulating layer 149. As illustrated in FIG. 15B, a protruding portion is formed in a portion of the insulating layer 147 that is in contact with the top surface of the conductive layer 112a in the cross-sectional view. An end portion of the protruding portion of the insulating layer 147 is in contact with the semiconductor layer 108. The protruding portion of the insulating layer 147 protrudes toward the center of the opening 141 more than the other portion of the insulating layer 147.

For the insulating layer 147, a material that can be used for the insulating layer 247 can be used. The insulating layer 147 and the insulating layer 247 can be formed through the same steps. For example, a film to be the insulating layer 247 and the insulating layer 147 is formed and processed, so that the insulating layer 247 and the insulating layer 147 can be formed.

The insulating layer 149 is in contact with the side surface of the insulating layer 147, the top surface of the protruding portion of the insulating layer 147, and the side surface and the bottom surface of the semiconductor layer 108. As illustrated in FIG. 15B, the side surface of the insulating layer 149 is flush with the side end portion of the protruding portion of the insulating layer 147 in the cross-sectional view in some cases.

For the insulating layer 149, a material that can be used for the insulating layer 249 can be used. The insulating layer 149 and the insulating layer 249 can be formed through the same steps. For example, a film to be the insulating layer 249 and the insulating layer 149 is formed and processed, so that the insulating layer 249 and the insulating layer 149 can be formed.

The semiconductor layer 108 is provided in contact with the top surface of the conductive layer 112a, the top surface of the conductive layer 112b, the top surface and the side surface of the insulating layer 147, and the top surface and the side surface of the insulating layer 149.

Note that the structures of the insulating layer 147, the insulating layer 149, the insulating layer 247, the insulating layer 249, the semiconductor layer 108, and the semiconductor layer 208 described here can also be applied to other structure examples.

### Structure Example 3

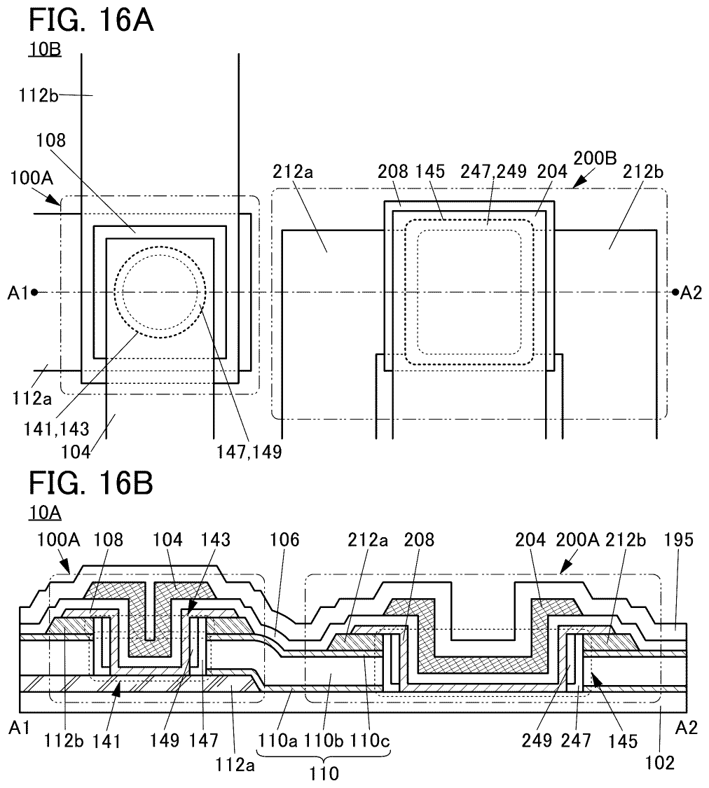

FIG. 16A is a top view of a semiconductor device 10B of one embodiment of the present invention. FIG. 16B is a cross-sectional view of a plane sectioned along the dashed-dotted line A1-A2 in FIG. 16A.

The semiconductor device 10B includes the transistor 100A, a transistor 200B, and the insulating layer 110. The transistor 200B is different from the transistor 200A illustrated in FIG. 15A and the like mainly in that the semiconductor layer 208 is provided also in the bottom portion of the opening 145. The transistor 200B employs the above-described structure of the transistor 20A.

Note that the structure of the semiconductor layer 208 described here can also be applied to other structure examples.

### Structure Example 4

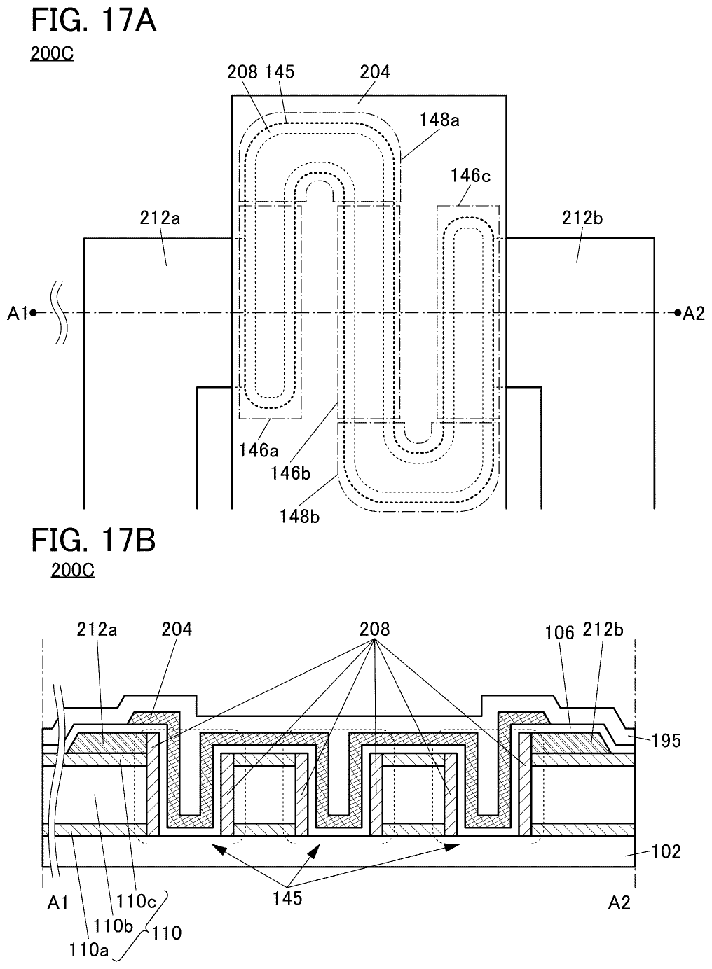

FIG. 17A is a top view of a transistor 200C of one embodiment of the present invention. FIG. 17B is a cross-sectional view of a plane sectioned along the dashed-dotted line A1-A2 in FIG. 17A.

The transistor 200C is different from the transistor 200 illustrated in FIG. 12A and the like mainly in that the opening 145 has an extending portion and a bent portion. Here, the top shape of the opening 145 formed by combining the extending portion and the bent portion can be referred to as a serpentine shape, a winding shape, a bending shape, or a meander shape.

As illustrated in FIG. 17A, the opening 145 includes an extending portion 146a, an extending portion 146b, an extending portion 146c, a bent portion 148a, and a bent portion 148b. The top surface shape of the opening 145 can be regarded as a shape in which the extending portion 146a and the extending portion 146b are connected to each other through the bent portion 148a, and the extending portion 146b and the extending portion 146c are connected to each other through the bent portion 148b. The semiconductor layer 208 is provided in contact with the side surface of the opening 145. The semiconductor layer 208 is provided to face the conductive layer 204 with the insulating layer 106 therebetween in the opening 145. Here, the semiconductor layer 208 is in contact with the conductive layer 212a in the extending portion 146a and is in contact with the conductive layer 212b in the extending portion 146b.

The extending portion 146a, the extending portion 146b, and the extending portion 146c have a shape extending in one direction (the direction perpendicular to the dashed-dotted line A1-A2 in FIG. 17A) in the top view. In contrast, the bent portion 148a and the bent portion 148b are provided such that one end portion is curved toward the other end portion in the top view.

When the two extending portions are connected to each other with one bent portion, a folded structure can be formed in the opening 145. By forming one or more of such folded shapes, the length of the opening 145 can be significantly larger than the distance between the conductive layer 212a and the conductive layer 212b. Thus, the channel length of the transistor 200C can be significantly increased, and the saturation characteristics of the transistor 200C can be further improved.

Although FIG. 17A illustrates the structure in which the opening 145 includes the extending portion 146a, the extending portion 146b, the extending portion 146c, the bent portion 148a, and the bent portion 148b, the present invention is not limited to the structure. The opening 145 preferably has a plurality of extending portions and at least one or more bent portions. Here, the number of bent portions is preferably smaller than that of the extending portions by one. For example, the opening 145 may have two extending portions and one bent portion. For another example, the opening 145 may have four or more extending portions and three or more bent portions.

Although the top surface shape of the opening 145 is a shape with rounded corners in FIG. 17A, the present invention is not limited to the shape, and the corners of the extending portion and the bent portion may be angular. In this case, the top surface shape of the opening 145 can also be referred to as a zigzag shape.

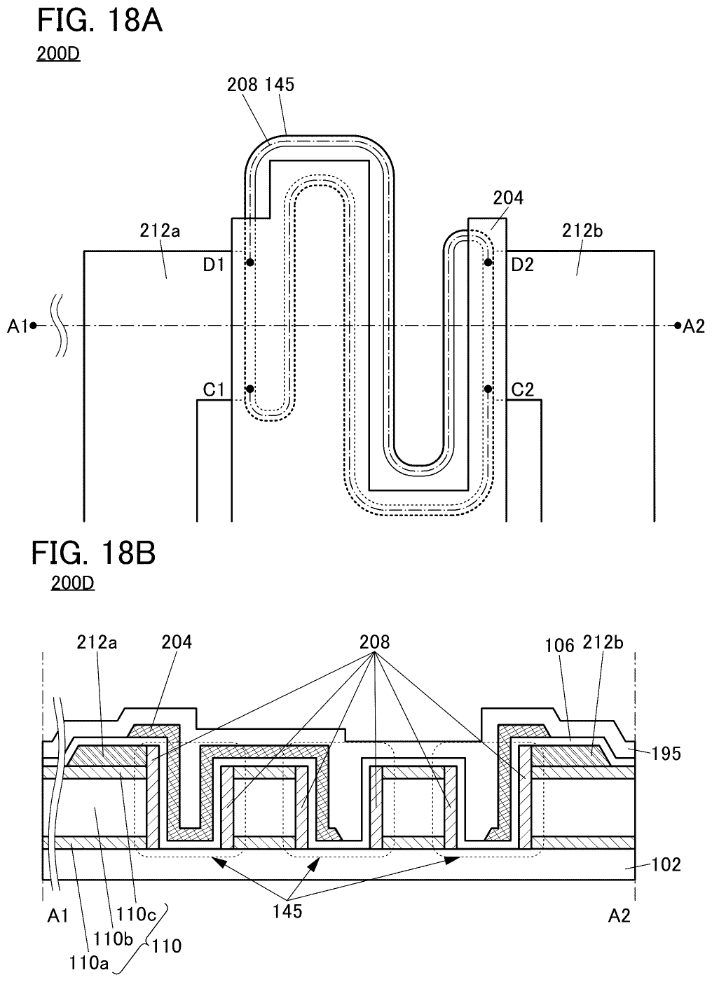

Although FIG. 17A illustrates the structure in which the conductive layer 204 covers the entire opening 145, the present invention is not limited to the structure. For example, as in a transistor 200D illustrated in FIG. 18A and FIG. 18B, the conductive layer 204 may overlap with part of the opening 145.

Here, as illustrated in FIG. 18A, the semiconductor layer 208 that connects the conductive layer 212a and the conductive layer 212b has two kinds of paths, i.e., a path represented by the dashed-dotted line C1-C2 and a path represented by the dashed-dotted line D1-D2. In the transistor in FIG. 18A, the path represented by the dashed-dotted line C1-C2 is covered with the conductive layer 204, whereas the path represented by the dashed-dotted line D1-D2 is exposed from the conductive layer 204. In a region where the conductive layer 204 is not formed, the insulating layer 195 is in contact with the top surface of the insulating layer 106. With such a structure, the layout area of the conductive layer 204 can be reduced, so that the transistors 200D can be arranged at high density.

In the transistor 200D, only the semiconductor layer 208 on the path represented by the dashed-dotted line C1-C2 functions as a channel formation region. Thus, the substantial channel width can be regarded as being approximately half that of the transistor 200C illustrated in FIG. 17A. Thus, the channel width of the transistor 200D illustrated in FIG. 18A is smaller, so that the saturation characteristics can be further improved.

Note that the structure of the opening 145 described here can also be applied to other structure examples.

### Structure Example 5

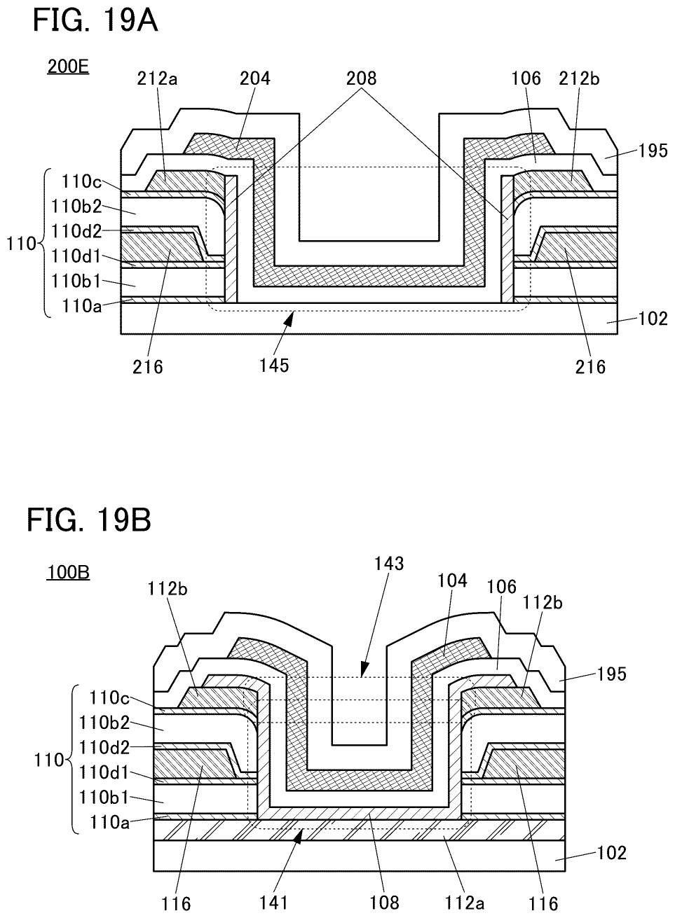

FIG. 19A is a cross-sectional view of a transistor 200E of one embodiment of the present invention. FIG. 19B is a cross-sectional view of a transistor 100B of one embodiment of the present invention.

The transistor 200E is different from the transistor 200 mainly in that a conductive layer 216 is provided between the substrate 102 and the conductive layer 212a and between the substrate 102 and the conductive layer 212b and in that the insulating layer 110 has a six-layer structure.

The insulating layer 110 includes the insulating layer 110a over the substrate 102, an insulating layer 110b1 over the insulating layer 110a, an insulating layer 110d1 over the insulating layer 110b1, an insulating layer 110d2 over the insulating layer 110d1 and the conductive layer 216, an insulating layer 110b2 over the insulating layer 110d2, and the insulating layer 110c over the insulating layer 110b2.

The conductive layer 216 functions as a back gate electrode (also referred to as a second gate electrode) of the transistor 200E. The conductive layer 216 is preferably positioned over the insulating layer 110d1. The conductive layers 212a and 212b and the conductive layer 216 are electrically insulated from each other by the insulating layers 110c, 110b2, and 110d2. The conductive layer 216 preferably has an opening, and inside the opening, the opening 145 is preferably provided.

The conductive layer 216 may be electrically connected to the conductive layer 212a or the conductive layer 212b. For example, the conductive layer 212a and the conductive layer 216 may be in contact with each other through an opening provided in the insulating layer 110d2, the insulating layer 110b2, and the insulating layer 110c.

Although FIG. 19A illustrates a structure in which the cross-sectional shape of the conductive layer 216 is a tapered shape, one embodiment of the present invention is not limited to the structure. For example, the conductive layer 216 may have a perpendicular cross-sectional shape. When the cross-sectional shape of the conductive layer 216 is perpendicular, the side surface of the conductive layer 216 is parallel to the surface of the semiconductor layer 208 in contact with the insulating layer 110. This is preferable because a potential supplied to the conductive layer 216 can be efficiently given to the semiconductor layer 208.

The conductive layer 216 may have a single-layer structure or a stacked-layer structure of two or more layers. The conductive layer 216 can be formed using any of the materials that can be used for the conductive layer 212a, the conductive layer 212b, and the conductive layer 204.

The insulating layer 110d2 covers the top surface and the side surface of the conductive layer 216. The insulating layer 110d2 is provided to cover part of the opening of the conductive layer 216. The insulating layer 110d2 is preferably in contact with the insulating layer 110d1 through the opening.

The insulating layer 110d1 and the insulating layer 110d2 preferably have structures similar to those of the insulating layers 110a and 110c. Specifically, each of the insulating layer 110d1 and the insulating layer 110d2 is preferably formed using a film that does not easily allow diffusion of oxygen. Each of the insulating layer 110d1 and the insulating layer 110d2 is preferably formed using a film that does not easily allow diffusion of hydrogen. Providing the insulating layer 110d1 and the insulating layer 110d2 in this manner can inhibit oxidation of the conductive layer 216. Furthermore, hydrogen contained in the conductive layer 216 can be inhibited from diffusing into the semiconductor layer 208.

Although FIG. 19A illustrates an example in which the thickness of the insulating layer 110d1 is uniform regardless of the place, the present invention is not limited to the example. For example, the thickness of the insulating layer 110d1 in the region that overlaps with the conductive layer 216 is sometimes different from the thickness of the insulating layer 110d1 in the region not overlapping with the conductive layer 216. For example, the insulating layer 110d1 in the region not overlapping with the conductive layer 216 is sometimes partly removed to have a reduced thickness at the time of processing of a film to be the conductive layer 216.

The insulating layer 110b2 preferably covers the top surface and the side surface of the conductive layer 216 with the insulating layer 110d2 therebetween. The insulating layer 110b2 is preferably provided to cover part of the opening in the conductive layer 216 with the insulating layer 110d2 therebetween.

The structures of the insulating layer 110b1 and the insulating layer 110b2 can each be similar to the structure applicable to the insulating layer 110b. Specifically, it is preferable that each of the insulating layer 110b1 and the insulating layer 110b2 be formed using a layer containing oxygen and include a region having a higher oxygen content than at least one of the insulating layer 110a, the insulating layer 110c, the insulating layer 110d1, and the insulating layer 110d2.

This structure enables the insulating layer 110 to be vertically symmetric with respect to the conductive layer 216. Furthermore, oxygen can be supplied to the semiconductor layer 208 from both the insulating layers 110b1 and 110b2; thus, the transistor can have improved characteristics.

Note that the present invention is not limited to the above, and a structure in which the insulating layer 110b1 is not provided can be employed, for example. Alternatively, a structure in which the insulating layer 110d1 and the insulating layer 110d2 are not provided can be employed.

In the transistor 200E, the semiconductor layer 208 includes a region overlapping with the conductive layer 204 with the insulating layer 106 therebetween and a region overlapping with the conductive layer 216 with parts (specifically, the insulating layer 110b2 and the insulating layer 110d2) of the insulating layer 110 therebetween. In other words, at least part of the semiconductor layer 208 is sandwiched between the side surface of the conductive layer 204 and the side surface of the conductive layer 216, parts of the insulating layer 110 (in particular, the insulating layer 110b2 and the insulating layer 110d2) are provided between at least part of the semiconductor layer 208 and the side surface of the conductive layer 204, and the insulating layer 106 is provided between at least part of the semiconductor layer 208 and the side surface of the conductive layer 216. Part of the insulating layer 110 functions as a back gate insulating layer (also referred to as a second gate insulating layer) of the transistor 200C.

Since a back gate is provided in the transistor 200E, the potential of the semiconductor layer 208 on the back gate side (also referred to as a back channel) can be fixed. Thus, the saturation characteristics of the I_{d}-V_{d} characteristics of the transistor 200E can be improved.

Since the transistor 200E includes the back gate electrode; thus, the potential of the back channel of the semiconductor layer 208 can be fixed and a negative shift of the threshold voltage can be inhibited. Accordingly, the transistor can have normally-off characteristics (i.e., a positive threshold voltage value).

In a region of the transistor 200E, the conductive layer 216, the insulating layer 110, the semiconductor layer 208, the insulating layer 106, and the conductive layer 204 are stacked in this order in one direction with no any other layer provided between these layers. When the above region is enlarged, the electric field applied to the back channel of the semiconductor layer 208 can be controlled more reliably.

In a cross-sectional view, the shortest distances between the conductive layer 216 and the semiconductor layer 208 may be different between the right side and the left side of the opening in the insulating layer 110.

As in the transistor 200E, the transistor 100 can be provided with a back gate. The transistor 100B illustrated in FIG. 19B is different from the transistor 100 mainly in that the conductive layer 116 is provided between the conductive layer 112a and the conductive layer 112b and the insulating layer 110 has a six-layer structure. Although FIG. 19B illustrates a structure in which the cross-sectional shape of the conductive layer 116 is a tapered shape, one embodiment of the present invention is not limited to the structure. For example, the conductive layer 116 may be placed so as to have a perpendicular cross-sectional shape. By the placement in this manner, the side surface of the conductive layer 116 is parallel to the surface of the semiconductor layer 208 in contact with the insulating layer 110. This placement is preferable because a potential supplied to the conductive layer 116 can be efficiently given to the semiconductor layer 208.

Here, the conductive layer 116 corresponds to the conductive layer 216, and the description of the conductive layer 216 can be referred to. In other words, the conductive layer 116 functions as a back gate electrode of the transistor 100B. The insulating layer 110 has a structure similar to that of the insulating layer 110 illustrated in FIG. 19A. In other words, part of the insulating layer 110 functions as a back gate insulating layer of the transistor 100B.

Thus, also in the transistor 100B, the semiconductor layer 108 includes a region overlapping with the conductive layer 104 with the insulating layer 106 therebetween and a region overlapping with the conductive layer 116 with parts (specifically, the insulating layer 110b2 and the insulating layer 110d2) of the insulating layer 110. In other words, at least part of the semiconductor layer 108 is sandwiched between the side surface of the conductive layer 104 and the side surface of the conductive layer 116, parts of the insulating layer 110 (in particular, the insulating layer 110b2 and the insulating layer 110d2) is provided between at least part of the semiconductor layer 108 and the side surface of the conductive layer 104, and the insulating layer 106 is provided between at least part of the semiconductor layer 108 and the side surface of the conductive layer 116.

Since a back gate is provided in the transistor 100B, the potential of the semiconductor layer 108 on the back gate side (also referred to as a back channel) can be fixed. Thus, the saturation characteristics of the I_{d}-V_{d} characteristics of the transistor 200B can be improved.

Since the transistor 100B includes the back gate electrode; thus, the potential of the back channel of the semiconductor layer 108 can be fixed and a negative shift of the threshold voltage can be inhibited. Accordingly, the transistor can have normally-off characteristics (i.e., a positive threshold voltage value).

Note that the structures of the conductive layer 216 and the insulating layer 110 described here can also be applied to other structure examples.

This embodiment can be combined with any of the other embodiments as appropriate. In this specification, in the case where a plurality of structure examples are shown in one embodiment, the structure examples can be combined as appropriate.

### Embodiment 3

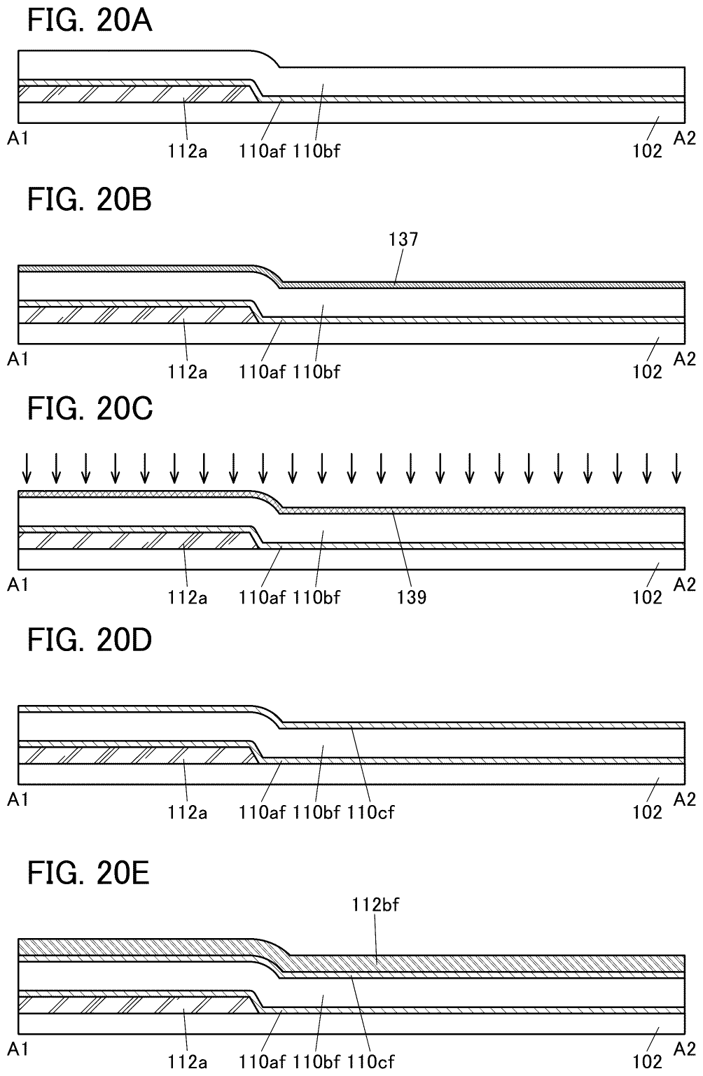

In this embodiment, a method for manufacturing a semiconductor device that is one embodiment of the present invention is described with reference to FIG. 20A to FIG. 30. Note that as for a material and a formation method of each component, portions similar to the portions described in Embodiment 2 are not described in some cases.

Thin films (e.g., insulating films, semiconductor films, and conductive films) included in the semiconductor device can be formed by a sputtering method, a chemical vapor deposition (CVD) method, a vacuum evaporation method, a pulsed laser deposition (PLD) method, an ALD method, a molecular beam epitaxy (MBE) method or the like. Examples of the CVD method include a PECVD method and a thermal CVD method. As an example of the thermal CVD method, a metal organic chemical vapor deposition (MOCVD: Metal Organic CVD) method is given.

The thin films (e.g., insulating films, semiconductor films, and conductive films) included in the semiconductor device can be formed by a wet film formation method such as spin coating, dipping, spray coating, inkjetting, dispensing, screen printing, offset printing, a doctor knife method, slit coating, roll coating, curtain coating, or knife coating.

When the thin films included in the semiconductor device are processed, a photolithography method or the like can be used. Alternatively, the thin films may be processed by a nanoimprinting method, a sandblasting method, a lift-off method, or the like. Alternatively, island-shaped thin films may be directly formed by a film formation method using a shielding mask such as a metal mask.

Two typical examples of a photolithography method are given below. In one of the methods, a resist mask is formed over a thin film to be processed, the thin film is processed by etching or the like, and then the resist mask is removed. In the other method, after a photosensitive thin film is formed, light exposure and development are performed, so that the thin film is processed into a desired shape.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet light, KrF laser light, ArF laser light, or the like can be used. The light exposure may be performed by liquid immersion exposure technique. As the light used for the light exposure, extreme ultraviolet (EUV) light or X-rays may be used. Instead of the light used for the light exposure, an electron beam can be used. Extreme ultraviolet light, X-rays, or an electron beam is preferably used, in which case extremely minute processing can be performed. Note that a photomask is not needed when the light exposure is performed by scanning with a beam such as an electron beam.

For etching of thin films, one or more of a dry etching method, a wet etching method, and a sandblast method can be used.

### Example 1 of Manufacturing Method

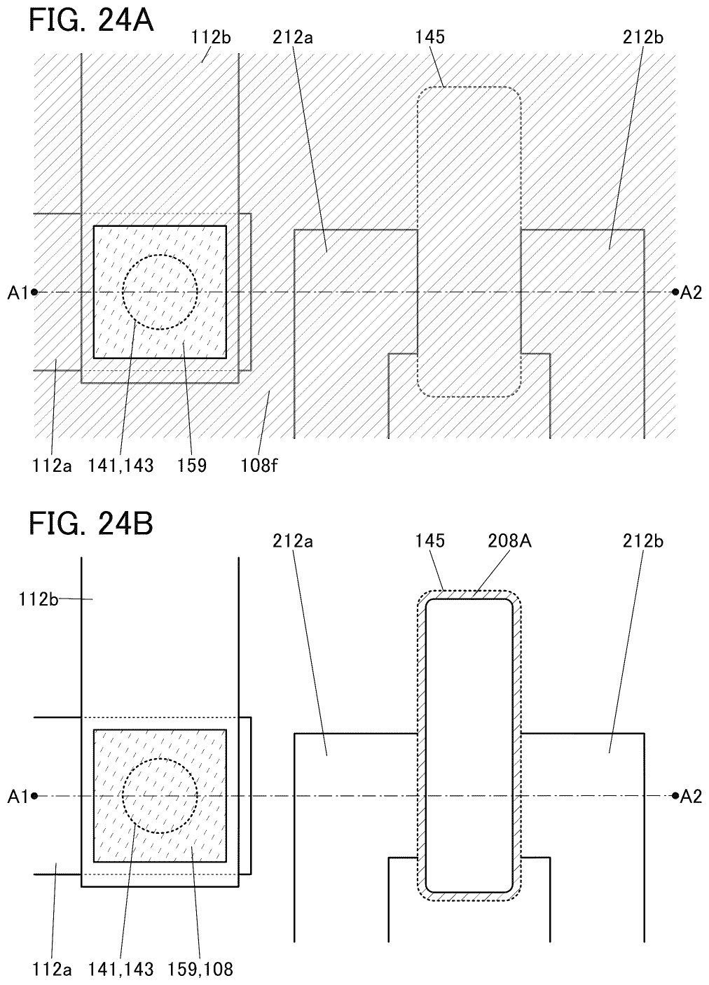

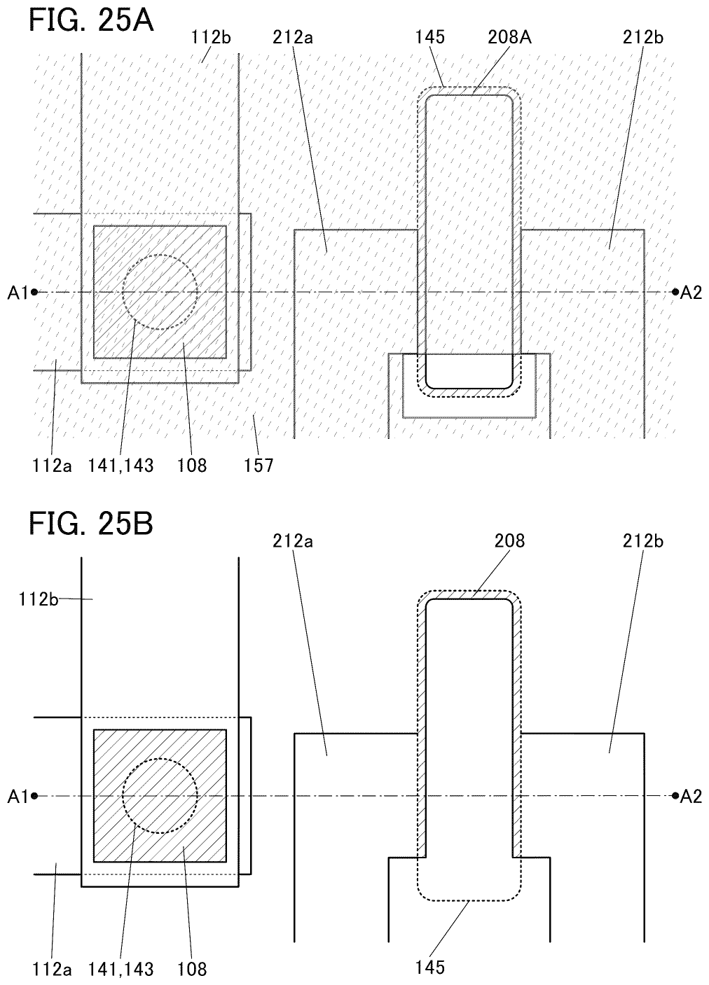

An example of a method for manufacturing the semiconductor device 10 illustrated in FIG. 12A and FIG. 12B is described with reference to FIG. 20A to FIG. 25B. FIG. 20A to FIG. 23B are cross-sectional views each taken along the dashed-dotted line A1-A2 in FIG. 12A. FIG. 24A to FIG. 25B are top views.

First, a film to be the conductive layer 112a is formed over the substrate 102, and the film is processed to form the conductive layer 112a. A sputtering method can be suitably used for the formation of the film.

Next, an insulating film 110af to be the insulating layer 110a and an insulating film 110bf to be the insulating layer 110b are formed over the substrate 102 and the conductive layer 112a (FIG. 20A).

A sputtering method or a PECVD method can be suitably used for the formation of the insulating film 110af and the insulating film 110bf. It is preferable that the insulating film 110bf be formed in a vacuum successively after the formation of the insulating film 110af, without exposure of a surface of the insulating film 110af to the air. By forming the insulating film 110af and the insulating film 110bf successively, attachment of impurities derived from the air to the surface of the insulating film 110af can be inhibited. Examples of the impurities include water and organic substances.

The substrate temperatures at the time of forming the insulating film 110af and the insulating film 110bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperature at the time of forming the insulating film 110af and the insulating film 110bf is in the above range, the amount of impurities (e.g., water and hydrogen) released from the insulating films themselves can be reduced, which inhibits the diffusion of the impurities to the semiconductor layer 108. Thus, the transistor can have favorable electrical characteristics and high reliability.

In addition, since the insulating film 110af and the insulating film 110bf are formed earlier than the semiconductor layer 108 and the semiconductor layer 208, there is no need to consider the probability of oxygen release from the semiconductor layer 108 and the semiconductor layer 208 due to heat applied at the time of forming the insulating film 110af and the insulating film 110bf.

After the insulating film 110bf is formed, oxygen may be supplied to the insulating film 110bf. As a method for supplying oxygen, an ion implantation method, an ion doping method, a plasma immersion ion implantation method, or plasma treatment can be used, for example. For the plasma treatment, an apparatus in which an oxygen gas is brought into a plasma state by high-frequency power can be suitably used. Examples of the apparatus in which a gas is brought into a plasma state by high-frequency power include a PECVD apparatus, a plasma etching apparatus, and a plasma ashing apparatus. The plasma treatment is preferably performed in an atmosphere containing oxygen. For example, the plasma treatment is preferably performed in an atmosphere containing one or more of oxygen, dinitrogen monoxide (N₂O), nitrogen dioxide (NO₂), carbon monoxide, and carbon dioxide.

Note that the plasma treatment may be successively performed in a vacuum without exposure of the surface of the insulating film 110bf to the air. For example, in the case where a PECVD apparatus is used to form the insulating film 110bf, the plasma treatment is preferably performed with the PECVD apparatus. Accordingly, the productivity can be increased. Specifically, after the insulating film 110bf is formed with the PECVD apparatus, N₂O plasma treatment can be successively performed in a vacuum.

Next, the metal oxide layer 137 is preferably formed over the insulating film 110bf (FIG. 20B). The formation of the metal oxide layer 137 enables oxygen supply to the insulating film 110bf.

There is no limitation on the conductivity of the metal oxide layer 137. As the metal oxide layer 137, at least one of an insulating film, a semiconductor film, and a conductive film can be used. For the metal oxide layer 137, aluminum oxide, hafnium oxide, hafnium aluminate, indium oxide, indium tin oxide (ITO), or indium tin oxide containing silicon (ITSO) can be used, for example.

For the metal oxide layer 137, an oxide material containing one or more elements that are the same as those of the semiconductor layer 108 and the semiconductor layer 208 is preferably used. It is particularly preferable to use a metal oxide semiconductor material that can be used for the semiconductor layer 108 and the semiconductor layer 208.

At the time of forming the metal oxide layer 137, the amount of oxygen supplied into the insulating film 110bf can be increased with a higher oxygen flow rate ratio of the film formation gas introduced into a processing chamber of a film formation apparatus or with a higher oxygen partial pressure in the processing chamber. The oxygen flow rate ratio or oxygen partial pressure is, for example, set to higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 137 is formed by a sputtering method in an atmosphere containing oxygen in the above manner, oxygen can be supplied to the insulating film 110bf and release of oxygen from the insulating film 110bf can be prevented at the time of the formation of the metal oxide layer 137. As a result, a large amount of oxygen can be enclosed in the insulating film 110bf. Moreover, a large amount of oxygen can be supplied to the semiconductor layer 108 by heat treatment performed later. Consequently, oxygen vacancies and V_{O}H in the semiconductor layer 108 can be reduced, whereby a transistor with favorable electrical characteristics and high reliability can be obtained.

After the metal oxide layer 137 is formed, heat treatment may be performed. By performing the heat treatment after the metal oxide layer 137 is formed, oxygen can be effectively supplied from the metal oxide layer 137 to the insulating film 110bf.

The heat treatment temperature is preferably higher than or equal to 150° C., higher than or equal to 200° C., higher than or equal to 230° C., or higher than or equal to 250° C. and lower than the strain point of the substrate, lower than or equal to 450° C., lower than or equal to 400° C., lower than or equal to 350° C., or lower than or equal to 300° C. The heat treatment can be performed in an atmosphere containing one or more of a noble gas, nitrogen, and oxygen. As an atmosphere containing nitrogen or an atmosphere containing oxygen, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With use of an atmosphere where the content of hydrogen, water, or the like is as low as possible, entry of hydrogen, water, or the like into the insulating film 110af and the insulating film 110bf can be prevented as much as possible. An oven, a rapid thermal annealing (RTA) apparatus, or the like can be used for the heat treatment. The use of the RTA apparatus can shorten the heat treatment time.

After the formation of the metal oxide layer 137 or after the above-described heat treatment, oxygen may be further supplied to the insulating film 110bf through the metal oxide layer 137. As a method for supplying oxygen, an ion implantation method, an ion doping method, a plasma immersion ion implantation method, or plasma treatment can be used, for example. The above description can be referred to for the plasma treatment; thus, the detailed description thereof is omitted.

Then, the metal oxide layer 137 is removed. There is no particular limitation on a method for removing the metal oxide layer 137, and a wet etching method can be suitably used. With use of a wet etching method, the insulating film 110bf can be inhibited from being etched at the time of the removal of the metal oxide layer 137. This can inhibit a reduction in the thickness of the insulating film 110bf and the thickness of the insulating layer 110b can be uniform.

After the metal oxide layer 137 is removed, oxygen may be further supplied to the insulating film 110bf. The above description can be referred to for a method for supplying oxygen. For example, as illustrated in FIG. 20C, a film 139 may be formed over the insulating film 110bf, and oxygen may be supplied to the insulating film 110bf may be performed through the film 139. As the treatment, plasma treatment in an atmosphere containing oxygen can be performed. FIG. 20C schematically illustrates a state where oxygen is supplied to the insulating film 110bf, which is indicated by arrows.

As the film 139, a conductive film or a semiconductor film is preferably used. As the film 139, a metal oxide film, a metal film, or an alloy film can be used. When the film 139 is formed using a metal oxide in an atmosphere containing oxygen by a sputtering method or the like, oxygen can be supplied to the insulating film 110bf also at the time of forming the film 139, which is preferable.

The thickness of the film 139 is preferably small. Specifically, the thickness of the film 139 is preferably greater than or equal to 1 nm, greater than or equal to 2 nm, or greater than or equal to 3 nm and less than or equal to 20 nm, less than or equal to 15 nm, or less than or equal to 10 nm. Typically, the thickness can be approximately 5 nm.

The substrate temperature at the time of forming the film 139 is preferably lower than or equal to 350° C., further preferably lower than or equal to 340° C., still further preferably lower than or equal to 330° C., yet still further preferably lower than or equal to 300° C. Thus, a large amount of oxygen can be supplied to the insulating film 110bf.

With the film 139, when a bias voltage is applied between the pair of electrodes in oxygen supply, ionized oxygen is easily drawn. Accordingly, a large amount of oxygen can be supplied to the insulating film 110bf.

As a treatment apparatus used for oxygen supply, a dry etching apparatus, an ashing apparatus, or a PECVD apparatus can be suitably used. In particular, an ashing apparatus is preferably used. When a bias voltage is applied between a pair of electrodes included in the treatment apparatus, the bias voltage is set to higher than or equal to 10 V and lower than or equal to 1 kV, for example. Alternatively, the power density of the bias is set to higher than or equal to 1 W/cm² and lower than or equal to 5 W/cm², for example.

Next, the film 139 is removed. A wet etching method can be suitably used to remove the film 139.

The treatment for supplying oxygen to the insulating film 110bf is not limited to the above-described method. An oxygen radical, an oxygen atom, an oxygen atomic ion, or an oxygen molecular ion is supplied to the insulating film 110bf by an ion doping method, an ion implantation method, or plasma treatment, for example. Alternatively, a film that inhibits oxygen release may be formed over the insulating film 110bf, and then oxygen may be supplied to the insulating film 110bf through the film. It is preferable to remove the film after supply of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

Next, an insulating film 110cf to be the insulating layer 110c is formed over the insulating film 110bf (FIG. 20D). The description of the formation of the insulating film 110af and the insulating film 110bf can be referred to for the formation of the insulating film 110cf; thus, the detailed description thereof is omitted.

Then, the conductive film 112bf to be the conductive layer 112b, the conductive layer 212a, and the conductive layer 212b is formed over the insulating film 110cf (FIG. 20E). For the formation of the conductive film 112bf, a sputtering method can be suitably used, for example.

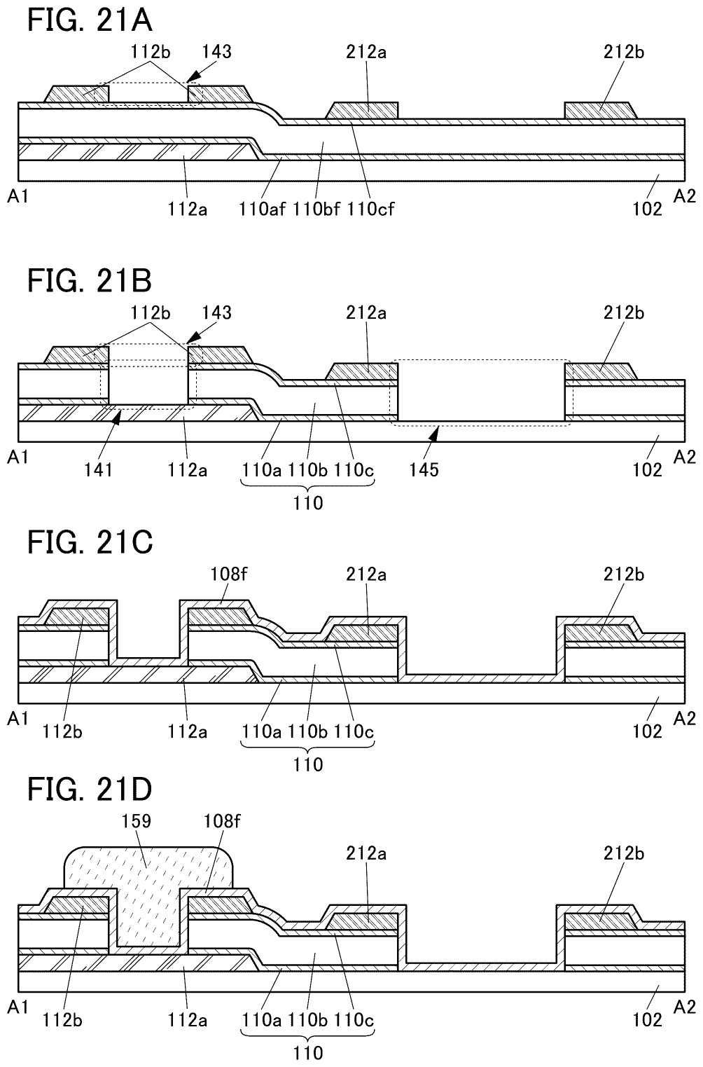

Subsequently, the conductive film 112bf is processed to form the conductive layer 112b, the conductive layer 212a, and the conductive layer 212b (FIG. 21A). For example, a wet etching method can be suitably used for formation of the conductive layer 112b, the conductive layer 212a, and the conductive layer 212b.

Next, part of the insulating film 110af, part of the insulating film 110bf, and part of the insulating film 110cf are removed, so that the insulating layer 110 including the opening 141 and the opening 145 is formed (FIG. 21B). The opening 141 is provided in a region overlapping with the opening 143. The conductive layer 112a is exposed by the formation of the opening 141, and the substrate 102 is exposed by the formation of the opening 145. For the formation of the insulating layer 110, a dry etching method can be suitably used, for example.

Note that in the formation of the opening 141 or after the formation of the opening 141, part of the conductive layer 112a in a region overlapping with the opening 141 may be removed. When the thickness of the region of the conductive layer 112a that is in contact with the bottom surface of the semiconductor layer 108 is smaller than the thickness of the region of the conductive layer 112a that is not in contact with the semiconductor layer 108, the electric field of the gate electrode applied to the channel formation region in the vicinity of the conductive layer 112a can be increased and the on-state current of the transistor can be increased.

Next, a metal oxide film 108f to be the semiconductor layer 108 and the semiconductor layer 208 is formed so as to cover the opening 141, the opening 143 and the opening 145 (FIG. 21C). The metal oxide film 108f is provided in contact with the top surface and the side surface of the conductive layer 112b, the top surface and the side surface of the insulating layer 110, the top surface of the conductive layer 112a, the top surface and the side surface of the conductive layer 212a, the top surface and the side surface of the conductive layer 212b, and the top surface of the substrate 102.

The metal oxide film 108f is preferably formed by a sputtering method using a metal oxide target. Alternatively, the metal oxide film 108f is preferably formed by an ALD method. An ALD method offers high coverage and thus can be suitably used for forming the metal oxide film 108f provided to cover the opening 141, the opening 143, and the opening 145. With use of an ALD method, a metal oxide film can be formed also on the side surface of the insulating layer 110 with high coverage. In an ALD method, the film formation rate can be easily controlled, so that a thin film can be formed with high yield.

The metal oxide film 108f is preferably a dense film with as few defects as possible. The metal oxide film 108f is preferably a highly purified film in which impurities including a hydrogen element are reduced as much as possible. It is particularly preferable to use a metal oxide film having crystallinity as the metal oxide film 108f.

In forming the metal oxide film 108f, an oxygen gas is preferably used. With use of an oxygen gas, oxygen can be suitably supplied into the insulating layer 110. For example, in the case of using an oxide or an oxynitride for the insulating layer 110b, oxygen can be suitably supplied into the insulating layer 110b.

By the supply of oxygen to the insulating layer 110b, oxygen is supplied to the channel formation regions in the semiconductor layer 108 and the semiconductor layer 208 in a later step, so that oxygen vacancies and V_{O}H in the channel formation regions can be reduced.

In forming the metal oxide film 108f, an oxygen gas and an inert gas (e.g., a helium gas, an argon gas, or a xenon gas) may be mixed. Note that when the oxygen flow rate ratio or the oxygen partial pressure in the processing chamber is high at the time of forming the metal oxide film, the metal oxide film can have increased crystallinity and the transistor can have higher reliability. On the other hand, when the oxygen flow rate ratio or the oxygen partial pressure is low, the metal oxide film can have lower crystallinity and a higher electrical conduction property, and a transistor with a higher on-state current can be obtained.

Here, when the oxygen flow rate ratio or the oxygen partial pressure is high, the metal oxide film may have a polycrystalline structure. In the case where the metal oxide film has a polycrystalline structure, the crystal grain boundary becomes a recombination center and captures carriers and thus decreases the on-state current of the transistor in some cases. Therefore, the oxygen flow rate ratio or the oxygen partial pressure is preferably adjusted so that the metal oxide film 108f does not have a polycrystalline structure. Since the ease of forming a polycrystalline structure depends on the composition of the metal oxide film, the oxygen flow rate ratio or the oxygen partial pressure is adjusted in accordance with the composition of the metal oxide film 108f.

As the substrate temperature in forming the metal oxide film is higher, a denser metal oxide film having higher crystallinity can be formed. On the other hand, as the substrate temperature is lower, a metal oxide film having lower crystallinity and a higher electrical conduction property can be formed.

The substrate temperature at the time of forming the metal oxide film 108f is preferably higher than or equal to room temperature and lower than or equal to 250° C., further preferably higher than or equal to room temperature and lower than or equal to 200° C., still further preferably higher than or equal to room temperature and lower than or equal to 140° C. For example, when the substrate temperature is higher than or equal to room temperature and lower than or equal to 140° C., high productivity is achieved, which is preferable. Furthermore, when the metal oxide film 108f is formed with the substrate temperature set at room temperature or without heating the substrate, the crystallinity can be made low.

When the substrate temperature is high, the metal oxide film may have a polycrystalline structure. The substrate temperature is preferably adjusted so that the metal oxide film 108f does not have a polycrystalline structure. The substrate temperature is adjusted in accordance with the composition applied to the metal oxide film 108f.

In the case of using an ALD method, a film formation method such as a thermal ALD method or PEALD (Plasma Enhanced ALD) is preferably used. The thermal ALD method offering extremely high coverage is preferable. The PEALD method enabling film formation at low temperatures as well as high coverage is preferable.

For example, the metal oxide film can be formed by an ALD method using a precursor containing a constituent metal element and an oxidizer.

For example, in the case where In—Ga—Zn oxide is formed, three precursors of a precursor containing indium, a precursor containing gallium, and a precursor containing zinc can be used. Alternatively, two precursors of a precursor containing indium and a precursor containing gallium and zinc may be used.

Examples of the precursor containing indium include triethylindium, tris(2,2,6,6-tetramethyl-3,5-heptanedionato) indium, cyclopentadienylindium, indium(III) chloride, and (3-(dimethylamino) propyl)dimethylindium.

As examples of the precursor containing gallium, trimethylgallium, triethylgallium, tris(dimethylamido)gallium(III), gallium(III) acetylacetonate, tris(2,2,6,6-tetramethyl-3,5-heptanedionato)gallium, dimethylchlorogallium, diethylchlorogallium, and gallium(III) chloride can be given.

Examples of the precursor containing zinc include dimethylzinc, diethylzinc, bis(2,2,6,6-tetramethyl-3,5-heptanedionato) zinc, and zinc chloride.

Examples of the oxidizer include ozone, oxygen, and water.

As a method for controlling the composition of a film to be obtained, adjusting one or more of the kinds of source gases, the flow rate ratio of source gases, the flowing time of the source gases, and the order in which the source gases flow is given. By adjusting these, the composition of the metal oxide film 108f can be controlled. Moreover, by adjusting these, a film whose composition is continuously changed can be formed. The composition of the metal oxide film 108f may be continuously changed.

It is preferable to perform, before the formation of the metal oxide film 108f, at least one of treatment for desorbing water, hydrogen, an organic substance, and the like adsorbed onto the surface of the insulating layer 110 and treatment for supplying oxygen into the insulating layer 110. For example, heat treatment can be performed at a temperature higher than or equal to 70° C. and lower than or equal to 200° C. in a reduced-pressure atmosphere. Alternatively, plasma treatment may be performed in an atmosphere containing oxygen. Alternatively, oxygen may be supplied to the insulating layer 110 by plasma treatment in an atmosphere containing an oxidizing gas such as dinitrogen monoxide (N₂O). Performing plasma treatment including a dinitrogen monoxide gas can supply oxygen while suitably removing an organic substance on the surface of the insulating layer 110. It is preferable that the metal oxide film 108f be formed successively after such treatment, without exposure of the surface of the insulating layer 110 to the air.

In the case where each of the semiconductor layer 108 and the semiconductor layer 208 is formed to have a stacked-layer structure, an upper metal oxide film is preferably formed successively after the formation of a lower metal oxide film without exposure of a surface of the lower metal oxide film to the air.

In the case where the semiconductor layer 108 and the semiconductor layer 208 have a stacked-layer structure, all the layers included in the semiconductor layer 108 and the semiconductor layer 208 may be formed by the same film formation method (e.g., a sputtering method or an ALD method) or the layers may be formed by different film formation methods. For example, the first metal oxide layer may be formed by a sputtering method, and the second metal oxide layer may be formed by an ALD method.

Then, a resist mask 159 is formed over the metal oxide film 108f (FIG. 21D and FIG. 24A). The resist mask 159 is provided in a region where the semiconductor layer 108 is formed so as to cover at least the opening 141 and the opening 143. Note that in FIG. 24A, the metal oxide film 108f and the resist mask 159 are shown with hatching patterns. For the sake of easy understanding of the structure below the metal oxide film 108f, the hatching pattern of the metal oxide film 108f is seen through.

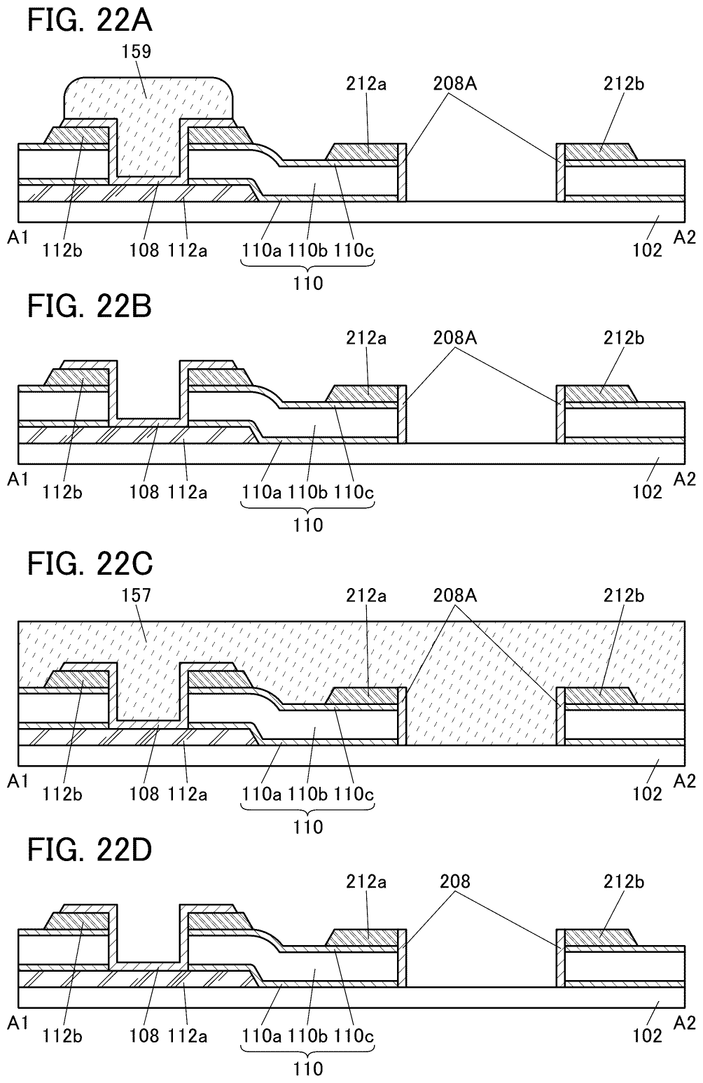

Subsequently, the metal oxide film 108f is processed into an island shape to form the semiconductor layer 108 and a semiconductor layer 208A to be the semiconductor layer 208 (FIG. 22A and FIG. 24B). For the formation of the semiconductor layer 108 and the semiconductor layer 208A, a dry etching method can be suitably used. For the formation of the semiconductor layer 108 and the semiconductor layer 208A, an anisotropic dry etching method can be suitably used. The semiconductor layer 108 is formed in a region of the metal oxide film 108f covered with the resist mask 159, and the semiconductor layer 208A is formed in a region in contact with the side surface of the opening 145. Note that in FIG. 24B, the resist mask 159 and the semiconductor layer 208A are shown with hatching patterns.

Next, the resist mask 159 is removed (FIG. 22B).

Next, a resist mask 157 is formed over the semiconductor layer 108, the semiconductor layer 208A, the conductive layer 112b, the conductive layer 212a, the conductive layer 212b, the insulating layer 110, and the substrate 102 (FIG. 22C and FIG. 25A). The resist mask 157 is provided to cover at least the semiconductor layer 108 and the semiconductor layer 208A in a region to be the semiconductor layer 208. At this time, the semiconductor layer 208A in a region where the semiconductor layer 208 is not provided is exposed. In FIG. 25A, the semiconductor layer 108, the semiconductor layer 208A, and the resist mask 157 are shown with hatching patterns. For the sake of easy understanding of the structure below the resist mask 157, the hatching pattern of the resist mask 157 is seen through.

Next, the semiconductor layer 208A in a region not covered with the resist mask 157 is removed, so that the semiconductor layer 208 is formed. For the formation of the semiconductor layer 208, one or both of a wet etching method and a dry etching method can be used. In particular, a dry etching method can be suitably used.

Next, the resist mask 157 is removed (FIG. 22D and FIG. 25B). In FIG. 25B, the semiconductor layer 108 and the semiconductor layer 208 are shown with hatching patterns.

It is preferable that heat treatment be performed after the metal oxide film 108f is formed or after the metal oxide film 108f is processed into the semiconductor layer 108 and the semiconductor layer 208. By the heat treatment, hydrogen and water contained in the metal oxide film 108f or the semiconductor layer 108 and the semiconductor layer 208 or adsorbed onto the surface thereof can be removed. Furthermore, the film quality of the metal oxide film 108f or the semiconductor layer 108 and the semiconductor layer 208 is improved (e.g., the number of defects is reduced or the crystallinity is increased) by the heat treatment in some cases.

Oxygen can be supplied from the insulating layer 110b to the metal oxide film 108f or the semiconductor layer 108 by heat treatment. Thus, oxygen vacancies (V_{O}) and V_{O}H in the channel formation region can be reduced. In this case, it is further preferable that the heat treatment be performed before the metal oxide film 108f is processed into the semiconductor layer 108 and the semiconductor layer 208. The above description can be referred to for the heat treatment; thus, the detailed description thereof is omitted. Note that supply of oxygen to the channel formation region may be performed not only through the heat treatment but also in a heat application step in and after the formation of the metal oxide film 108f (e.g., the step of forming the insulating layer 106).

Note that the heat treatment is not necessarily performed. The heat treatment in this step may be omitted, and heat treatment performed in a later step may also function as the heat treatment in this step. In some cases, heat application treatment in a later step (e.g., a film formation step) or the like can serve as the heat treatment in this step.

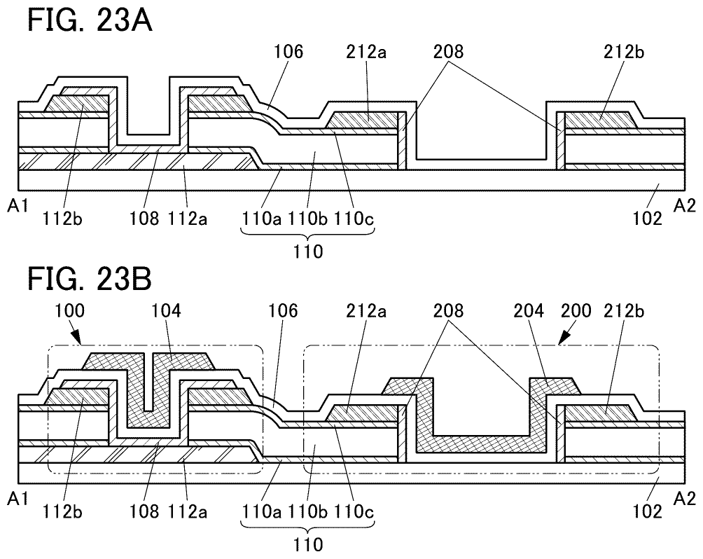

Next, the insulating layer 106 is formed so as to cover the semiconductor layer 108, the semiconductor layer 208, the insulating layer 110, and the substrate 102 (FIG. 23A). For the formation of the insulating layer 106, for example, a PECVD method or an ALD method can be suitably used.

In the case of using a metal oxide for the semiconductor layer 108 and the semiconductor layer 208, the insulating layer 106 preferably functions as a barrier film that inhibits diffusion of oxygen. When the insulating layer 106 has a function of inhibiting diffusion of oxygen, oxygen contained in the semiconductor layer 108 and the semiconductor layer 208 is inhibited from diffusing to above the insulating layer 106, and an increase in oxygen vacancies (V_{O}) in the semiconductor layer 108 and the semiconductor layer 208 can be inhibited. Consequently, the transistor can have favorable electrical characteristics and high reliability.

Note that in this specification and the like, a barrier film refers to a film having a barrier property. For example, an insulating layer having a barrier property can be referred to as a barrier insulating layer.

By increasing the temperature at the time of forming the insulating layer 106 functioning as the gate insulating layer, the insulating layer including few defects can be obtained. However, the high temperature at the time of forming the insulating layer 106 sometimes allows release of oxygen from the semiconductor layer 108 and the semiconductor layer 208, which increases oxygen vacancies (V_{O}) and V_{O}H in the semiconductor layer 108 and the semiconductor layer 208 in some cases. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above range, release of oxygen from the semiconductor layer 108 and the semiconductor layer 208 can be inhibited while the defects in the insulating layer 106 can be reduced. Thus, the transistor can have favorable electrical characteristics and high reliability.

Before the formation of the insulating layer 106, plasma treatment may be performed on the surface of the semiconductor layer 108 and the surface of the semiconductor layer 208. By the plasma treatment, impurities such as water adsorbed on the surfaces of the semiconductor layer 108 and the semiconductor layer 208 can be reduced. Therefore, impurities at the interface between the semiconductor layer 108 and the insulating layer 106 and the interface between the semiconductor layer 208 and the insulating layer 106 can be reduced, and highly reliable transistors can be provided. The plasma treatment is particularly suitable in the case where the surfaces of the semiconductor layer 108 and the semiconductor layer 208 are exposed to the air in a period between the formation of the semiconductor layer 108 and the semiconductor layer 208 and the formation of the insulating layer 106. For example, the plasma treatment can be performed in an atmosphere containing oxygen, ozone, nitrogen, dinitrogen monoxide, argon, or the like. The plasma treatment and the formation of the insulating layer 106 are preferably performed successively without exposure to the air.

Then, a film to be the conductive layer 104 and the conductive layer 204 is formed over the insulating layer 106 and the film is processed, so that the conductive layer 104 and the conductive layer 204 are formed (FIG. 23B). For the formation of the film, a sputtering method, a thermal CVD method (including an MOCVD method), or an ALD method can be suitable used, for example.

Subsequently, the insulating layer 195 is formed to cover the conductive layer 104, the conductive layer 204, and the insulating layer 106 (FIG. 12B). For the formation of the insulating layer 195, a PECVD method can be suitably used.

Heat treatment may be performed after the formation of the insulating layer 195. Note that the heat treatment is not necessarily performed. The heat treatment in this step may be omitted, and heat treatment performed in a later step may also function as the heat treatment in this step. In the case where heat application treatment (e.g., film formation step) is performed in a later step, the treatment can serve as the heat treatment in this step in some cases.

Through the above steps, the semiconductor device of one embodiment of the present invention can be manufactured.

### Example 2 of Manufacturing Method

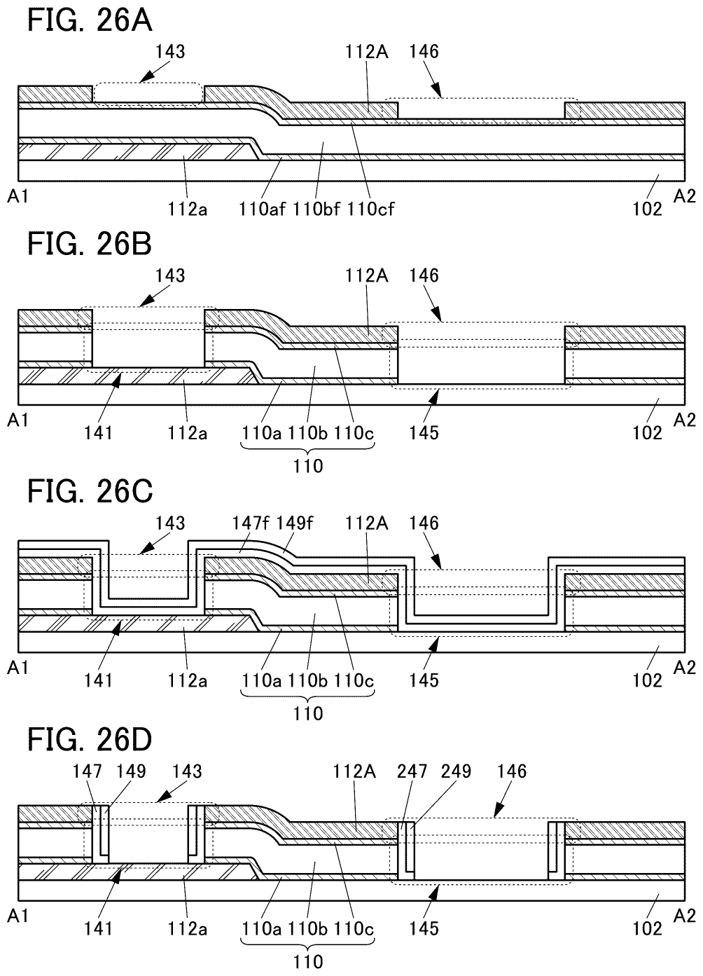

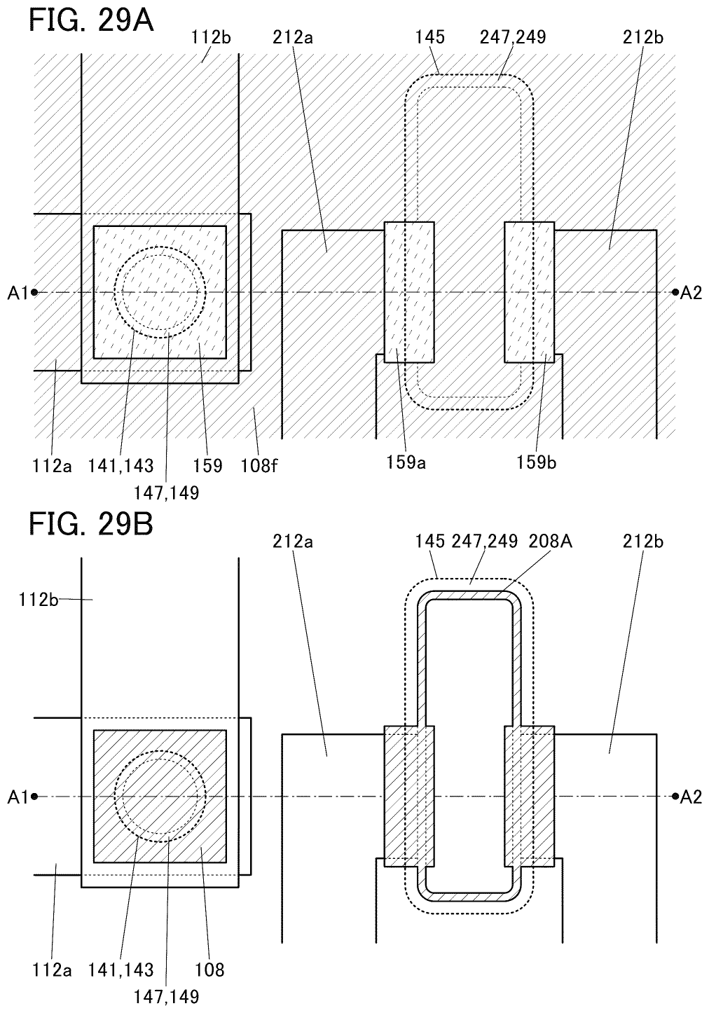

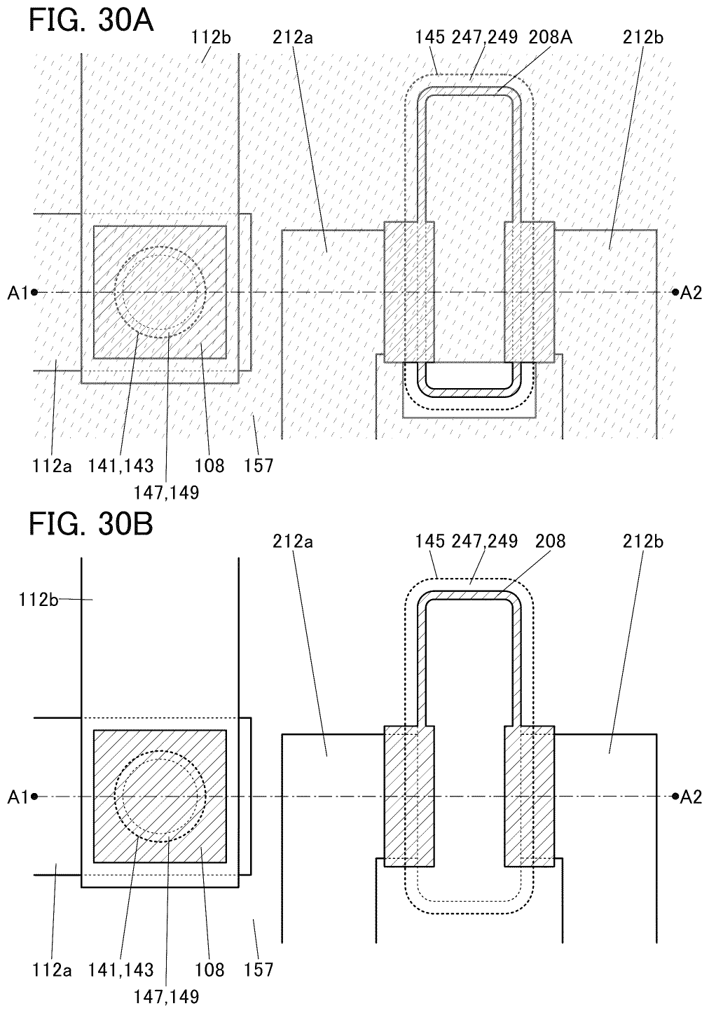

An example of a method for manufacturing the semiconductor device 10A illustrated in FIG. 15A and FIG. 15B is described with reference to FIG. 26A to FIG. 30B. FIG. 26A to FIG. 28D are cross-sectional views taken along the dashed-dotted line A1-A2 in FIG. 15A. FIG. 29A to FIG. 30B are top views. Note that description of the same portions as those in the example 1 of manufacturing method described above is omitted and different portions are described.

First, as in the example 1 of manufacturing method, the steps up to the formation of the conductive film 112bf are performed (FIG. 20A to FIG. 20E).

Next, the conductive film 112bf is processed to form a conductive layer 112A (FIG. 26A). The conductive layer 112A is to be the conductive layer 112b, the conductive layer 212a, and the conductive layer 212b later. The conductive layer 112A includes the opening 143 and an opening 146. The opening 143 is formed in a region overlapping with the opening 141, and the opening 146 is formed in a region overlapping with the opening 145.

Next, the insulating film 110af, the insulating film 110bf, and the insulating film 110cf are partly removed, so that the insulating layer 110 including the opening 141 and the opening 145 is formed (FIG. 26B).

Next, an insulating film 147f to be the insulating layer 147 and the insulating layer 247 is formed to cover the opening 141, the opening 143, the opening 145, and the opening 146, and an insulating film 149f to be the insulating layer 149 and the insulating layer 249 is formed over the insulating film 147f (FIG. 26C).

The insulating film 147f is preferably formed in contact with the sidewall of the opening 145. The insulating film 149f is preferably formed in contact with a depressed portion of the insulating film 147f that is formed to reflect the shape of the opening 145. Thus, the insulating film 147f and the insulating film 149f are preferably formed by a film-formation method enabling favorable coverage, and a CVD method or an ALD method can be suitably used. It is preferable that the insulating film 149f be formed in a vacuum successively after the formation of the insulating film 147f, without exposure of the surface of the insulating film 147f to the air. By forming the insulating film 147f and the insulating film 149f successively, attachment of impurities derived from the air to the surface of the insulating film 147f can be inhibited. Examples of the impurities include water and organic substances.

Next, the insulating film 149f and the insulating film 147f are processed to form the insulating layer 149, the insulating layer 249, the insulating layer 147, and the insulating layer 247 (FIG. 26D). At this time, the top surface of the conductive layer 112a is exposed in the opening 141, the top surface of the substrate 102 is exposed in the opening 145, and the top surface of the conductive layer 112A is exposed. An anisotropic dry etching method can be suitably used for forming the insulating layer 147 and the insulating layer 247.

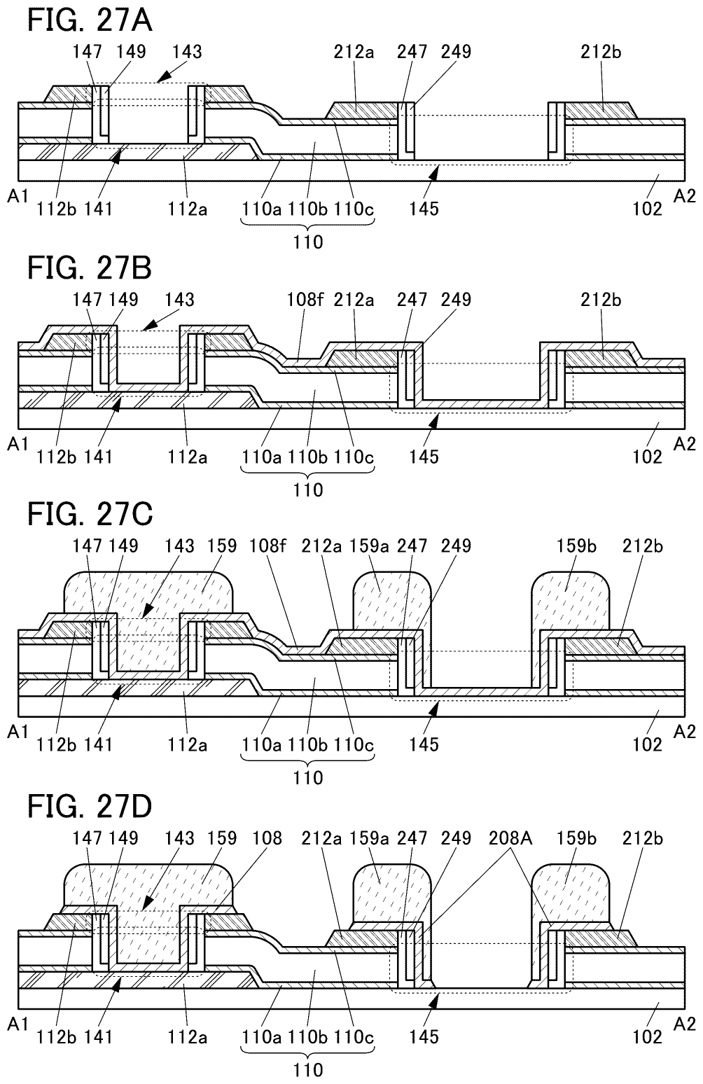

Next, the conductive layer 112A is processed to form the conductive layer 112b, the conductive layer 212a, and the conductive layer 212b (FIG. 27A).

Next, a metal oxide film 108f to be the semiconductor layer 108 and the semiconductor layer 208 later is formed (FIG. 27B). The metal oxide film 108f is provided in contact with the top surface and the side surface of the conductive layer 112b, the top surface and the side surface of the insulating layer 147, the top surface and the side surface of the insulating layer 149, the top surface and the side surface of the insulating layer 247, the top surface and the side surface of the insulating layer 249, the top surface of the insulating layer 110, the top surface of the conductive layer 112a, the top surface and the side surface of the conductive layer 212a, the top surface and the side surface of the conductive layer 212b, and the top surface of the substrate 102.

Next, the resist mask 159, a resist mask 159a, and a resist mask 159b are formed over the metal oxide film 108f (FIG. 27C and FIG. 29A). The resist mask 159 is provided in a region where the semiconductor layer 108 is formed so as to cover at least the opening 141 and the opening 143. The resist mask 159a is provided at least in a region where the conductive layer 212a and the semiconductor layer 208 are in contact with each other. The resist mask 159b is provided at least in a region where the conductive layer 212b and the semiconductor layer 208 are in contact with each other. Note that in FIG. 29A, the metal oxide film 108f, the resist mask 159, the resist mask 159a, and the resist mask 159b are shown with hatching patterns. For the sake of easy understanding of the structure below the metal oxide film 108f, the hatching pattern of the metal oxide film 108f is seen through.

Next, the metal oxide film 108f is processed into an island shape to form the semiconductor layer 108 and the semiconductor layer 208A to be the semiconductor layer 208 (FIG. 27D and FIG. 29B). The semiconductor layer 108 is formed in a region of the metal oxide film 108f that is covered with the resist mask 159, and the semiconductor layer 208A is formed in a region of the metal oxide film 108f that is covered with the resist mask 159a, a region of the metal oxide film 108f that is covered with the resist mask 159b, and a region of the metal oxide film 108f in contact with the side surface of the opening 145. In FIG. 29B, the semiconductor layer 108 and the semiconductor layer 208A are shown with hatching patterns.

Then, the resist mask 159, the resist mask 159a, and the resist mask 159b are removed.

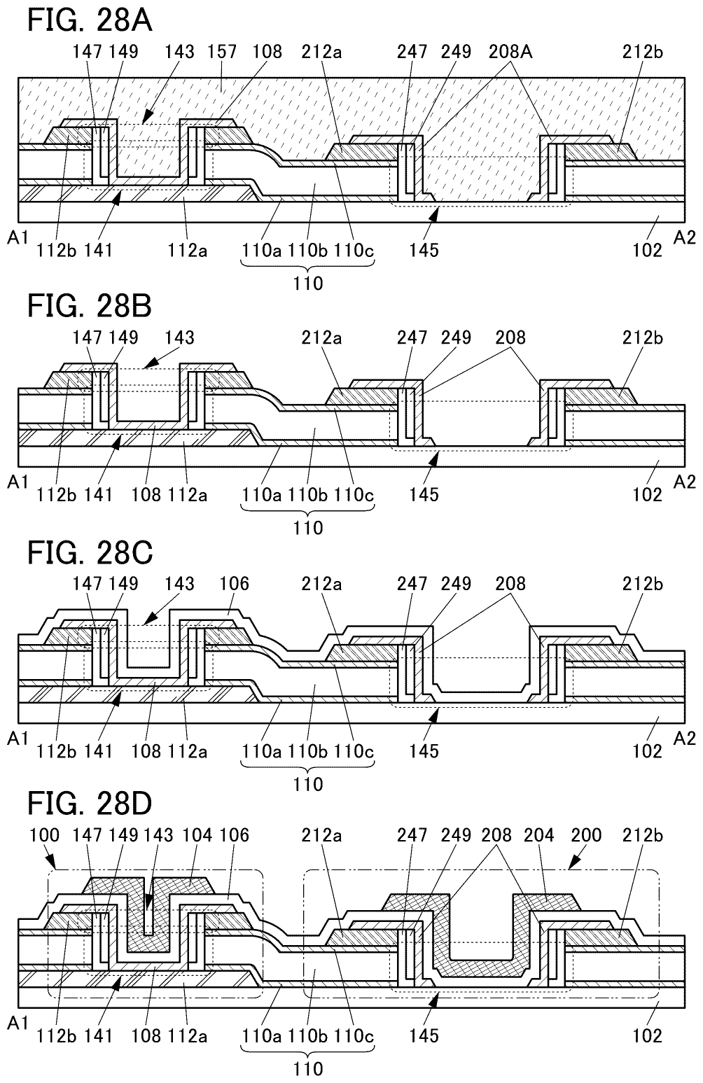

Subsequently, the resist mask 157 is formed over the semiconductor layer 108, the semiconductor layer 208A, the conductive layer 112b, the conductive layer 212a, the conductive layer 212b, the insulating layer 110, and the substrate 102 (FIG. 28A) and FIG. 30A). The resist mask 157 is provided so as to cover at least the semiconductor layer 108 and the semiconductor layer 208A in the region to be the semiconductor layer 208. At this time, the semiconductor layer 208A in the region where the semiconductor layer 208 is not provided is exposed. In FIG. 30A, the semiconductor layer 108, the semiconductor layer 208A, and the resist mask 157 are shown with hatching patterns. For the sake of easy understanding of the structure below the resist mask 157, the hatching pattern of the resist mask 157 is seen through.

Subsequently, the semiconductor layer 208A in a region not covered with the resist mask 157 is removed, so that the semiconductor layer 208 is formed.

Next, the resist mask 157 is removed (FIG. 28B and FIG. 30B). In FIG. 30B, the semiconductor layer 108 and the semiconductor layer 208 are shown with hatching patterns.

Then, the insulating layer 106 is formed to cover the semiconductor layer 108, the semiconductor layer 208, the insulating layer 110, and the substrate 102 (FIG. 28C).

Then, a film to be the conductive layer 104 and the conductive layer 204 is formed over the insulating layer 106 and the film is processed, so that the conductive layer 104 and the conductive layer 204 are formed (FIG. 28D).

Subsequently, the insulating layer 195 is formed to cover the conductive layer 104, the conductive layer 204, and the insulating layer 106 (FIG. 15B).

Through the above steps, the semiconductor device of one embodiment of the present invention can be manufactured.

At least part of the structure examples, the drawings corresponding thereto, and the like described in this embodiment can be combined with any of the other structure examples, the other drawings corresponding thereto, and the like as appropriate.

### Embodiment 4

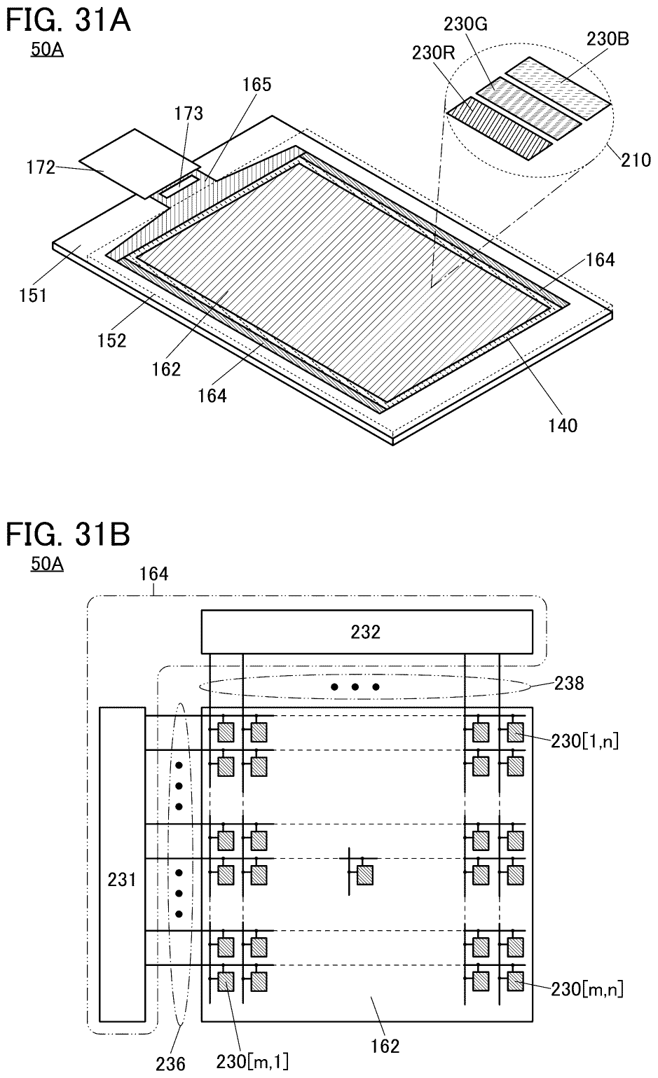

In this embodiment, a display apparatus of one embodiment of the present invention will be described with reference to FIG. 31 to FIG. 35.

The display apparatus of this embodiment can be a high-resolution display apparatus or a large-sized display apparatus. Accordingly, for example, the display apparatus of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop computer, a monitor of a computer or the like, digital signage, and a large game machine such as a pachinko machine.

The display apparatus of this embodiment can be a high-definition display apparatus. Accordingly, the display apparatus of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display apparatus or a module including the display apparatus. Examples of the module including the display apparatus are a module in which a connector such as a flexible printed circuit board (hereinafter referred to as an FPC) or a TCP (Tape Carrier Package) is attached to the display apparatus and a module in which the display apparatus is mounted with an integrated circuit (IC) by a COG (Chip On Glass) method, a COF (Chip On Film) method, or the like.

The display apparatus of this embodiment may have a function of a touch panel. The display apparatus can employ any of a variety of sensor elements that can sense proximity or touch of a sensing target such as a finger, for example.

Examples of the sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of the mutual capacitive type is preferable because multiple points can be sensed simultaneously.

Examples of a touch panel include an out-cell type, an on-cell type, and an in-cell type. Note that an in-cell touch panel has a structure in which an electrode included in a sensor element is provided on one or both of a substrate supporting a display element (also referred to as a display device) and a counter substrate.

### Structure Example 1

FIG. 31A illustrates a perspective view of a display apparatus 50A.

The display apparatus 50A has a structure in which a substrate 152 and a substrate 151 are attached to each other. In FIG. 31A, the substrate 152 is denoted by a dashed line.

The display apparatus 50A includes a display portion 162, a connection portion 140, a circuit portion 164, a conductive layer 165, and the like. FIG. 31A illustrates an example where an IC 173 and an FPC 172 are mounted onto the display apparatus 50A. Thus, the structure illustrated in FIG. 31A can be regarded as a display module including the display apparatus 50A, the IC, and the FPC.

The connection portion 140 is provided outside the display portion 162. The connection portion 140 can be provided along one or more sides of the display portion 162. The number of connection portions 140 may be one or more. FIG. 31A illustrates an example in which the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The conductive layer 165 has a function of supplying a signal and electric power to the display portion 162 and the circuit portion 164. The signal and electric power are input to the conductive layer 165 from the outside through the FPC 172 or input to the conductive layer 165 from the IC 173.

FIG. 31A illustrates an example where the IC 173 is provided on the substrate 151 by a COG method, a COF method, or the like. An IC including one or both of a scan line driver circuit and a signal line driver circuit can be used as the IC 173, for example. Note that the display apparatus 50A and the display module may be configured not to include an IC. The IC may be mounted on the FPC by a COF method or the like.

The semiconductor device of one embodiment of the present invention can be used for one or both of the display portion 162 and the circuit portion 164 of the display apparatus 50A, for example. An oxide semiconductor (OS) can be suitably used for a channel formation region of a transistor included in the display apparatus. By using an OS transistor, a display apparatus can have low power consumption. The semiconductor device of one embodiment of the present invention can be used for both the display portion 162 and the circuit portion 164, that is, all the transistors included in the display apparatus can be OS transistors. When all the transistors included in the display apparatus are OS transistors in this manner, an effect of reducing the manufacturing cost can be obtained.

When the semiconductor device of one embodiment of the present invention is used for a pixel circuit of a display apparatus, the area occupied by the pixel circuit can be reduced and a high-definition display apparatus can be provided, for example. When the semiconductor device of one embodiment of the present invention is used for a driver circuit (e.g., one or both of a gate line driver circuit and a source line driver circuit) of a display apparatus, the area occupied by the driver circuit can be reduced and the display apparatus can have a narrow bezel. Since the semiconductor device of one embodiment of the present invention has favorable electrical characteristics, the display apparatus can have increased reliability by using the semiconductor device.

The display portion 162 of the display apparatus 50A is a region where an image is to be displayed, and includes a plurality of pixels 210 that are periodically arranged. In FIG. 31A, an enlarged view of one of the pixels 210 is illustrated.

There is no particular limitation on the arrangement of the pixels in the display apparatus of this embodiment, and a variety of methods can be used. Examples of the arrangement of the pixels include stripe arrangement, S-stripe arrangement, matrix arrangement, delta arrangement, Bayer arrangement, and PenTile arrangement.

The pixel 210 illustrated in FIG. 31A includes a pixel 230R that emits red light, a pixel 230G that emits green light, and a pixel 230B that emits blue light. The pixel 230R, the pixel 230G, and the pixel 230B constitutes one pixel 210, and can performs full-color display. The pixel 230R, the pixel 230G, and the pixel 230B function as subpixels. The display apparatus 50A illustrated in FIG. 31A illustrates an example in which the pixels 230 each functioning as a subpixel are arranged in a stripe pattern. The number of subpixels constituting one pixel 210 is not limited to three, and may be four or more. For example, four subpixels which emit light of R, G, B, and white (W) may be included. Alternatively, four subpixels which emit light of four colors, R, G, B, and Y may be included.

The pixel 230R, the pixel 230G, and the pixel 230B each include a display element and a circuit for controlling the driving of the display element.

A variety of elements can be used as the display element, and a liquid crystal element (also referred to as a liquid crystal device) or a light-emitting device can be used, for example. Alternatively, it is also possible to use, for example, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like. Alternatively, a QLED (Quantum-dot LED) employing a light source and color conversion technology using quantum dot materials may be used.

Examples of a display apparatus using a liquid crystal element include a transmissive liquid crystal display apparatus, a reflective liquid crystal display apparatus, and a transflective liquid crystal display apparatus.

Examples of a mode that can be employed for a display apparatus including a liquid crystal element include a vertical alignment (VA) mode, an FFS (Fringe Field Switching) mode, an IPS (In-Plane-Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include an MVA (Multi-Domain Vertical Alignment) mode, a PVA (Patterned Vertical Alignment) mode, and an ASV (Advanced Super View) mode.

Examples of a liquid crystal material that can be used for the liquid crystal element include a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

Examples of the light-emitting device include a self-luminous light-emitting device such as an LED (Light Emitting Diode), an OLED (Organic LED), and a semiconductor laser. As the LED, for example, a mini LED or a micro LED can be used.

Examples of a light-emitting substance included in the light-emitting device include a substance that emits fluorescent light (a fluorescent material), a substance that emits phosphorescent light (a phosphorescent material), a substance exhibiting thermally activated delayed fluorescence (a thermally activated delayed fluorescent (TADF) material), and an inorganic compound (e.g., a quantum dot material).

The emission color of the light-emitting device can be infrared, red, green, blue, cyan, magenta, yellow, white, or the like. Furthermore, color purity can be increased when the light-emitting device has a microcavity structure.

One of the pair of electrodes of the light-emitting device functions as an anode, and the other electrode functions as a cathode.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

In this embodiment, the case where a light-emitting device is used as the display element is mainly described as an example.

FIG. 31B is a block diagram illustrating the display apparatus 50A. The display apparatus 50A includes the display portion 162 and the circuit portion 164. The display portion 162 includes a plurality of pixels 230 arranged periodically (the pixel 230 [1,1] to the pixel 230 [m,n], where m and n are each independently an integer greater than or equal to 2). The circuit portion 164 includes a first driver circuit portion 231 and a second driver circuit portion 232.

A circuit included in the first driver circuit portion 231 functions as, for example, a scan line driver circuit. A circuit included in the second driver circuit portion 232 functions as, for example, a signal line driver circuit. Some sort of circuit may be provided to face the first driver circuit portion 231 with the display portion 162 placed therebetween. Some sort of circuit may be provided to face the second driver circuit portion 232 with the display portion 162 placed therebetween.

Any of various circuits such as a shift register circuit, a level shifter circuit, an inverter circuit, a latch circuit, an analog switch circuit, a demultiplexer circuit, and a logic circuit can be used as the circuit portion 164. In the circuit portion 164, a transistor, a capacitor, and the like can be used. Transistors included in the circuit portion 164 may be formed in the same process as the transistors included in the pixels 230.

The display apparatus 50A includes wirings 236 which are arranged substantially parallel to each other and whose potentials are controlled by the circuits included in the first driver circuit portion 231, and wirings 238 which are arranged substantially parallel to each other and whose potentials are controlled by the circuits included in the second driver circuit portion 232. FIG. 31B illustrates an example in which the wiring 236 and the wiring 238 are connected to the pixel 230. Note that the wiring 236 and the wiring 238 are examples, and the wirings connected to the pixel 230 are not limited to the wiring 236 and the wiring 238.

In the semiconductor device of one embodiment of the present invention, a VFET having a submicron-sized channel length and high on-state current and a VLFET having a long channel length and high saturation characteristics can be formed in some common steps. An oxide semiconductor (OS) can be suitably used for each of channel formation regions of these transistors, so that the transistors can have low off-state current. The semiconductor device of one embodiment of the present invention can be suitably used for one or both of the display portion 162 and the circuit portion 164. The semiconductor device of one embodiment of the present invention can be used for both the display portion 162 and the circuit portion 164, that is, all the transistors included in the display apparatus can be OS transistors. When all the transistors included in the display apparatus are OS transistors in this manner, an effect of reducing the manufacturing cost can be obtained.

### Structure Example 2

Using a latch circuit as an example, a structure example of a circuit that can be used in the circuit portion 164 will be described.

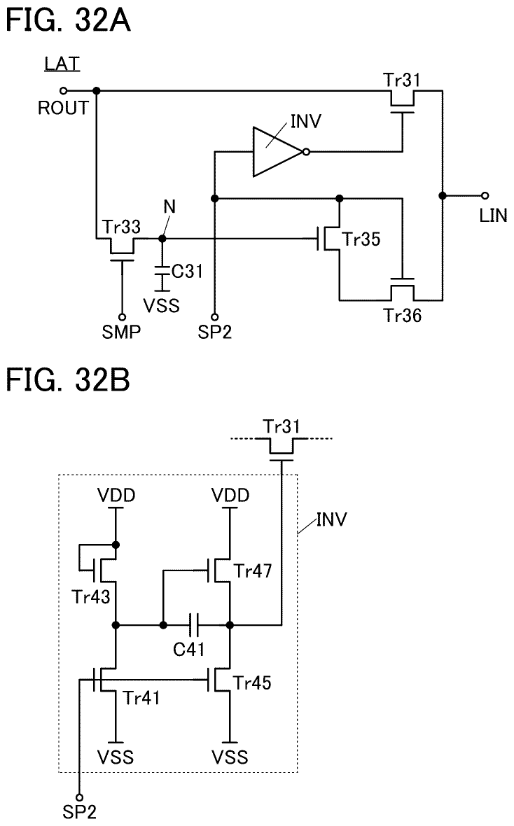

FIG. 32A is a circuit diagram illustrating a structure example of a latch circuit LAT. The latch circuit LAT illustrated in FIG. 32A includes a transistor Tr31, a transistor Tr33, a transistor Tr35, a transistor Tr36, a capacitor C31, and an inverter circuit INV. In FIG. 32A, a node at which one of a source and a drain of the transistor Tr33, a gate of the transistor Tr35, and one electrode of the capacitor C31 are electrically connected to each other is referred to as a node N.

In the latch circuit LAT illustrated in FIG. 32A, when a high-potential signal is input to a terminal SMP, the transistor Tr33 is turned on. Thus, the potential of the node N becomes a potential corresponding to the potential of a terminal ROUT, and data corresponding to a signal input from the terminal ROUT to the latch circuit LAT is written to the latch circuit LAT. After data is written to the latch circuit LAT, the potential of the terminal SMP is set to a low potential, so that the transistor Tr33 is turned off. Thus, the potential of the node N is held and the data written to the latch circuit LAT is held. Specifically, when the potential of the node N is a low potential, data “0” is held in the latch circuit LAT and when the potential of the node N is a high potential, data “1” is held in the latch circuit LAT, for example.

A transistor with low off-state current is preferably used as the transistor Tr33. An OS transistor can be suitably used as the transistor Tr33. Thus, the latch circuit LAT can hold data for a long period. Thus, the frequency of rewriting data in the latch circuit LAT can be lowered.

In this specification and the like, writing data to the latch circuit LAT such that a signal input from a terminal SP2 is output to the terminal LIN is simply referred to as “writing data to the latch circuit LAT” in some cases. That is, for example, data “1” is written to the latch circuit LAT, which is referred to simply as “writing data to the latch circuit LAT” in some cases.

The semiconductor device of one embodiment of the present invention can be suitably used for the latch circuit LAT. For example, the transistor 100 or the transistor 200 illustrated in FIG. 12B or the like can be used as one or more of the transistor Tr31, the transistor Tr33, the transistor Tr35, and the transistor Tr36.

FIG. 32B illustrates a structure example of the inverter circuit INV. The inverter circuit INV includes a transistor Tr41, a transistor Tr43, a transistor Tr45, a transistor Tr47, and a capacitor C41.

The latch circuit LAT has the structure illustrated in FIG. 32A and the inverter circuit INV has the structure illustrated in FIG. 32B, in which case all the transistors included in the latch circuit LAT can be transistors having the same polarity, for example, n-channel transistors. Thus, the transistor Tr31, the transistor Tr35, the transistor Tr36, the transistor Tr41, the transistor Tr43, the transistor Tr45, and the transistor Tr47 as well as the transistor Tr33 can be OS transistors, for example. Accordingly, all the transistors included in the latch circuit LAT can be formed in the same steps.

The semiconductor device of one embodiment of the present invention can be suitably used for the inverter circuit INV. For example, the transistor 100 or the transistor 200 illustrated in FIG. 12B or the like can be used as one or more of the transistor Tr41, the transistor Tr43, the transistor Tr45, and the transistor Tr47.

Furthermore, one or more of the transistor 20 to the transistor 20B and the transistor 200 to the transistor 200E can be suitably used as the transistor required to have high saturation characteristics. One or more of the transistor 100 to the transistor 100B can be suitably used as the transistors that need to have high on-state current. Accordingly, the display apparatus can have high performance. Furthermore, the occupation area can be reduced, so that the display apparatus can have a narrow bezel.

### Structure Example 3

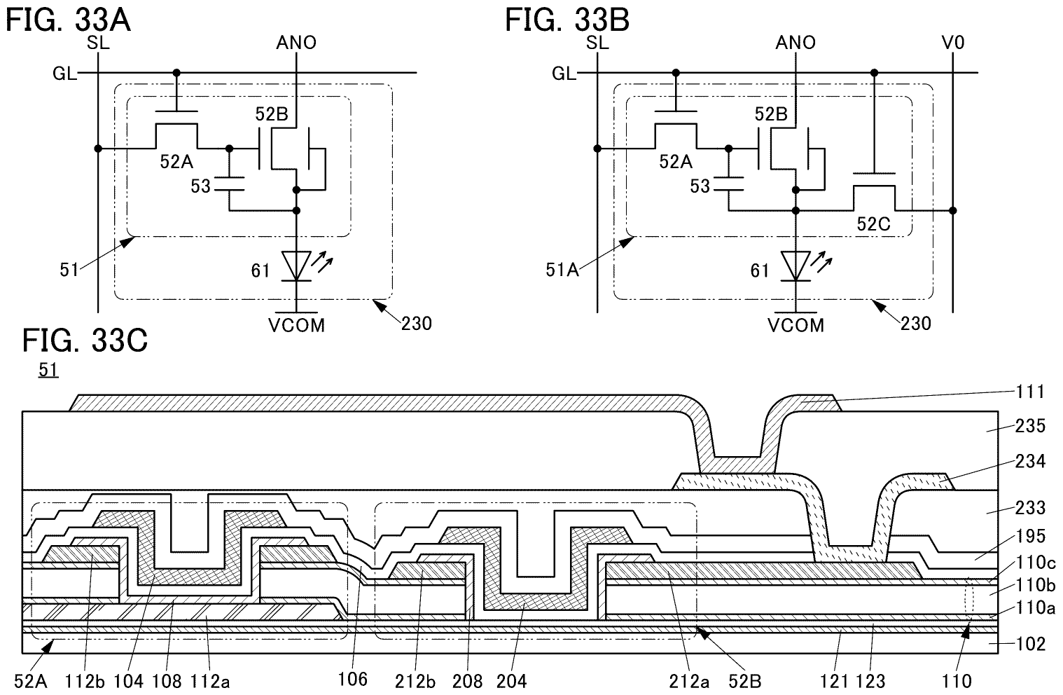

FIG. 33A illustrates a structure example of the pixel 230. The pixel 230 includes a pixel circuit 51 and a light-emitting device 61.

The pixel circuit 51 illustrated in FIG. 33A includes a transistor 52A, a transistor 52B, and a capacitor 53. The pixel circuit 51 is a 2Tr1C pixel circuit including two transistors and one capacitor. Note that there is no particular limitation on the pixel circuit that can be used for the display apparatus of one embodiment of the present invention.

An anode of the light-emitting device 61 is electrically connected to one of a source and a drain of the transistor 52B and one electrode of the capacitor 53. The other of the source and the drain of the transistor 52B is electrically connected to a wiring ANO. A gate of the transistor 52B is electrically connected to one of the source and the drain of the transistor 52A and the other electrode of the capacitor 53. The other of the source and the drain of the transistor 52A is electrically connected to a wiring GL. A gate of the transistor 52A is electrically connected to a wiring GL. A cathode of the light-emitting device 61 is electrically connected to a wiring VCOM.

The wiring GL corresponds to the wiring 236, and the wiring SL corresponds to the wiring 238. The wiring VCOM is a wiring that supplies a potential for supplying current to the light-emitting device 61. The transistor 52A has a function of controlling the conduction state and the non-conduction state between the wiring SL and the gate of the transistor 52B in accordance with the potential of the wiring GL. For example, VDD is supplied to the wiring ANO, and VSS is supplied to the wiring VCOM.

The transistor 52B has a function of controlling the amount of current flowing through the light-emitting device 61. The capacitor 53 has a function of holding a gate potential of the transistor 52B. The intensity of light emitted by the light-emitting device 61 can be controlled in accordance with an image signal supplied to the gate of the transistor 52B.

Some or all of the transistors included in the pixel circuit 51 may each be provided with a back gate. In the pixel circuit 51 illustrated in FIG. 33A, the transistor 52B includes a back gate, and the back gate is electrically connected to one of the source and the drain of the transistor 52B. Note that a structure in which the back gate of the transistor 52B is electrically connected to the gate of the transistor 52B may be employed as well.

The above-described semiconductor device can be suitably used for the pixel circuit 51. The transistor 52B functioning as a driving transistor that controls a current flowing through the light-emitting device 61 preferably has higher saturation characteristics than the transistor 52A functioning as a selection transistor for controlling a selection state of the pixel 230. The use of any one of the transistor 20 to the transistor 20B and the transistor 200 to the transistor 200E each having a long channel length as the transistor 52B enables the display apparatus to have high reliability. Furthermore, when any one of the transistor 100 to the transistor 100B is used as the transistor 52A, the area occupied by a pixel circuit 51A can be reduced, so that a high-definition display apparatus can be obtained.

Note that the transistor 100 may also be used as the transistor 52B. The use of a transistor having a short channel length as the transistor 52B enables the display apparatus to have high luminance. Furthermore, the area occupied by the pixel circuit 51 can be reduced, so that a high-definition display apparatus can be obtained.

FIG. 33B illustrates a structure example different from that of the pixel 230 illustrated in FIG. 33A. The pixel 230 includes the pixel circuit 51A and the light-emitting device 61.

The pixel circuit 51A illustrated in FIG. 33B is different from the pixel circuit 51 illustrated in FIG. 33A mainly in including a transistor 52C. The pixel circuit 51A includes the transistor 52A, the transistor 52B, the transistor 52C, and the capacitor 53. The pixel circuit 51A is a 3Tr1C pixel circuit including three transistors and one capacitor.

One of a source and a drain of the transistor 52C is electrically connected to one of the source and the drain of the transistor 52B. The other of the source and the drain of the transistor 52C is electrically connected to a wiring V0. For example, a reference potential is supplied to the wiring V0. A gate of the transistor 52C is electrically connected to the wiring GL.

The transistor 52C has a function of controlling the conduction state and the non-conduction state between the wiring V0 and the one of the source electrode and the drain electrode of the transistor 52B in accordance with the potential of the wiring GL. Variations in the gate-source potential of the transistor 52B can be inhibited by the reference potential of the wiring V0 supplied through the transistor 52C.

A current value that can be used for setting pixel parameters can be obtained with use of the wiring V0. Specifically, the wiring V0 can function as a monitor line for outputting current flowing through the transistor 52B or current flowing through the light-emitting device 61 to the outside. Current output to the wiring V0 is converted into a voltage by a source follower circuit and can be output to the outside. Alternatively, the current is converted into a digital signal by an A/D converter, and can be output to the outside.

The above-described semiconductor device can be suitably used for the pixel circuit 51A. The use of one of the transistor 20 to the transistor 20B and the transistor 200 to the transistor 200E each having a long channel length as the transistor 52B enables the display apparatus to have high reliability. Furthermore, the use of one of the transistor 100 to the transistor 100B as each of the transistor 52A and the transistor 52C enables the area occupied by the pixel circuit 51A to be reduced, so that a high-definition display apparatus can be obtained. In addition, one of the transistor 100 to the transistor 100B may also be used as the transistor 52B.

FIG. 33C illustrates a structure example of the pixel circuit 51. FIG. 33C is a cross-sectional view of the pixel circuit 51. FIG. 33C selectively illustrates the pixel electrodes included in the transistor 52A, the transistor 52B, and the light-emitting device 61. Note that the electrical connection between the transistor 52A and the transistor 52B is not illustrated.

The transistor 52A includes the conductive layer 104, the insulating layer 106, the semiconductor layer 108, the conductive layer 112a, and the conductive layer 112b. The transistor 52B includes the insulating layer 106, the semiconductor layer 208, the conductive layer 204, the conductive layer 212a, and the conductive layer 212b. The above description can be referred to for the transistor 52A and the transistor 52B; thus, the detailed description is omitted.

The transistor 52A and the transistor 52B are provided over the substrate 102. FIG. 33C illustrates a structure in which the insulating layer 121 and the insulating layer 123 are provided between the transistors 52A and 52B and the substrate 102. Note that the semiconductor layer 108 of the transistor 52A is provided over the conductive layer 112a, and the semiconductor layer 208 of the transistor 52B is provided over the insulating layer 123. When the layers over which the semiconductor layers of the two transistors are provided are different in this manner, the transistors having different structures can be easily formed over the same substrate.

The insulating layer 121 preferably has a barrier property against hydrogen, and preferably has high capability of capturing or fixing (gettering) hydrogen, in particular. For the insulating layer 121, a material that can be used for the insulating layer 149 and the insulating layer 249 can be suitably used, for example. Hafnium oxide can be suitably used for the insulating layer 121, for example. For example, a material that can be used for the insulating layer 110 can be suitably used for the insulating layer 123 provided over the insulating layer 121. For example, silicon oxide can be suitably used for the insulating layer 123.

The insulating layer 195 is provided to cover the transistor 52A, the transistor 52B, and the capacitor 53, an insulating layer 233 is provided to cover the insulating layer 195, and an insulating layer 235 is provided to cover the insulating layer 233. The light-emitting device 61 can be provided over the insulating layer 235. FIG. 33C illustrates a pixel electrode 111 functioning as one electrode of the light-emitting device 61. The insulating layer 195 and the insulating layer 233 include a first opening reaching the conductive layer 212a, and the conductive layer 234 is provided to cover the first opening. The conductive layer 234 is electrically connected to the conductive layer 212a through the first opening. The insulating layer 235 includes a second opening reaching the conductive layer 234, and the pixel electrode 111 is provided to cover the second opening. The pixel electrode 111 is electrically connected to the conductive layer 234 through the second opening. The above description can be referred to for the insulating layer 195; thus, the detailed description thereof is omitted. The insulating layer 233 and the insulating layer 235 each have a function of reducing unevenness due to the transistor 52A, the transistor 52B, and the transistor 52C and making the formation surface of the light-emitting device 61 flatter. Note that in this specification and the like, each of the insulating layer 233 and the insulating layer 235 is referred to as a planarization layer in some cases.

An organic insulating film is suitable for each of the insulating layer 233 and the insulating layer 235. Examples of a material that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. The insulating layer 235 may have a stacked-layer structure of an organic insulating film and an inorganic insulating film. The insulating layer 235 preferably has a stacked-layer structure of an organic insulating film and an inorganic insulating film over the organic insulating film. Thus, the inorganic insulating film can function as an etching protective layer at the time of forming the light-emitting device 61. Specifically, part of the insulating layer 235 can be inhibited from being etched at the time of forming the pixel electrode 111, so that a depressed portion can be inhibited from being formed in the insulating layer 235. Alternatively, a depressed portion may be formed in the insulating layer 235 at the time of forming the pixel electrode 111. Similarly, the insulating layer 233 may have a stacked-layer structure of an organic insulating film and an inorganic insulating film.

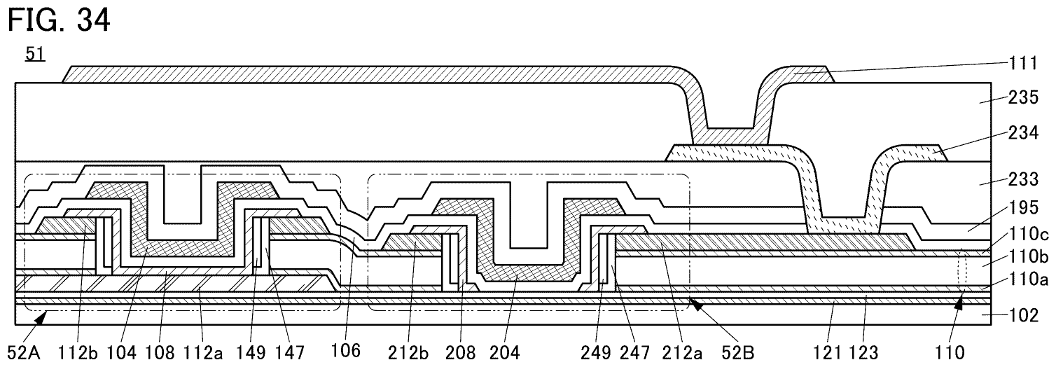

Although FIG. 33C illustrates the structure in which the transistor 200 illustrated in FIG. 12A or the like is used as the transistor 52B, one embodiment of the present invention is not limited to the structure. As illustrated in FIG. 34, the transistor 200A illustrated in FIG. 15A or the like may be used as the transistor 52B.

### Structure Example 4

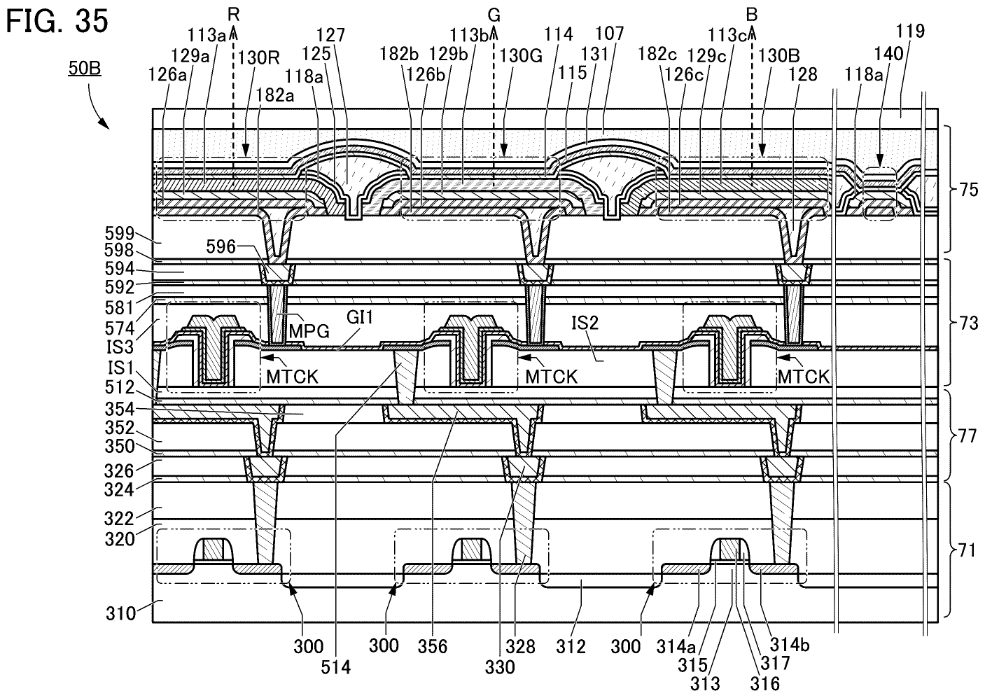

FIG. 35 illustrates a structure example different from the structure in the above description. A display apparatus 50B has a structure including a pixel circuit, a driver circuit, and the like provided over a substrate 310. The display apparatus 50B includes an element layer 71, an element layer 73, an element layer 75, and a wiring layer 77. The wiring layer 77 is a layer in which wirings are formed.

The element layer 71 includes the substrate 310, for example, and a transistor 300 is formed over the substrate 310. The wiring layer 77 is provided above the transistor 300, and in the wiring layer 77, wirings are provided to electrically connect the transistors 300, transistors MTCK, a light-emitting device 130R, a light-emitting device 130G, and a light-emitting device 130B. The element layer 73 and the element layer 75 are provided above the wiring layer 77, and the element layer 73 includes the transistors MTCK and the like, for example. The element layer 75 includes the light-emitting devices 130 (the light-emitting device 130R, the light-emitting device 130G, and the light-emitting device 130B in FIG. 35), and the like.

That is, the transistor 300 can be a transistor included in the element layer 71. The transistor MTCK can be a transistor included in the element layer 73. The light-emitting device 130 can be a light-emitting device included in the element layer 75.

As the transistor MTCK, one of the above-described transistor 20 to transistor 20B and transistor 200 to transistor 200E can be suitably used. Alternatively, one of the transistor 100 to the transistor 100B may be used as the transistor MTCK.

As the substrate 310, a semiconductor substrate (e.g., a single crystal substrate containing silicon or germanium as a material) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate 310. In description of this embodiment, the substrate 310 is a semiconductor substrate containing silicon as a material. Thus, the transistor included in the element layer 71 can be a transistor including silicon (also referred to as a Si transistor).

The transistor 300 includes an element isolation layer 312, a conductive layer 316, an insulating layer 315, an insulating layer 317, a semiconductor region 313 that is part of the substrate 310, and a low-resistance region 314a and a low-resistance region 314b that function as a source region and a drain region. Thus, the transistor 300 is a Si transistor. Although FIG. 35 illustrates a structure in which one of a source and a drain of the transistor 300 is electrically connected to a conductive layer 330, a conductive layer 356, and a conductive layer 514 through a conductive layer 328, the electrical connection in the display apparatus of one embodiment of the present invention is not limited to the structure. The display apparatus of one embodiment of the present invention may have a structure in which, for example, a gate of the transistor 300 is electrically connected to the conductive layer 514 through the conductive layer 328.

The transistor 300 can be a fin type when, for example, the top surface and the side surface in the channel width direction of the semiconductor region 313 are covered with the conductive layer 316 with the insulating layer 315 functioning as a gate insulating layer therebetween. The effective channel width can be increased in the fin-type transistor 300, so that the on-state characteristics of the transistor 300 can be improved. In addition, contribution of the electric field of the gate electrode can be increased, so that the off-state characteristics of the transistor 300 can be improved. Alternatively, the transistor 300 may have a planar structure instead of a fin-type structure.

Note that the transistor 300 may be either a p-channel transistor or an n-channel transistor. Alternatively, a plurality of the transistors 300 may be provided and both the p-channel transistor and the n-channel transistor may be used.

A region of the semiconductor region 313 where a channel is formed, a region in the vicinity thereof, and the low-resistance region 314a and the low-resistance region 314b that function as the source region and the drain region preferably contain a silicon-based semiconductor, specifically, preferably contain single crystal silicon. Alternatively, each of the regions may be formed using germanium, silicon germanium, gallium arsenide, aluminum gallium arsenide, or gallium nitride, for example. A structure using silicon whose effective mass is controlled by applying stress to a crystal lattice and changing lattice spacing may be employed. Alternatively, the transistor 300 may be a HEMT (High Electron Mobility Transistor) using gallium arsenide and aluminum gallium arsenide, for example.

For the conductive layer 316 functioning as a gate electrode, a semiconductor material such as silicon containing an element that imparts n-type conductivity, such as arsenic or phosphorus or an element that imparts p-type conductivity, such as boron or aluminum, can be used. Alternatively, for the conductive layer 316, a conductive material such as a metal material, an alloy material, or a metal oxide material can be used, for example.

Note that since a work function depends on the material of the conductor, the threshold voltage of the transistor can be adjusted by selecting the material of the conductor. Specifically, it is preferable to use one or both of titanium nitride and tantalum nitride as the material of the conductor. Moreover, for both conductivity and embeddability, it is preferable to use stacked layers of metal materials of one or both of tungsten and aluminum as the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (Local Oxidation of Silicon) method, an STI (Shallow Trench Isolation) method, or a mesa isolation method.

Over the transistor 300 illustrated in FIG. 35, an insulating layer 320 and an insulating layer 322 are sequentially stacked from the substrate 310 side.

For the insulating layer 320 and the insulating layer 322, one or more selected from silicon oxide, silicon oxynitride, silicon nitride oxide, silicon nitride, aluminum oxide, aluminum oxynitride, aluminum nitride oxide, and aluminum nitride can be used, for example.

The insulating layer 322 may have a function of a planarization film for reducing a level difference caused by the transistor 300 or the like covered with the insulating layer 320 and the insulating layer 322. For example, the top surface of the insulating layer 322 may be planarized by planarization treatment using a chemical mechanical polishing (CMP) method or the like to have improved planarity.

The conductive layer 328 connected to the transistor MTCK and the like provided above the insulating layer 322 is embedded in the insulating layer 320 and the insulating layer 322. Note that the conductive layer 328 functions as a plug or a wiring. Thus, a material that is usable for a conductive layer MPG can be used for the conductive layer 328.

In the display apparatus 50B, the wiring layer 77 is provided over the transistor 300. The wiring layer 77 includes, for example, an insulating layer 324, an insulating layer 326, the conductive layer 330, an insulating layer 350, an insulating layer 352, an insulating layer 354, and the conductive layer 356.

Over the insulating layer 322 and the conductive layer 328, the insulating layer 324 and the insulating layer 326 are stacked in this order. An opening is formed in the insulating layer 324 and the insulating layer 326 in a region overlapping with the conductive layer 328. In addition, the conductive layer 330 is embedded in the opening.

The insulating layer 350, the insulating layer 352, and the insulating layer 354 are stacked sequentially over the insulating layer 326 and the conductive layer 330. An opening is formed in the insulating layer 350, the insulating layer 352, and the insulating layer 354 in a region overlapping with the conductor 330. The conductive layer 356 is embedded in the opening.

The conductor 330 and the conductive layer 356 have a function of a plug or a wiring that is connected to the transistor 300. Note that the conductor 330 and the conductive layer 356 can be provided using a material similar to that for the conductive layer 328 or the conductive layer 596.

For example, the insulating layer 324 and the insulating layer 350 are preferably formed using an insulator having a barrier property against one or more selected from hydrogen, oxygen, and water. Like the insulating layer 594, each of the insulating layer 326, the insulating layer 352, and the insulating layer 354 is preferably formed using an insulator having a comparatively low relative permittivity to reduce parasitic capacitance generated between wirings. Each of the insulating layer 326, the insulating layer 352, and the insulating layer 354 has a function of an interlayer insulating film and a planarization film. Furthermore, the conductive layer 330 and the conductive layer 356 preferably include a conductor having a barrier property against one or more selected from hydrogen, oxygen, and water.

For the conductor having a barrier property against hydrogen, tantalum nitride is preferably used, for example. The use of a stack including tantalum nitride and tungsten that has high conductivity can inhibit diffusion of hydrogen from the transistor 300 while the conductivity of a wiring is maintained. In that case, a tantalum nitride layer having a barrier property against hydrogen is preferably in contact with the insulating layer 350 having a barrier property against hydrogen.

An insulating layer 512 is provided over the insulating layer 354 and the insulating layer 356. An insulating layer IS1 is provided over the insulating layer 512, and an insulating layer IS2 is provided over the insulating layer IS1. A conductive layer 514 functioning as a plug or a wiring is embedded in the insulating layer IS2, the insulating layer IS1, and the insulating layer 512. Thus, one of a source and a drain of the transistor MTCK is electrically connected to one of a source and a drain of the transistor 300. A material that is usable for the conductive layer MPG can be used for conductive layer 514, for example.

The transistor MTCK is provided over the insulating layer IS1 and the conductive layer 514. An insulating layer 574 is formed over the transistor MTCK, and an insulating layer 581 is formed over the insulating layer 574. The conductive layer MPG functioning as a plug or a wiring is embedded in an insulating layer IS3, the insulating layer 574, and the insulating layer 581. Note that Embodiment 2 is referred to for the insulating layer, the conductive layer, and the semiconductor layer around the transistor MTCK.

The insulating layer IS3 is formed above the transistor MTCK. The insulating layer 574 and the insulating layer 581 are stacked in this order over the insulating layer IS3.

The insulating layer 574 preferably has a function of inhibiting diffusion of impurities such as water and hydrogen (e.g., one or both of a hydrogen atom and a hydrogen molecule). In other words, the insulating layer 574 preferably functions as a barrier insulating film that inhibits the entry of the impurities into the transistor MTCK. In addition, it is preferable that the insulating layer 574 have a function of inhibiting diffusion of oxygen (e.g., one or both of an oxygen atom and an oxygen molecule). For example, the insulating layer 574 preferably has lower oxygen permeability than the insulating layer IS2 and the insulating layer IS3.

Thus, the insulating layer 574 preferably functions as a barrier insulating film that inhibits diffusion of impurities such as water and hydrogen. Accordingly, it is preferable to use, for the insulating layer 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulating layer 574. Accordingly, it is possible to inhibit diffusion of impurities such as water and hydrogen to the transistor MTCK side from above the insulating layer 574. Alternatively, oxygen contained in the insulating layer IS3 and the like can be inhibited from diffusing above the insulating layer 574.

The insulating layer 581 is preferably a film functioning as an interlayer film and having a lower permittivity than the insulating layer 574. When a material with a lower permittivity is used for an interlayer film, parasitic capacitance generated between wirings can be reduced. For example, the relative permittivity of the insulating layer 581 is preferably lower than 4, further preferably lower than 3. The relative permittivity of the insulating layer 581 is, for example, preferably 0.7 times or less, further preferably 0.6 times or less the relative permittivity of the insulating layer 574. When a material with a low permittivity is used for the insulating layer 581, the parasitic capacitance generated between wirings can be reduced.

The concentration of impurities such as water and hydrogen in the film of the insulating layer 581 is preferably reduced. In this case, for the insulating layer 581, silicon oxide, silicon oxynitride, silicon nitride oxide, or silicon nitride may be used, for example. For the insulating layer 581, for example, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Moreover, the insulating layer 581 can be formed using a resin. The material that can be used for the insulating layer 581 may be an appropriate combination of the above-described materials.

The insulating layer 592 and the insulating layer 594 are stacked in this order over the insulating layer 574 and the insulating layer 581.

For the insulating layer 592, it is preferable to use an insulating film having a barrier property (referred to as a barrier insulating film) which can prevent diffusion of impurities such as water and hydrogen from the substrate 310 or the transistor MTCK to a region above the insulating layer 592 (e.g., the region where the light-emitting device 130R, the light-emitting device 130G, the light-emitting device 130B, and the like are provided). Accordingly, for the insulating layer 592, it is preferable to use an insulating material that has a function of inhibiting diffusion of impurities such as a hydrogen atom, a hydrogen molecule, and a water molecule (an insulating material through which the above impurities are less likely to pass). Furthermore, depending on the situation, for the insulating layer 592, it is preferable to use an insulating material that has a function of inhibiting diffusion of impurities such as a nitrogen atom, a nitrogen molecule, a nitrogen oxide molecule (e.g., N₂O, NO, and NO₂), and a copper atom (an insulating material through which the above oxygen is less likely to pass). It is preferable that the insulating layer 592 have a function of inhibiting diffusion of oxygen (e.g., one or both of an oxygen atom and an oxygen molecule).

For the film having a barrier property against hydrogen, for example, silicon nitride deposited by a CVD method can be used.

The amount of released hydrogen can be analyzed by thermal desorption spectroscopy (TDS), for example. The amount of hydrogen released from the insulating layer 324 that is converted into hydrogen atoms per area of the insulating layer 324 is less than or equal to 10×10¹⁵ atoms/cm², preferably less than or equal to 5×10¹⁵ atoms/cm² in the TDS in a film-surface temperature range of 50° C. to 500° C., for example.

Like the insulating layer 581, the insulating layer 594 is preferably an interlayer film with a low permittivity. Thus, the insulating layer 594 can be formed using any of the materials usable for the insulating layer 581.

Note that the permittivity of the insulating layer 594 is preferably lower than that of the insulating layer 592. For example, the relative permittivity of the insulating layer 594 is preferably lower than 4, further preferably lower than 3. The relative permittivity of the insulating layer 594 is, for example, preferably 0.7 times or less, further preferably 0.6 times or less the relative permittivity of the insulating layer 592. When the insulating layer 594 is an interlayer film formed using a material with a low permittivity, the parasitic capacitance generated between wirings can be reduced.

The conductive layer MPG functioning as a plug or a wiring is embedded in an insulating layer GI1 and the insulating layer IS3, and a conductive layer 596 functioning as a plug or a wiring is embedded in the insulating layer 592 and the insulating layer 594. In particular, the conductive layer MPG and the conductive layer 596 are electrically connected to the light-emitting device or the like provided above the insulating layer 594. A plurality of conductive layers each having a function of a plug or a wiring are collectively denoted by the same reference numeral in some cases. In this specification and the like, a wiring and a plug connected to the wiring may be a single component. That is, part of a conductive layer functions as a wiring in some cases and part of the conductive layer functions as a plug in other cases.

As a material of each of plugs and wirings (e.g., the conductive layer MPG and the conductive layer 596), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

An insulating layer 598 and an insulating layer 599 are formed in order over the insulating layer 594 and the conductive layer 596.

Like the insulating layer 592, for example, the insulating layer 598 is preferably formed using an insulator having a barrier property against one or more selected from hydrogen, oxygen, and water. Like the insulating layer 594, the insulating layer 599 is preferably formed using an insulator having a comparatively low relative permittivity to reduce parasitic capacitance generated between wirings. The insulating layer 599 has functions of an interlayer insulating film and a planarization film.

The light-emitting device 130 and the connection portion 140 are formed over the insulating layer 599.

The connection portion 140 is referred to as a cathode contact portion in some cases, and is electrically connected to cathode electrodes of the light-emitting device 130R, the light-emitting device 130G, and the light-emitting device 130B. The connection portion 140 in FIG. 35 includes one or more conductive layers selected from a conductive layer 182a to a conductive layer 182c, at least one of a conductive layer 126a to a conductive layer 126c, one or more conductors selected from a conductive layer 129a to a conductive layer 129c, a common layer 114, and a common electrode 115.

Note that the connection portion 140 may be provided to surround four sides of the display portion in the plan view, or may be provided in the display portion (e.g., between adjacent light-emitting devices 130) (not illustrated).

The light-emitting device 130R includes the conductive layer 182a, the conductive layer 126a over the conductive layer 182a, and the conductive layer 129a over the conductive layer 126a. All of the conductive layer 182a, the conductive layer 126a, and the conductive layer 129a can be referred to as pixel electrodes, or some of them can be referred to as pixel electrodes. The light-emitting device 130G includes the conductive layer 182b, the conductive layer 126b over the conductive layer 182b, and the conductive layer 129b over the conductive layer 126b. As in the light-emitting device 130R, all of the conductive layer 182b, the conductive layer 126b, and the conductive layer 129b can be referred to as pixel electrodes, or some of them can be referred to as pixel electrodes. The light-emitting device 130B includes the conductive layer 182c, the conductive layer 126c over the conductive layer 182c, and the conductive layer 129c over the conductive layer 126c. As in the light-emitting device 130R and the light-emitting device 130G, all of the conductive layer 182c, the conductive layer 126c, and the conductive layer 129c can be referred to as pixel electrodes, or some of them can be referred to as pixel electrodes.

For each of the conductive layer 182a to the conductive layer 182c and the conductive layer 126a to the conductive layer 126c, a conductive layer functioning as a reflective electrode can be used, for example. For the conductive layer functioning as a reflective electrode, a conductor with high visible-light reflectivity such as silver, aluminum, or an alloy film of silver (Ag), palladium (Pd), and copper (Cu) (an Ag—Pd—Cu (APC) film) can be used. The conductive layer 182a to the conductive layer 182c and the conductive layer 126a to the conductive layer 126c can each be a stacked-layer film in which a pair of titanium films sandwich aluminum (a film in which Ti, Al, and Ti are stacked in this order) or a stacked-layer film in which a pair of indium tin oxide films sandwich silver (a film in which ITO, Ag, and ITO are stacked in this order).

For example, a conductive layer functioning as a reflective electrode may be used for the conductive layer 182a to the conductive layer 182c, and a material with a high light-transmitting property may be used for the conductive layer 126a to the conductive layer 126c. Examples of the material with a high light-transmitting property include an alloy of silver and magnesium and indium tin oxide.

A conductive layer functioning as a transparent electrode can be used for the conductive layer 129a to the conductive layer 129c. For the conductive layer functioning as a transparent electrode, for example, the above-described conductive layer with a high light-transmitting property can be used.

A microcavity structure may be provided in the light-emitting device 130 to be described in detail later. The microcavity structure refers to a structure in which the distance between the bottom surface of the light-emitting layer and the top surface of a lower electrode is set to a thickness depending on a wavelength of color of light emitted from the light-emitting layer. In that case, a light-transmitting and light-reflective conductive material is preferably used for the conductive layer 129a to the conductive layer 129c serving as an upper electrode (a common electrode), and light-reflective conductive materials are preferably used for the conductive layer 182a to the conductive layer 182c and the conductive layer 126a to the conductive layer 126c which serve as lower electrodes (pixel electrodes).

The microcavity structure refers to a structure in which the optical distance between the lower electrode and the light-emitting layer is adjusted to be (2n−1)λ/4 (n is an integer greater than or equal to 1, and λ is a wavelength of emitted light to be amplified). Thus, light that is reflected back by the lower electrode (reflected light) considerably interferes with light that directly enters the upper electrode from the light-emitting layer (incident light). Accordingly, the phases of the reflected light and the incident light each having the wavelength λ can be aligned with each other, and the light emitted from the light-emitting layer can be further amplified. Meanwhile, in the case where the reflected light and the incident light each have a wavelength other than the wavelength λ, their phases are not aligned with each other, resulting in attenuation without resonation.

The conductive layer 182a is connected to the conductive layer 596 embedded in the insulating layer 594 through an opening formed in the insulating layer 599. An end portion of the conductive layer 126a is positioned outward from an end portion of the conductive layer 182a. The end portion of the conductive layer 126a and an end portion of the conductive layer 129a are aligned or substantially aligned with each other.

Detailed description of the conductive layer 182b, the conductive layer 126b, and the conductive layer 129b of the light-emitting device 130G and the conductive layer 182c, the conductive layer 126c, and the conductive layer 129c of the light-emitting device 130B is omitted because these conductive layers are similar to the conductive layer 182a, the conductive layer 126a, and the conductive layer 129a of the light-emitting device 130R.

Depressed portions are formed in the conductive layer 182a, the conductive layer 182b, and the conductive layer 182c to cover the openings provided in the insulating layer 599. A layer 128 is embedded in the depression portions.

The layer 128 has a function of filling the depression portions of the conductive layer 182a to the conductive layer 182c for planarization. The conductive layer 126a to the conductive layer 126c electrically connected to the conductive layer 182a to the conductive layer 182c, respectively, are provided over the conductive layer 182a to the conductive layer 182c and the layer 128. Thus, regions overlapping with the depression portions of the conductive layer 182a to the conductive layer 182c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. For the layer 128, an acrylic resin, a polyimide resin, an epoxy resin, a polyamide resin, a polyimide-amide resin, a siloxane resin, a benzocyclobutene-based resin, a phenol resin, or a precursor of any of these resins can be used, for example. A photosensitive resin can also be used for the layer 128. As the photosensitive resin, a positive material or a negative material is given.

When a photosensitive resin is used, the layer 128 can be formed through only light-exposure and development steps, reducing the influence of dry etching or wet etching on the surfaces of the conductive layer 182a, the conductive layer 182b, and the conductive layer 182c. When the layer 128 is formed using a negative photosensitive resin, the layer 128 can be formed using the same photomask (light-exposure mask) as the photomask used for forming the opening in the insulating layer 599 in some cases.

The light-emitting device 130R includes a first layer 113a, the common layer 114 over the first layer 113a, and the common electrode 115 over the common layer 114. The light-emitting device 130G includes a second layer 113b, the common layer 114 over the second layer 113b, and the common electrode 115 over the common layer 114. The light-emitting device 130B includes a third layer 113c, the common layer 114 over the third layer 113c, and the common electrode 115 over the common layer 114.

The first layer 113a is formed to cover the top surface and the side surface of the conductive layer 126a and the top surface and the side surface of the conductive layer 129a. Similarly, the second layer 113b is formed to cover the top surface and the side surface of the conductive layer 126b and the top surface and the side surface of the conductive layer 129b. Similarly, the third layer 113c is formed to cover the top surface and side surface of the conductive layer 126c and the top surface and side surface of the conductive layer 129c. Accordingly, regions provided with the conductive layer 126a, the conductive layer 126b, and the conductive layer 126c can be entirely used as the light-emitting regions of the light-emitting device 130R, the light-emitting device 130G, and the light-emitting device 130B, increasing the aperture ratio of the pixels.

In the light-emitting device 130R, the first layer 113a and the common layer 114 can be collectively referred to as an EL layer. Similarly, in the light-emitting device 130G, the second layer 113b and the common layer 114 can be collectively referred to as an EL layer. Similarly, in the light-emitting device 130B, the third layer 113c and the common layer 114 can be collectively referred to as an EL layer

There is no particular limitation on the structure of the light-emitting device in this embodiment, and the light-emitting device can have a single structure or a tandem structure.

The first layer 113a, the second layer 113b, and the third layer 113c are each processed into an island shape by a photolithography method. At each of end portions of the first layer 113a, the second layer 113b, and the third layer 113c, an angle between the top surface and side surface is approximately 90°. By contrast, for example, an organic film formed using an FMM (Fine Metal Mask) tends to have a thickness that gradually decreases with decreasing distance to an end portion, and has a sloped top surface in an area ranging from 1 μm to 10 μm, both inclusive, for example; thus, such an organic film has a shape whose top surface and side surface cannot be easily distinguished from each other.

The top surface and side surface of each of the first layer 113a, the second layer 113b, and the third layer 113c are clearly distinguished from each other. Accordingly, as for the first layer 113a and the second layer 113b which are adjacent to each other, one of the side surfaces of the first layer 113a and one of the side surfaces of the second layer 113b face to each other. This applies to a combination of any of the first layer 113a, the second layer 113b, and the third layer 113c.

The first layer 113a, the second layer 113b, and the third layer 113c each include at least a light-emitting layer. For example, a structure is preferable in which the first layer 113a includes a light-emitting layer that emits red light, the second layer 113b includes a light-emitting layer that emits green light, and the third layer 113c includes a light-emitting layer that emits blue light. Other than the above colors, cyan, magenta, yellow, or white can be employed for the light-emitting layers.

The first material layer 113a, the second material layer 113b, and the third material layer 113c each preferably include a light-emitting layer and a carrier-transport layer (an electron-transport layer or a hole-transport layer) over the light-emitting layer. Since surfaces of the first layer 113a, the second layer 113b, and the third layer 113c may be exposed in the manufacturing process of the display apparatus, providing the carrier-transport layer over the light-emitting layers inhibits the light-emitting layers from being exposed on the outermost surface, so that damage to the light-emitting layers can be reduced. Accordingly, the reliability of the light-emitting devices can be improved.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared between the light-emitting device 130R, the light-emitting device 130G, and the light-emitting device 130B.

The common electrode 115 is shared between the light-emitting device 130R, the light-emitting device 130G, and the light-emitting device 130B. As illustrated in FIG. 35, the common electrode 115 shared between the plurality of light-emitting devices is electrically connected to a conductive layer included in the connection portion 140.

The insulating layer 125 preferably has a function of a barrier insulating layer against one or both of water and oxygen. Alternatively, the insulating layer 125 preferably has a function of inhibiting diffusion of one or both of water and oxygen. Alternatively, the insulating layer 125 preferably has a function of capturing or fixing (also referred to as gettering) one or both of water and oxygen. When the insulating layer 125 has a function of a barrier insulating layer or a gettering function, entry of impurities (typically, one or both of water and oxygen) that would diffuse into the light-emitting devices from the outside can be inhibited. With this structure, a highly reliable light-emitting device and a highly reliable display panel can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against one or both of water and oxygen can be increased. For example, the insulating layer 125 preferably has one of a sufficiently low hydrogen concentration and a sufficiently low carbon concentration, desirably has both of them.

As the insulating layer 127, an insulating layer containing an organic material can be suitably used. As the organic material, a photosensitive organic resin is preferably used; for example, a photosensitive resin composition containing an acrylic resin may be used. The viscosity of the material for the insulating layer 127 is greater than or equal to 1 cP and less than or equal to 1500 cP, and is preferably greater than or equal to 1 cP and less than or equal to 12 cP. By setting the viscosity of the material of the insulating layer 127 in the above range, the insulating layer 127 having a tapered shape can be formed relatively easily. Note that in this specification and the like, an acrylic resin refers to not only a polymethacrylic acid ester or a methacrylic resin, but also all the acrylic-based polymers in a broad sense in some cases.

Note that in this specification and the like, a tapered shape indicates a shape in which at least part of a side surface of a structure is inclined to a substrate surface. For example, a tapered shape preferably includes a region where an angle between the inclined side surface and the substrate surface (such an angle is also referred to as a taper angle) is less than 90°.

Note that the organic material that can be used for the insulating layer 127 is not limited to the above materials as long as the insulating layer 127 has a tapered side surface. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be employed for the insulating layer 127 in some cases. For the insulating layer 127, for example, a photoresist can be used as the photosensitive resin in some cases. Note that as the photosensitive resin, a positive material or a negative material can be used.

For the insulating layer 127, a material absorbing visible light may be used. When the insulating layer 127 absorbs light from the light-emitting device, leakage of light (stray light) from the light-emitting device to the adjacent light-emitting device through the insulating layer 127 can be inhibited. Thus, the display quality of the display panel can be improved. Since the display quality of the display panel can be improved without using a polarizing plate, the weight and thickness of the display panel can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two colors or three or more colors is particularly preferable, in which case the effect of blocking visible light can be enhanced. In particular, mixing color filter materials of three or more colors enables the formation of a black or nearly black resin layer.

For example, the insulating layer 127 can be formed by a wet film formation method such as spin coating, dipping, spray coating, ink-jetting, dispensing, screen printing, offset printing, doctor blade coating, slit coating, roll coating, curtain coating, or knife coating. Specifically, an organic insulating film that is to be the insulating layer 127 is preferably formed by spin coating.

The insulating layer 127 is formed at a temperature lower than the upper temperature limit of the EL layer. The typical substrate temperature in formation of the insulating layer 127 is lower than or equal to 200° C., preferably lower than or equal to 180° C., further preferably lower than or equal to 160° C., still further preferably lower than or equal to 150° C., yet still further preferably lower than or equal to 140° C.

The description is made below on the structure of the insulating layer 127 or the like using the structure of the insulating layer 127 between the light-emitting device 130R and the light-emitting device 130G as an example. Note that the same applies to the insulating layer 127 between the light-emitting device 130G and the light-emitting device 130B, the insulating layer 127 between the light-emitting device 130B and the light-emitting device 130R, and the like. In the description below, an end portion of the insulating layer 127 over the second layer 113b is used as an example in some cases, and the same can apply to an end portion of the insulating layer 127 over the first layer 113a, an end portion of the insulating layer 127 over the third layer 113c, and the like.

The insulating layer 127 preferably has the tapered side surface with a taper angle θ1 in the cross-sectional view of the display apparatus. The taper angle θ1 is an angle subtended between the side surface of the insulating layer 127 and the substrate surface. Note that the taper angle θ1 is not limited to the angle with the substrate surface, and may be an angle subtended between the side surface of the insulating layer 127 and the top surface of the flat portion of the insulating layer 125 or the top surface of the flat portion of the second layer 113b. When the side surface of the insulating layer 127 has a tapered shape, a side surface of the insulating layer 125 and a side surface of the mask layer 118a also have a tapered shape in some cases.

The taper angle θ1 of the insulating layer 127 is less than 90°, preferably less than or equal to 60°, further preferably less than or equal to 45°. Such a forward tapered shape of the end portion of the side surface of the insulating layer 127 can prevent disconnection, local thinning, or the like from occurring in the common layer 114 and the common electrode 115 which are provided over the end portion of the side surface of the insulating layer 127, leading to film formation with good coverage. Accordingly, the in-plane uniformity of the common layer 114 and the common electrode 115 can be improved, leading to higher display quality of the display apparatus.

The top surface of the insulating layer 127 preferably has a convex shape in a cross-sectional view of the display apparatus. The convex shape of the top surface of the insulating layer 127 is preferably a shape gently bulged toward the center. The convex portion at the center of the top surface of the insulating layer 127 preferably has a shape connected continuously to the tapered end portion of the side surface. When the insulating layer 127 has such a shape, the common layer 114 and the common electrode 115 can be formed with good coverage over the entire insulating layer 127.

The insulating layer 127 is formed in a region between two EL layers (e.g., a region between the first layer 113a and the second layer 113b). At this time, part of the insulating layer 127 is placed at a position sandwiched between an end portion of the side surface of one of the EL layers (e.g., the first layer 113a) and an end portion of the side surface of the other of the EL layers (e.g., the second layer 113b).

One end portion of the insulating layer 127 preferably overlaps with the conductive layer 126a serving as a pixel electrode, and the other end portion of the insulating layer 127 preferably overlaps with the conductive layer 126b serving as a pixel electrode. With such a structure, the end portion of the insulating layer 127 can be formed over a substantially flat region of the first layer 113a (the second layer 113b). This makes it relatively easy to process the tapered shape of the insulating layer 127 as described above.

By providing the insulating layer 127 and the like as described above, a disconnected portion and a locally thinned portion can be prevented from being formed in the common layer 114 and the common electrode 115 from a substantially flat region in the first layer 113a to a substantially flat region in the second layer 113b. Thus, between the light-emitting devices, a connection defect caused by the disconnected portion and an increase in electric resistance caused by the locally thinned portion can be inhibited from occurring in the common layer 114 and the common electrode 115.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where a distance between two adjacent island-shaped EL layers is less than or equal to 1 μm, preferably less than or equal to 0.5 μm (500 nm), further preferably less than or equal to 100 nm. The distance between light-emitting devices is shortened in this manner, whereby a high-definition display apparatus with a high aperture ratio can be provided.

The protective layer 131 is provided over the light-emitting device 130. The protective layer 131 is a film serving as a passivation film for protecting the light-emitting devices 130. Provision of the protective layer 131 covering the light-emitting device can inhibit an impurity such as water and oxygen from entering the light-emitting device, and increase the reliability of the light-emitting device 130. For the protective layer 131, aluminum oxide, silicon nitride, or silicon nitride oxide can be used, for example.

The protective layer 131 and the substrate 119 are bonded to each other with an adhesive layer 107. A solid sealing structure, a hollow sealing structure, or the like can be employed to seal the light-emitting devices. In FIG. 35, a solid sealing structure is employed in which a space between the substrate 310 and the substrate 119 is filled with the adhesive layer 107. Alternatively, a hollow sealing structure may be employed, in which the space is filled with an inert gas (e.g., nitrogen or argon). Here, the adhesive layer 107 may be provided not to overlap with the light-emitting devices. The space may be filled with a resin other than the frame-shaped adhesive layer 107.

For the adhesive layer 107, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-liquid-mixture-type resin may be used. An adhesive sheet may be used.

The display apparatus 50B has a top-emission structure. Light from the light-emitting device is emitted toward the substrate 119 side. Thus, for the substrate 119, a material having a high visible-light-transmitting property is preferably used. For example, as the substrate 119, a substrate having a high visible-light-transmitting property may be selected from substrates usable as the substrate 310. The pixel electrode contains a material that reflects visible light, and a counter electrode (the common electrode 115) contains a material that transmits visible light. Note that the display apparatus of one embodiment of the present invention may be not a top-emission display apparatus but a bottom-emission display apparatus where light from the light-emitting device is emitted to the substrate 310 side. In that case, a substrate having a high visible-light-transmitting property is selected as the substrate 310.

When one of the above structure examples is applied to a display apparatus, a high-definition display apparatus having high resolution can be achieved in some cases. Specifically, for example, a display apparatus with a resolution of HD (number of pixels: 1280×720), FHD (number of pixels: 1920×1080), WQHD (number of pixels: 2560×1440), WQXGA (number of pixels: 2560×1600), 4K (number of pixels: 3840× 2160), or 8K (number of pixels: 7680× 4320) can be achieved in some cases. Furthermore, specifically, for example, a high-definition display apparatus with greater than or equal to 100 ppi, greater than or equal to 300 ppi, greater than or equal to 500 ppi, greater than or equal to 1000 ppi, greater than or equal to 2000 ppi, greater than or equal to 3000 ppi, greater than or equal to 5000 ppi, or greater than or equal to 6000 ppi can be provided in some cases.

Note that this embodiment can be combined with any of the same embodiment or the other embodiments in this specification as appropriate. For example, the configurations, structures, methods, and the like described in this embodiment can be used in an appropriate combination with any of the configurations, structures, methods, and the like described in this embodiment. Moreover, the configurations, structures, methods, and the like described in this embodiment can be used in an appropriate combination with any of the configurations, structures, methods, and the like described in the other embodiments and the like.

At least part of the structure examples, the drawings corresponding thereto, and the like described in this embodiment can be combined with the other structure examples, the other drawings corresponding thereto, and the like as appropriate.

### Embodiment 5

In this embodiment, an electronic device, a display apparatus, and the like according to one embodiment of the present invention will be described. The electronic device of one embodiment of the present invention can be suitably used also as a wearable electronic device for VR or AR applications, for example.

### Structure Example of Electronic Device

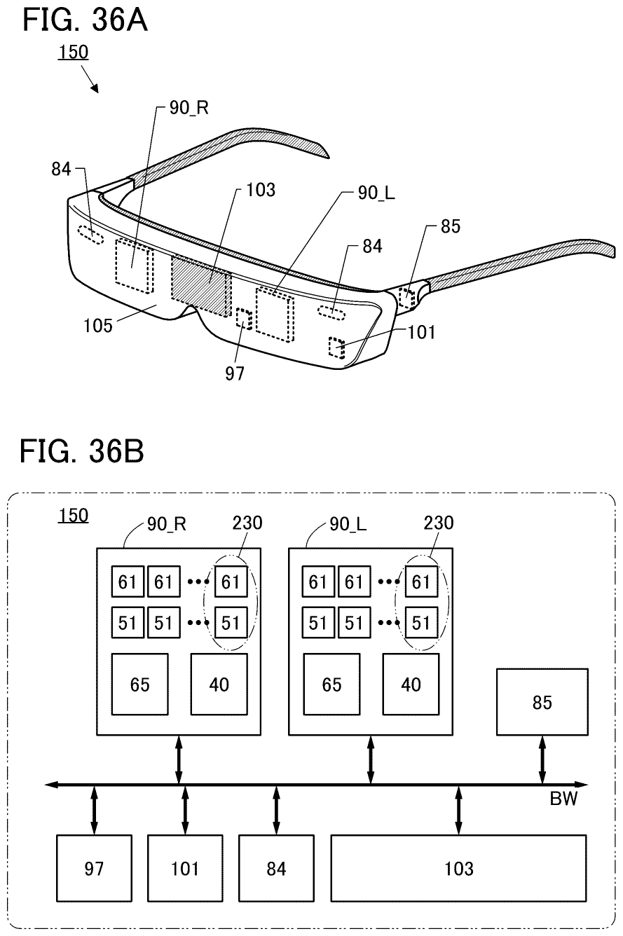

FIG. 36A is a perspective view of a glasses-type electronic device 150 as an example of a wearable electronic device. FIG. 36A illustrates the electronic device 150 that includes, in a housing 105, a pair of display apparatuses 90 (a display apparatus 90_L and a display apparatus 90_R), a motion detection portion 101, gaze detection portions 84, an arithmetic portion 103, and a communication portion 85.

FIG. 36B is a block diagram of the electronic device 150 in FIG. 36A. As in FIG. 36A, the electronic device 150 includes the display apparatus 90_L, the display apparatus 90_R, the motion detection portion 101, the gaze detection portions 84, the arithmetic portion 103, and the communication portion 85, and a variety of signals are transmitted and received between these components through a bus wiring BW. Each of the display apparatus 90_L and the display apparatus 90_R includes a plurality of pixels 230, a driver circuit 65, and a functional circuit 40. One pixel 230 includes one light-emitting device 61 and one pixel circuit 51. Thus, each of the display apparatus 90_L and the display apparatus 90_R includes a plurality of light-emitting devices 61 and a plurality of pixel circuits 51.

The motion detection portion 101 has a function of detecting the motion of the housing 105, i.e., the motion of the head of the user who wears the electronic device 150. The motion detection portion 101 can include a motion sensor using a MEMS technology, for example. As the motion sensor, a three-axis motion sensor, a six-axis motion sensor, or the like can be used. Information on the motion of the housing 105 detected by the motion detection portion 101 may be referred to as first information, motion data, or the like.

The gaze detection portion 84 has a function of obtaining information regarding the user's gaze. Specifically, the gaze detection portion 84 has a function of detecting the user's gaze. The user's gaze, for example, may be obtained by a gaze measurement (eye tracking) method such as a pupil center corneal reflection method or a bright/dark pupil effect method. Alternatively, the user's gaze may be obtained by a gaze measurement method using a laser, an ultrasonic wave, or the like.

The arithmetic portion 103 has a function of calculating the user's gaze point by using a gaze detection result in the gaze detection portion 84. That is, it is possible to detect which object the user is gazing in the image displayed on the display apparatus 90_L and the display apparatus 90_R. In addition, whether or not the user is gazing at a part other than the screen can be detected. Note that information regarding the user's gaze obtained by the gaze detection portion 84 (the gaze detection result) may be referred to as second information, gaze information, or the like in some cases.

The arithmetic portion 103 has a function of performing drawing processing (arithmetic process of image data) in accordance with the motion of the housing 105. The arithmetic portion 103 performs the drawing processing in accordance with the motion of the housing 105 with the use of the first information and image data that is input from the outside through the communication portion 85. As the image data, for example, a 360-degree omnidirectional image data can be used. The 360-degree omnidirectional image data is image data captured by a celestial sphere camera (an omnidirectional camera or a 360° camera), image data generated by computer graphics, or the like, for example. The arithmetic portion 103 has a function of converting the 360-degree omnidirectional image data on the basis of the first information into image data that can be displayed on the display apparatus 90_L and the display apparatus 90_R.

The arithmetic portion 103 has a function of determining the sizes and shapes of a plurality of regions that are set for each of the display portions of the display apparatus 90_L and the display apparatus 90_R with use of the second information. Specifically, the arithmetic portion 103 calculates a gaze point on the display portion on the basis of the second information and sets a first region S1 to a third region S3 and the like on the display portion with use of the gaze point as a reference.

A microprocessor such as a DSP (Digital Signal Processor), or a GPU (Graphics Processing Unit) as well as a central processing unit (CPU) can be used alone or in combination as the arithmetic portion 103. A structure may be employed in which such a microprocessor is obtained with a PLD (Programmable Logic Device) such as an FPGA (Field Programmable Gate Array) or an FPAA (Field Programmable Analog Array).

The arithmetic portion 103 interprets and executes instructions from various programs with the use of a processor to perform various kinds of data processing and program control. The programs that can be executed by the processor may be stored in a memory region included in the processor or a memory portion which is additionally provided. As the memory portion, a memory device using a nonvolatile memory element, such as a flash memory, an MRAM (Magnetoresistive Random Access Memory), a PRAM (Phase change RAM), an ReRAM (Resistive RAM), or an FeRAM (Ferroelectric RAM); a memory device using a volatile memory element, such as a DRAM (Dynamic RAM) and an SRAM (Static RAM); or the like may be used, for example.

The communication portion 85 has a function of communicating with an external device by wire or wirelessly to obtain a variety of data, including image data. The communication portion 85 is provided with a high frequency circuit (RF circuit), for example, to transmit and receive an RF signal. The high frequency circuit is a circuit for performing mutual conversion between an electromagnetic signal and an electrical signal in a frequency band that is set by national laws to perform wireless communication with another communication apparatus using the electromagnetic signal. In the case of performing wireless communication, it is possible to use, as a communication protocol or a communication technology, a communication standard such as LTE (Long Term Evolution), GSM (Global System for Mobile Communication: registered trademark), EDGE (Enhanced Data Rates for GSM Evolution), CDMA 2000 (Code Division Multiple Access 2000), or WCDMA (Wideband Code Division Multiple Access: registered trademark), or a communication standard developed by IEEE such as Wi-Fi (registered trademark), Bluetooth (registered trademark), or ZigBee (registered trademark). The third-generation mobile communication system (3G), the fourth-generation mobile communication system (4G), or the fifth-generation mobile communication system (5G) defined by the International Telecommunication Union (ITU) or the like can be used.

The communication portion 85 may include an external port such as a LAN (Local Area Network) connection terminal, a digital broadcast-receiving terminal, or an AC adaptor connection terminal.

Each of the display apparatus 90_L and the display apparatus 90_R includes the plurality of light-emitting devices 61, the plurality of pixel circuits 51, the driver circuit 65, and the functional circuit 40. The pixel circuit 51 has a function of controlling light emission of the light-emitting device 61. The driver circuit 65 has a function of controlling the pixel circuit 51.

Information on the plurality of regions in the display portion of the display apparatus determined by the arithmetic portion 103 can be used for driving such that the resolution differs from region to region. The functional circuit 40 has a function of controlling the driver circuit 65 such that display with high resolution is performed in a region close to a gaze point and controlling the driver circuit 65 such that display with low resolution is performed in a region distant from the gaze point.

For example, when rewriting of image data is performed for every other pixel or every other plurality of pixels, display with low resolution can be performed. By reducing the number of pixels where image data are rewritten, power consumption of the display apparatus can be reduced.

The electronic device 150 may be provided with a sensor 97. The sensor 97 has a function of obtaining information on one or more of the senses of sight, hearing, touch, taste, and smell of the user. Specifically, the sensor 97 has a function of sensing or measuring one or more of the following information: force, displacement, position, speed, acceleration, angular velocity, rotational frequency, distance, light, magnetism, temperature, sound, time, electric field, current, voltage, electric power, radiation, humidity, gradient, oscillation, smell, and infrared rays. The electronic device 150 may be provided with one or more sensors 97.

With use of the sensor 97, ambient temperature, humidity, illumination, odor, and the like may be measured. Furthermore, with use of the sensor 97, information for personal authentication using a fingerprint, a palm print, an iris, a retina, a shape of a blood vessel (including the shape of a vein and a shape of an artery), a face, or the like may be obtained, for example. Moreover, with use of the sensor 97, the number of blinks, eyelid behavior, pupil size, body temperature, pulse, oxygen saturation in blood, or the like of the user may be measured, so that the user's fatigue level, health condition, and the like can be detected. The electronic device 150 may sense the user's fatigue level, health condition, and the like and display an alert or the like on the display apparatus 90.

The operation of the electronic device 150 may be controlled by detecting the user's gaze and eyelid movement. Since the user does not need to touch and operate the electronic device 150, an input operation or the like can be achieved with holding nothing in both hands (in a state where both hands are free).

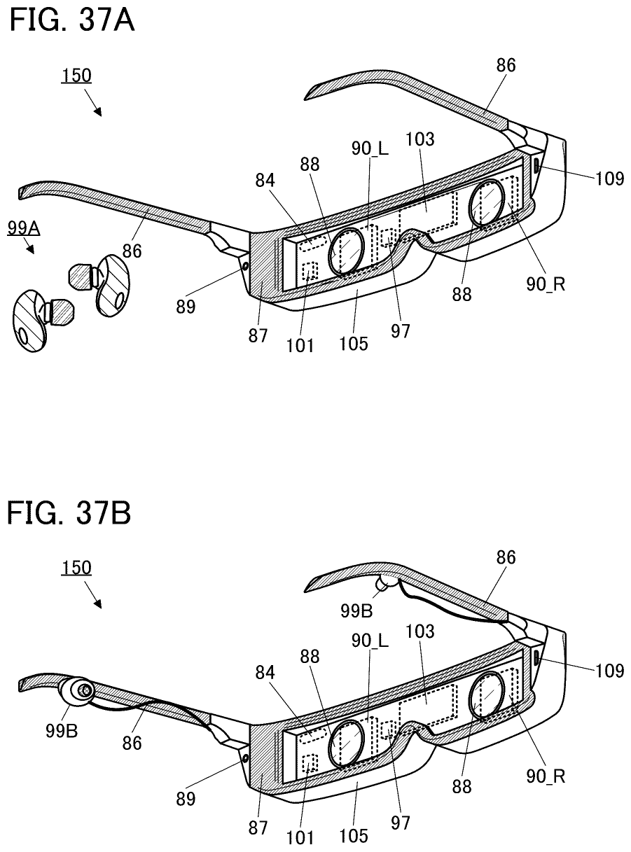

FIG. 37A is a perspective view illustrating the electronic device 150. In FIG. 37A, the housing 105 of the electronic device 150 includes therein, for example, a wearing portion 86, a cushion 87, a pair of lenses 88, and the like, in addition to the pair of the display apparatus 90_L and the display apparatus 90_R and the arithmetic portion 103. The pair of the display apparatus 90_L and the display apparatus 90_R are positioned inside the housing 105 so as to be seen through the lenses 88.

In addition, an input terminal 109 and an output terminal 89 are provided in the housing 105 illustrated in FIG. 37A. To the input terminal 109, a cable for supplying an image signal (image data) from a video output device or the like, power for charging a battery (not illustrated) provided in the housing 105, or the like can be connected. The output terminal 89 can function as, for example, an audio output terminal to which earphones, headphones, or the like can be connected.

The housing 105 preferably includes a mechanism by which the left and right positions of the lenses 88 and the display apparatus 90_L and the display apparatus 90_R can be adjusted to the optimal positions in accordance with the positions of the user's eyes. Moreover, the housing 105 preferably includes a mechanism for adjusting focus by changing the distance between the lenses 88 and each of the display apparatus 90_L and the display apparatus 90_R.

The cushion 87 is a portion to be in contact with the user's face (forehead, cheek, or the like). When the cushion 87 is in close contact with the user's face, external light incidence (light leakage) can be prevented, which increases the sense of immersion. A soft material is preferably used for the cushion 87 so that the cushion 87 can be in close contact with the user's face when the user wears the electronic device 150. Using such a material is preferable because it provides a soft texture and the user does not feel cold when wearing the electronic device in a cold season, for example. The member to be in contact with the user's skin, such as the cushion 87 or the wearing portion 86, is preferably detachable, in which case cleaning or replacement can be easily performed.

The electronic device of one embodiment of the present invention may further include earphones 99A. The earphones 99A include a communication portion (not illustrated) and have a wireless communication function. The earphones 99A can output audio data with the wireless communication function. The earphones 99A may include a vibration mechanism functioning as bone-conduction earphones.

The earphones 99A can be connected to the wearing portion 86 directly or by wire like earphones 99B illustrated in FIG. 37B. The earphones 99B and the wearing portion 86 may each have a magnet. This is preferable because the earphones 99B can be fixed to the wearing portion 86 with magnetic force and thus can be easily housed.

### Structure Example of Display Apparatus

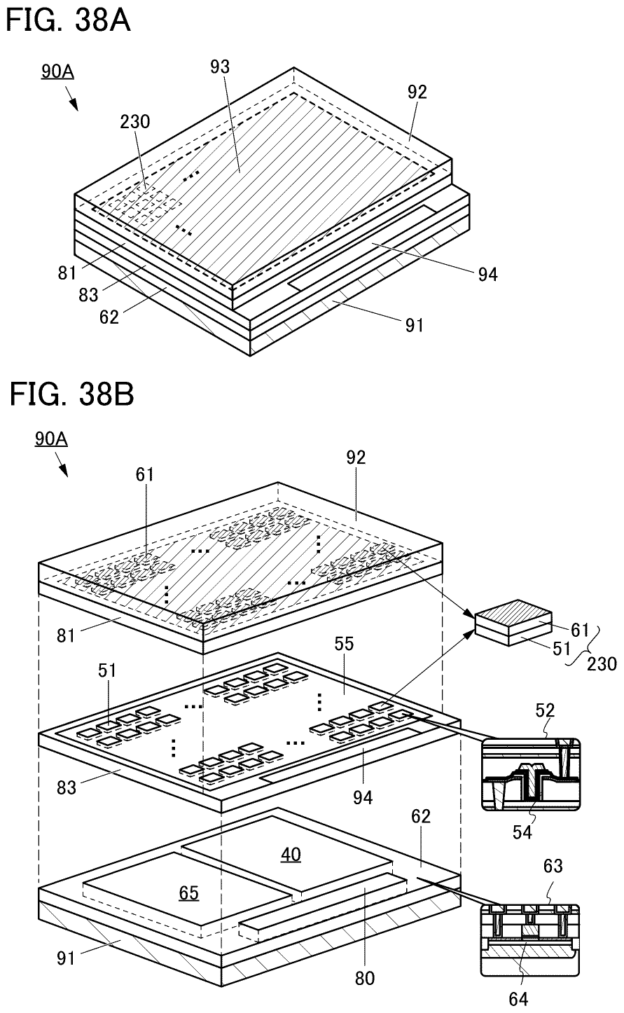

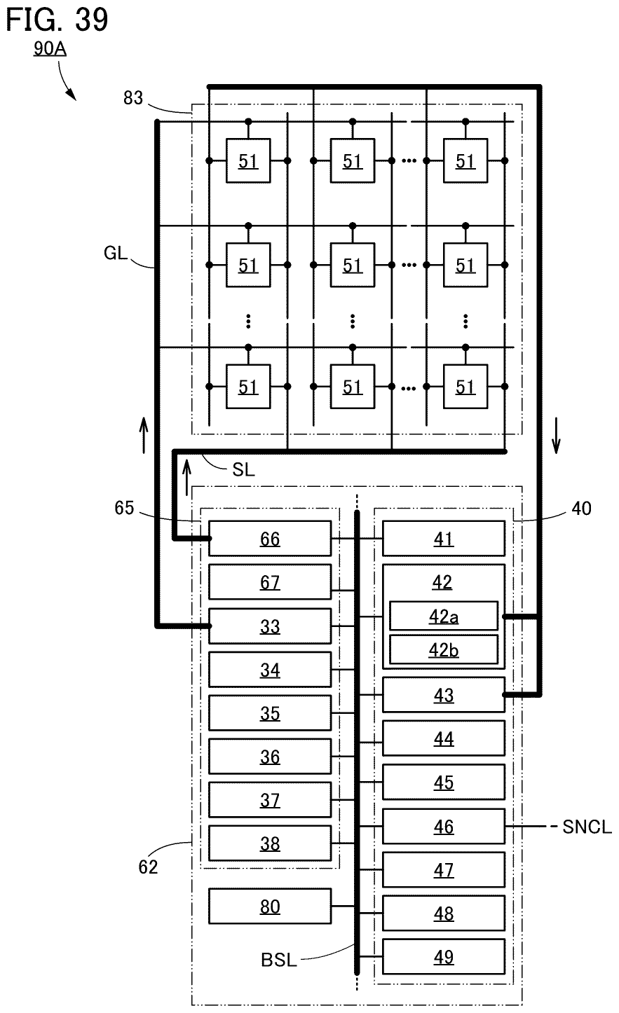

A structure of a display apparatus 90A that can be used for the display apparatus 90_L and the display apparatus 90_R illustrated in FIG. 36A and FIG. 36B will be described with reference to FIG. 38A, FIG. 38B, and FIG. 39.

FIG. 38A is a perspective view of the display apparatus 90A that can be used for the display apparatus 90_L and the display apparatus 90_R illustrated in FIG. 36A and FIG. 36B.

The display apparatus 90A includes a substrate 91 and a substrate 92. The display apparatus 90A includes a display portion 93 provided between the substrate 91 and the substrate 92. The display portion 93 includes the plurality of pixels 230. The pixels 230 each include the pixel circuit 51 and the light-emitting device 61. The display portion 93 is a region for displaying an image in the display apparatus 90A.

By using the pixels 230 arranged in a matrix of 1920×1080 pixels, the display portion 93 can perform display with a resolution of a so-called full hi-vision (also referred to as “2K resolution”, “2K1K”, “2K”, or the like). For example, by using the pixels 230 arranged in a matrix of 3840×2160 pixels, the display portion 93 can perform display with a resolution of a so-called ultra hi-vision (also referred to as “4K resolution”, “4K2K”, “4K”, or the like). For example, by using the pixels 230 arranged in a matrix of 7680×4320 pixels, the display portion 93 can perform display with a resolution of a so-called super hi-vision (also referred to as “8K resolution”, “8K4K”, “8K”, or the like). By increasing the number of pixels 230, the display portion 93 that can perform display with 16K or 32K resolution can also be obtained.

Furthermore, the pixel density (definition) of the display portion 93 is preferably higher than or equal to 1000 ppi and lower than or equal to 10000 ppi. For example, the definition may be higher than or equal to 2000 ppi and lower than or equal to 6000 ppi, or higher than or equal to 3000 ppi and lower than or equal to 5000 ppi.

Note that there is no particular limitation on the screen ratio (aspect ratio) of the display portion 93. For example, the display portion 93 is compatible with a variety of screen ratios such as 1:1 (a square), 4:3, 16:9, and 16:10.

In this specification and the like, the term “element” can be replaced with the term “device” in some cases. For example, a display element, a light-emitting device, and a liquid crystal element can be rephrased as a display device, a light-emitting device, and a liquid crystal device, respectively.

Various kinds of signals and power supply potentials are input to the display apparatus 90A from the outside via a terminal portion 94, so that image display can be performed using a display element provided in the display portion 93. Any of a variety of elements can be used as the display element. Typically, a light-emitting device having a function of emitting light, such as an organic EL element or an LED element, a liquid crystal element, a MEMS (Micro Electro Mechanical Systems) element, or the like can be used.

A plurality of layers are provided between the substrate 91 and the substrate 92, and each of the layers is provided with a transistor for a circuit operation or a display element which emits light. A pixel circuit having a function of controlling an operation of the display element, a driver circuit having a function of controlling the pixel circuit, a functional circuit having a function of controlling the driver circuit, and the like are provided in the plurality of layers. FIG. 38B is a perspective view schematically illustrating the structures of the layers provided between the substrate 91 and the substrate 92.

A layer 62 is provided over the substrate 91. The layer 62 includes the driver circuit 65, the functional circuit 40, and an input/output circuit 80. The layer 62 includes a transistor 63 containing silicon in a channel formation region 64. The substrate 91 is, for example, a silicon substrate. A silicon substrate is preferable because it has higher thermal conductivity than a glass substrate. By providing the driver circuit 65, the functional circuit 40, and the input/output circuit 80 in the same layer, wirings electrically connecting the driver circuit 65, the functional circuit 40, and the input/output circuit 80 can be short. As a result, charge and discharge time of a control signal used when the functional circuit 40 controls the driver circuit 65 becomes short, leading to a reduction in power consumption. In addition, charge and discharge time during which a signal is supplied from the input/output circuit 80 to the functional circuit 40 and the driver circuit 65 becomes short, leading to a reduction in power consumption.

The transistor 63 can be a transistor containing single crystal silicon in its channel formation region (also referred to as a “c-Si transistor”), for example. In particular, the use of a transistor containing single crystal silicon in a channel formation region as the transistor provided in the layer 62 can increase the on-state current of the transistor. This enables high-speed driving of circuits included in the layer 62 and is thus preferable. The Si transistor can be formed by microfabrication to have a channel length greater than or equal to 3 nm and less than or equal to 10 nm, for example; thus, a CPU, an accelerator such as a GPU, an application processor, or the like can be integrated with the display portion in the display apparatus 90A.

A transistor containing polycrystalline silicon in its channel formation region (also referred to as a “Poly-Si transistor”) may be provided in the layer 62. As the polycrystalline silicon, low-temperature polysilicon (LTPS) may be used. Note that a transistor containing LTPS in its channel formation region is also referred to as an “LTPS transistor”. An OS transistor may be provided in the layer 62 as necessary.

Any of a variety of circuits such as a shift register, a level shifter, an inverter, a latch, an analog switch, and a logic circuit can be used as the driver circuit 65. The driver circuit 65 includes a gate driver circuit, a source driver circuit, or the like, for example. In addition, an arithmetic circuit, a memory circuit, a power supply circuit, and the like may be included. Since the gate driver circuit, the source driver circuit, and other circuits can be placed to overlap with the display portion 93, the width of a non-display region (also referred to as a bezel) provided along the outer periphery of the display portion 93 of the display apparatus 90A can be extremely narrow compared with the case where these circuits and the display portion 93 are arranged side by side, whereby the display apparatus 90A can be downsized.

The functional circuit 40 has a function of an application processor for controlling the circuits in the display apparatus 90A and generating signals used for controlling the circuits, for example. The functional circuit 40 may include a circuit used for correcting image data, like a CPU and an accelerator such as a GPU. The functional circuit 40 may include an LVDS (Low Voltage Differential Signaling) circuit, an MIPI (Mobile Industry Processor Interface) circuit, and a D/A (Digital to Analog) converter circuit, for example, having a function of an interface for receiving image data or the like from the outside of the display apparatus 90A. The functional circuit 40 may include a circuit for compressing and decompressing image data and a power supply circuit, for example.

A layer 83 is provided over the layer 62. The layer 83 includes a pixel circuit group 55 including the plurality of pixel circuits 51. An OS transistor may be provided in the layer 83. Each of the pixel circuits 51 may include an OS transistor. Note that the layer 83 can be stacked over the layer 62.

A Si transistor may be provided in the layer 83. For example, the pixel circuits 51 may each include a transistor containing single crystal silicon or polycrystalline silicon in its channel formation region. As the polycrystalline silicon, LTPS may be used. For example, the layer 83 can be formed over another substrate and bonded to the layer 62.

As another example, the pixel circuits 51 may each include a plurality of kinds of transistors using different semiconductor materials. In the case where the pixel circuits 51 each include a plurality of kinds of transistors using different semiconductor materials, the transistors may be provided in different layers depending on the kinds of transistors. For example, in the case where the pixel circuits 51 each include a Si transistor and an OS transistor, the Si transistor and the OS transistor may be provided to overlap with each other. Providing the transistors to overlap with each other reduces the area occupied by the pixel circuits 51. Thus, the definition of the display apparatus 90A can be improved. Note that a structure in which an LTPS transistor and an OS transistor are combined is referred to as LTPO in some cases.

It is preferable to use, as the transistor 52 that is an OS transistor, a transistor including an oxide containing at least one of indium, an element M (the element M is aluminum, gallium, yttrium, or tin), and zinc in a channel formation region 54. Such an OS transistor has a characteristic of an extremely low off-state current. Thus, it is particularly preferable to use the OS transistor as a transistor provided in the pixel circuit, in which case analog data written to the pixel circuit can be retained for a long period.

A layer 81 is provided over the layer 83. Over the layer 81, the substrate 92 is provided. The substrate 92 is preferably a light-transmitting substrate or a layer formed of a light-transmitting material. The layer 81 includes the plurality of light-emitting devices 61. The layer 81 can be stacked over the layer 83. As the light-emitting device 61, an organic electroluminescent element (also referred to as an organic EL element) or the like can be used, for example. However, the light-emitting device 61 is not limited thereto, and an inorganic EL element formed of an inorganic material may be used, for example. Note that an “organic EL element” and an “inorganic EL element” are collectively referred to as “EL element” in some cases. The light-emitting device 61 may contain an inorganic compound such as quantum dots. For example, when used for a light-emitting layer, the quantum dots can function as a light-emitting material.

As illustrated in FIG. 38B, the display apparatus 90A of one embodiment of the present invention can have a structure in which the light-emitting devices 61, the pixel circuits 51, the driver circuit 65, and the functional circuit 40 are stacked; thus, the aperture ratio (effective display area ratio) of the pixels can be extremely high. For example, the pixel aperture ratio can be higher than or equal to 40% and lower than 100%, preferably higher than or equal to 50% and lower than or equal to 95%, further preferably higher than or equal to 60% and lower than or equal to 95%. Furthermore, the pixel circuits 51 can be arranged extremely densely, and thus the pixels can be arranged with an extremely high definition. For example, the pixels can be arranged in the display portion 93 of the display apparatus 90A (a region where the pixel circuits 51 and the light-emitting devices 61 are stacked) with a definition higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

The display apparatus 90A described above has an extremely high definition, and thus can be suitably used for a device for VR such as a head-mounted display or a glasses-type device for AR. For example, even in the case of a structure in which the display portion of the display apparatus 90A is seen through an optical member such as a lens, pixels of the extremely-high-definition display portion included in the display apparatus 90A are not seen when the display portion is magnified by the lens, so that display providing a high sense of immersion can be performed.

Note that in the case where the display apparatus 90A is used as a wearable display apparatus for VR or AR, the display portion 93 can have a diagonal size greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the display portion 93 may have a diagonal size of 1.5 inches or approximately 1.5 inches. When the display portion 93 has a diagonal size less than or equal to 2.0 inches, the number of times of light-exposure treatment using a light-exposure apparatus (typically, a scanner apparatus) can be one; thus, the productivity of a manufacturing process can be improved.

The display apparatus 90A according to one embodiment of the present invention can be used for an electronic device other than a wearable electronic device. In that case, the display portion 93 can have a diagonal size greater than 2.0 inches. The structure of transistors used in the pixel circuits 51 may be selected as appropriate depending on the diagonal size of the display portion 93. In the case where single-crystal Si transistors are used in the pixel circuits 51, for example, the diagonal size of the display portion 93 is preferably greater than or equal to 0.1 inches and less than or equal to 3 inches. In the case where LTPS transistors are used in the pixel circuits 51, the diagonal size of the display portion 93 is preferably greater than or equal to 0.1 inches and less than or equal to 30 inches, further preferably greater than or equal to 1 inch and less than or equal to 30 inches. In the case where an LTPO (a combination of LTPS transistors and OS transistors) structure is used in the pixel circuits 51, the diagonal size of the display portion 93 is preferably greater than or equal to 0.1 inches and less than or equal to 50 inches, further preferably greater than or equal to 1 inch and less than or equal to 50 inches. In the case where OS transistors are used in the pixel circuits 51, the diagonal size of the display portion 93 is preferably greater than or equal to 0.1 inches and less than or equal to 200 inches, further preferably greater than or equal to 50 inches and less than or equal to 100 inches.

An increase in size of a display apparatus using single-crystal Si transistors in the pixel circuit 51 or the like is extremely difficult due to the size of a single crystal silicon substrate is difficult. Furthermore, the display apparatus where LTPS transistors are used in the pixel circuit 51 or the like is unlikely to respond to an increase in size (typically to a screen diagonal size greater than 30 inches) since a laser crystallization apparatus is used in the manufacturing process. By contrast, since the manufacturing process does not necessarily require a laser crystallization apparatus or the like or can be performed at a relatively low process temperature (typically, lower than or equal to 450° C.), OS transistors can be used for a display apparatus with a relatively large area (typically, a diagonal size greater than or equal to 50 inches and less than or equal to 100 inches). In addition, LTPO can be applied to a diagonal size of a display portion between the case of using LTPS transistors and the case of using OS transistors (typically, greater than or equal to 1 inch and less than or equal to 50 inches).

Specific structure examples of the driver circuit 65 and the functional circuit 40 will be described with reference to FIG. 39. FIG. 39 is a block diagram of the structure of the display apparatus 90A, illustrating a plurality of wirings connecting the pixel circuits 51, the driver circuit 65, and the functional circuit 40, a bus wiring, and the like in the display apparatus 90A.

In the display apparatus 90A illustrated in FIG. 39, the plurality of pixel circuits 51 are arranged in a matrix in the layer 83.

Furthermore, the driver circuit 65, the functional circuit 40, and the input/output circuit 80 are provided in the layer 62 in the display apparatus 90A illustrated in FIG. 39. The driver circuit 65 includes, for example, a source driver circuit 66, a digital-analog converter (DAC) circuit 32, a gate driver circuit 33, and a level shifter 34, an amplifier circuit 35, an inspection circuit 36, a video generation circuit 37, and a video distribution circuit 38. The functional circuit 40 includes, for example, a memory device 41, a GPU 42, an EL correction circuit 43, a timing controller 44, a CPU 45, a sensor controller 46, a power supply circuit 47, a temperature sensor 48, and a luminance correction circuit 49. The functional circuit 40 has a function of an application processor. Note that a GPU performing calculation of artificial intelligence is referred to an AI accelerator in some cases.

The input/output circuit 80 is compatible with a transmission method such as LVDS (Low Voltage Differential Signaling), and the input/output circuit 80 has a function of distributing control signals, image data, and the like input via the terminal portion 94 to the driver circuit 65 and the functional circuit 40. Furthermore, the input/output circuit 80 has a function of outputting information of the display apparatus 90A to the outside via the terminal portion 94.

In the display apparatus 90A in FIG. 39, an example of a structure in which the circuits included in the driver circuit 65, the circuits included in the functional circuit 40, and the input/output circuit 80 are each electrically connected to a bus wiring BSL is illustrated. The source driver circuit 66 has a function of transmitting image data to the pixel circuits 51 included in the pixels 230, for example. Thus, the source driver circuit 66 is electrically connected to the pixel circuits 51 through a wiring SL. Note that a plurality of source driver circuits 66 may be provided.

The digital-analog converter circuit 67 has a function of converting image data that has been digitally processed by a GPU, a correction circuit, or the like, into analog data, for example. The image data converted into analog data is amplified by the amplifier circuit 35 such as an operational amplifier and is transmitted to the pixel circuits 51 via the source driver circuit 66. Note that the image data may be transmitted to the source driver circuit 66, the digital-analog converter circuit 67, and the pixel circuits 51 in this order. The digital-analog converter circuit 67 and the amplifier circuit 35 may be included in the source driver circuit 66.

The gate driver circuit 33 has a function of selecting a pixel circuit to which image data is to be transmitted among the pixel circuits 51, for example. Thus, the gate driver circuit 33 is electrically connected to the pixel circuits 51 through a wiring GL. Note that a plurality of gate driver circuits 33 may be provided such that the number of the gate driver circuits 33 corresponds to the number of the source driver circuits 66.

The level shifter 34 has a function of converting signals to be input to the source driver circuit 66, the digital-analog converter circuit 67, the gate driver circuit 33, and the like into appropriate levels, for example.

The memory device 41 has a function of storing image data to be displayed by the pixel circuits 51, for example. Note that the memory device 41 can be configured to store the image data as digital data or analog data.

In the case where the memory device 41 stores image data, the memory device 41 is preferably a nonvolatile memory. In that case, a NAND memory or the like can be used as the memory device 41, for example.

In the case where the memory device 41 stores temporary data generated in the GPU 42, the EL correction circuit 43, the CPU 45, or the like, the memory device 41 is preferably a volatile memory. In that case, an SRAM (Static Random Access Memory), a DRAM (Dynamic Random Access Memory), or the like can be used as the memory device 41, for example.

The GPU 42 has a function of performing processing for outputting, to the pixel circuits 51, image data read from the memory device 41, for example. Specifically, the GPU 42 is configured to perform pipeline processing in parallel and thus can perform high-speed processing of image data to be output to the pixel circuits 51. The GPU 42 can also have a function of a decoder for decoding an encoded image.

The functional circuit 40 may include a plurality of circuits that can improve the display quality of the display apparatus 90A. As such circuits, for example, correction (toning and dimming) circuits that detect color irregularity of a displayed image and correct the color irregularity to obtain an optimal image may be provided. In the case where a light-emitting device utilizing organic EL is used as the display element, for example, an EL correction circuit that corrects image data in accordance with characteristics of the light-emitting device may be provided in the functional circuit 40. The functional circuit 40 includes the EL correction circuit 43 as an example.

The above-described image correction may be performed using artificial intelligence. For example, a current flowing in a pixel circuit (or a voltage applied to the pixel circuit) may be monitored and obtained, a displayed image may be obtained with an image sensor or the like, the current (or voltage) and the image may be used as input data in an arithmetic operation of the artificial intelligence (e.g., an artificial neural network), and the output result may be used to judge whether the image should be corrected.

Such an arithmetic operation of artificial intelligence can be applied to not only image correction but also upconversion for increasing the resolution of image data. As an example, FIG. 39 illustrates the GPU 42 that includes blocks for performing arithmetic operations for various kinds of correction (e.g., color irregularity correction 42a and upconversion 42b).

The upconversion processing of image data can be performed with an algorithm selected from a Nearest neighbor method, a Bilinear method, a Bicubic method, a RAISR (Rapid and Accurate Image Super-Resolution) method, an ANR (Anchored Neighborhood Regression) method, an A+ method, an SRCNN (Super-Resolution Convolutional Neural Network) method, and the like.

The algorithm used for the upconversion processing may be different for each region determined in accordance with a gaze point. For example, upconversion processing for a region including the gaze point and the vicinity of the gaze point is performed using an algorithm with a low processing speed but high accuracy, and upconversion processing for a region other than the region is performed using an algorithm with low accuracy but a high processing speed. In that case, the time required for upconversion processing can be shortened. In addition, power consumption required for upconversion processing can be reduced.

Without limitation to upconversion processing, downconversion processing for decreasing the resolution of image data may be performed. In the case where the resolution of image data is higher than the resolution of the display portion 93, part of the image data is not displayed on the display portion 93 in some cases. In that case, downconversion processing enables the entire image data to be displayed on the display portion 93.

The timing controller 44 has a function of controlling driving frequency (e.g., frame frequency, frame rate, or refresh rate) for displaying an image, for example. In the case where a still image is displayed on the display apparatus 90A, for example, the driving frequency is lowered by the timing controller 44, so that power consumption of the display apparatus 90A can be reduced.

The CPU 45 has a function of performing general-purpose processing such as execution of an operating system, control of data, and execution of various kinds of arithmetic operations and programs, for example. The CPU 45 has a role in, for example, giving an instruction for a writing operation or a reading operation of image data in the memory device 41, an operation for correcting image data, an operation of a later-described sensor, or the like. Furthermore, the CPU 45 may have a function of transmitting a control signal to at least one of the circuits included in the functional circuit 40, for example.

The sensor controller 46 has a function of controlling a sensor, for example. FIG. 39 illustrates a wiring SNCL as a wiring for electrical connection to the sensor.

The sensor can be, for example, a touch sensor that can be provided in the display portion. Alternatively, the sensor can be an illuminance sensor, for example.

The power supply circuit 47 has a function of generating voltages to be supplied to circuits included in the pixel circuits 51, the driver circuit 65, and the functional circuit 40, for example. Note that the power supply circuit 47 may have a function of selecting a circuit to which a voltage is to be supplied. The power supply circuit 47 can stop supply of a voltage to the CPU 45, the GPU 42, and the like during a period in which a still image is displayed, so that the power consumption of the whole display apparatus 90A is reduced, for example.

As described above, the display apparatus of one embodiment of the present invention can have a structure in which display elements, pixel circuits, a driver circuit, and the functional circuit 40 are stacked. The driver circuit and the functional circuit, which are peripheral circuits, can be provided so as to overlap with the pixel circuits and thus the width of the bezel can be made extremely small, so that the display apparatus can be downsized. The display apparatus of one embodiment of the present invention has a structure in which circuits are stacked and thus wirings connecting the circuits can be shortened, resulting in a reduction in weight of the display apparatus. The display apparatus of one embodiment of the present invention can include a display portion of pixels with an increased definition; thus, the display apparatus can have high display quality.

### Structure Example of Display Module

Next, a structure example of a display module including the display apparatus 90A will be described.

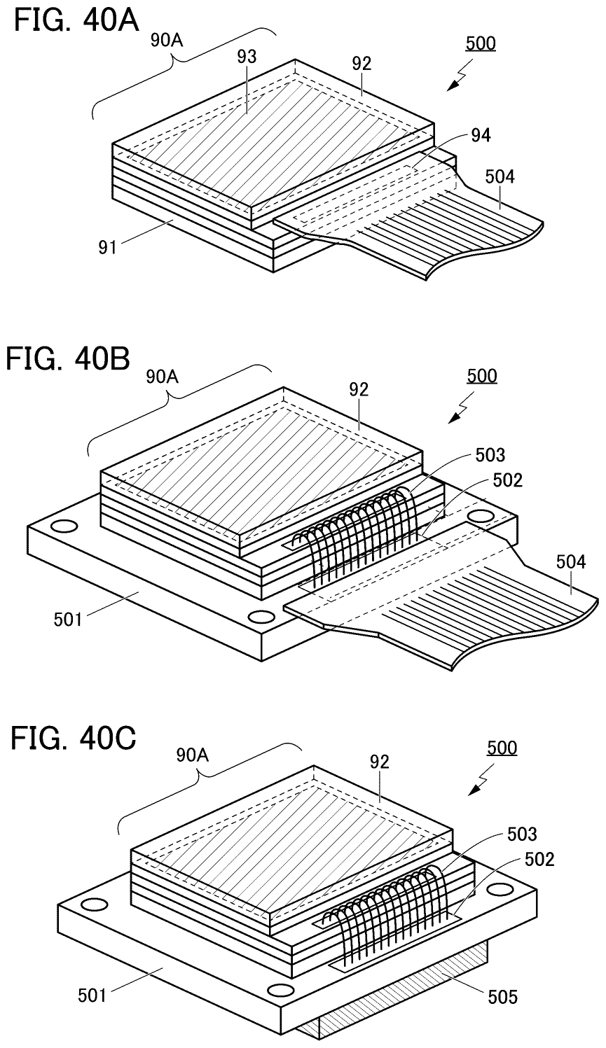

FIG. 40A to FIG. 40C are each a perspective view of a display module 500. The display module 500 has a structure in which an FPC (Flexible printed circuit) 504 is provided on the terminal portion 94 of the display apparatus 90A. The FPC 504 has a structure in which a film formed of an insulator is provided with a wiring. The FPC 504 is flexible. The FPC 504 functions as a wiring for supplying a video signal, a control signal, a power supply potential, and the like to the display apparatus 90A from the outside. An IC may be mounted on the FPC 504.

The display module 500 illustrated in FIG. 40B includes the display apparatus 90A over a printed wiring board 501. The printed wiring board 501 includes wirings inside a substrate formed of an insulator and/or on the surface of the substrate.

In the display module 500 illustrated in FIG. 40B, the terminal portion 94 of the display apparatus 90A is electrically connected to a terminal portion 502 of the printed wiring board 501 through a wire 503. The wire 503 can be formed in wire bonding. Ball bonding or wedge bonding can be used as the wire bonding.

After the wire 503 is formed, the wire 503 may be covered with a resin material or the like. Note that the display apparatus 90A and the printed wiring board 501 may be electrically connected to each other by a method other than the wire bonding. For example, the display apparatus 90A and the printed wiring board 501 may be electrically connected to each other using an anisotropic conductive adhesive, a bump, or the like.

In the display module 500 illustrated in FIG. 40B, the terminal portion 502 of the printed wiring board 501 is electrically connected to the FPC 504. In the case where the electrode pitch in the terminal portion 94 of the display apparatus 90A is different from the electrode pitch in the FPC 504, for example, the terminal portion 94 may be electrically connected to the FPC 504 via the printed wiring board 501. Specifically, the interval (pitch) between a plurality of electrodes in the terminal portion 94 can be changed into the interval between a plurality of electrodes in the terminal portion 502 using wirings formed on the printed wiring board 501. Accordingly, even when the electrode pitch in the terminal portion 94 is different from the electrode pitch in the FPC 504, electrical connection between the electrodes can be made.

The printed wiring board 501 can be provided with a variety of elements such as a resistor, a capacitor element, and a semiconductor element.

As in the display module 500 illustrated in FIG. 40C, the terminal portion 502 may be electrically connected to a connection portion 505 provided on a bottom surface (a surface where the display apparatus 90A is not provided) of the printed wiring board 501. With the use of a socket-type connection portion as the connection portion 505, for example, the display module 500 can be easily attached to and detached from another device.

### Structure Example of Pixel Circuit

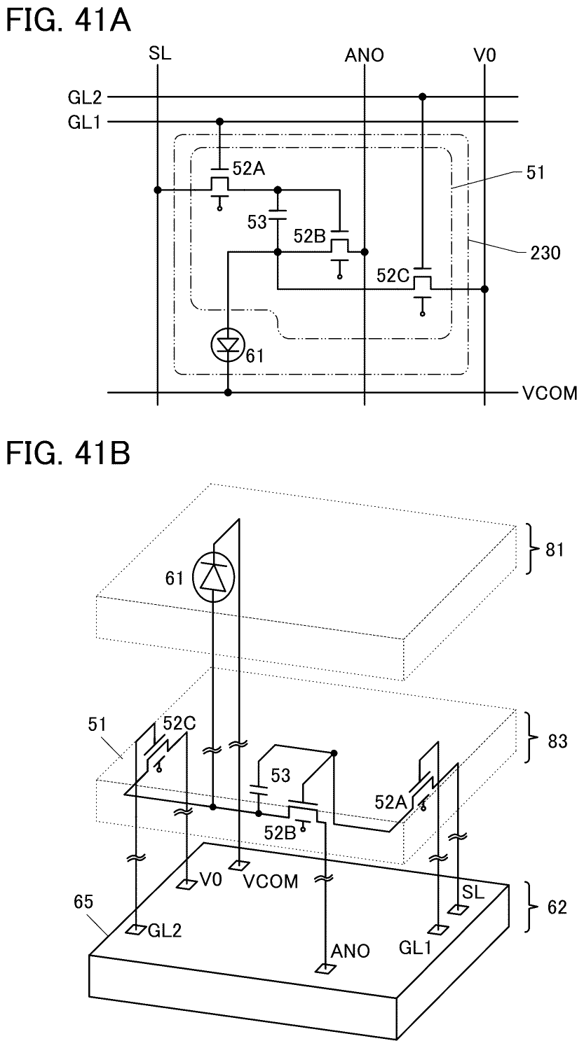

FIG. 41A and FIG. 41B illustrate a structure example of the pixel circuit 51 and the light-emitting device 61 connected to the pixel circuit 51. FIG. 41A schematically illustrates connection of the elements, and FIG. 41B schematically illustrates the vertical position relation of the layer 62 including the driver circuit, the layer 83 including a plurality of transistors in the pixel circuit, and the layer 81 including a light-emitting device.

The pixel circuit 51 illustrated as an example in FIG. 41A and FIG. 41B includes a transistor 52A, a transistor 52B, a transistor 52C, and a capacitor 53. The transistor 52A, the transistor 52B, and the transistor 52C can be OS transistors. Each of the OS transistors of the transistor 52A, the transistor 52B, and the transistor 52C preferably includes a back gate electrode, in which case the structure in which the back gate electrode is supplied with the same signals as those supplied to the gate electrode or the structure in which the back gate electrode is supplied with signals different from those supplied to the gate electrode can be used.

The transistor 52B includes the gate electrode electrically connected to the transistor 52A, a first electrode electrically connected to the light-emitting device 61, and a second electrode electrically connected to a wiring ANO. The wiring ANO is a wiring for supplying a potential for supplying a current to the light-emitting device 61.

The transistor 52A includes a first terminal electrically connected to the gate electrode of the transistor 52B, a second terminal electrically connected to the wiring SL which functions as a source line, and the gate electrode having a function of controlling the conduction state or non-conduction state on the basis of the potential of a wiring GL1 which functions as a gate line.

The transistor 52C includes a first terminal electrically connected to the wiring V0, a second terminal electrically connected to the light-emitting device 61, and the gate electrode having a function of controlling the conduction state or non-conduction state on the basis of the potential of a wiring GL2 which functions as a gate line. The wiring V0 is a wiring for supplying a reference potential and a wiring for outputting a current flowing through the pixel circuit 51 to the driver circuit 65 or the functional circuit 40.

The capacitor 53 includes a conductive film electrically connected to the gate electrode of the transistor 52B and a conductive film electrically connected to the second electrode of the transistor 52C.

The light-emitting device 61 includes a first electrode electrically connected to the first electrode of the transistor 52B and a second electrode electrically connected to the wiring VCOM. The wiring VCOM is a wiring for supplying a potential for supplying a current to the light-emitting device 61.

Accordingly, the intensity of light emitted from the light-emitting device 61 can be controlled in accordance with an image signal supplied to the gate electrode of the transistor 52B. Furthermore, variations in voltage between the gate and the source of the transistor 52B can be reduced by the reference potential of the wiring V0 supplied through the transistor 52C.

A current value that can be used for setting of a pixel parameter can be output from the wiring V0. Specifically, the wiring V0 can function as a monitor line for outputting a current flowing through the transistor 52B or a current flowing through the light-emitting device 61 to the outside. A current output to the wiring V0 is converted into a voltage by a source follower circuit or the like and output to the outside. Alternatively, the current output to the wiring V0 can be converted into a digital signal by an A-D converter or the like and output to the functional circuit 40 or the like.

Note that the light-emitting device described in one embodiment of the present invention refers to a self-luminous display element such as an organic EL element (also referred to as an OLED (Organic Light Emitting Diode)). Note that the light-emitting device electrically connected to the pixel circuit can be a self-luminous light-emitting device such as an LED (Light Emitting Diode), a micro LED, a QLED (Quantum-dot Light Emitting Diode), or a semiconductor laser.

Note that in the structure illustrated as an example in FIG. 41B, the wirings electrically connecting the pixel circuit 51 and the driver circuit 65 can be shortened, so that wiring resistance of the wirings can be reduced. Thus, data can be written at high speed, which enables high-speed driving of the display apparatus 90A. Therefore, even when the number of the pixel circuits 51 included in the display apparatus 90A is increased, a sufficient frame period can be ensured, and thus, the pixel density of the display apparatus 90A can be increased. In addition, the increased pixel density of the display apparatus 90A can increase the definition of an image displayed by the display apparatus 90A. For example, the pixel density of the display apparatus 90A can be higher than or equal to 1000 ppi, higher than or equal to 5000 ppi, or higher than or equal to 7000 ppi. Thus, the display apparatus 90A can be, for example, a display apparatus for AR or VR and can be suitably used in an electronic device with a short distance between a display portion and the user, such as an HMD.

Although FIG. 41A and FIG. 41B illustrate, as an example, the pixel circuit 51 including three transistors in total, one embodiment of the present invention is not limited to the example. Structure examples and a driving method example of a pixel circuit which can be used for the pixel circuit 51 will be described below.

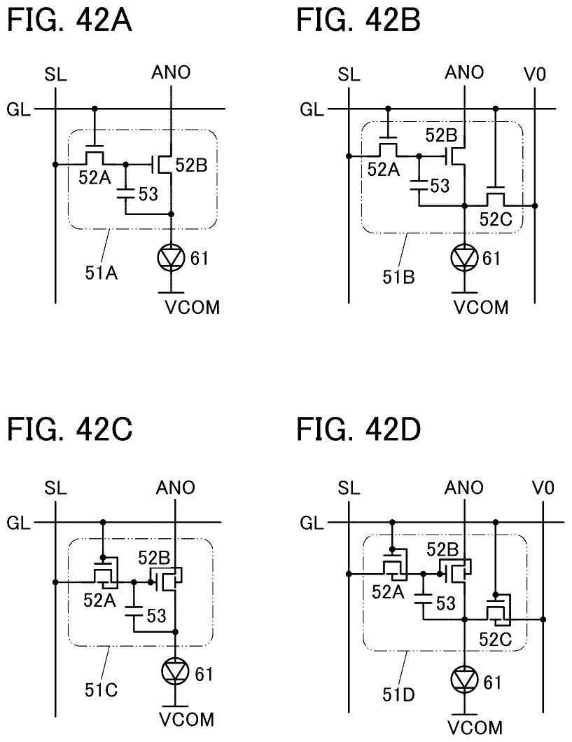

The pixel circuit 51A illustrated in FIG. 42A includes the transistor 52A, the transistor 52B, and the capacitor 53. FIG. 42A illustrates the light-emitting device 61 connected to the pixel circuit 51A. The wiring SL, the wiring GL, the wiring ANO, and the wiring VCOM are electrically connected to the pixel circuit 51A. The pixel circuit 51A has a structure in which the transistor 52C is removed from the pixel circuit 51 illustrated in FIG. 41A and the wiring GL1 and the wiring GL2 are replaced with the wiring GL.

The gate of the transistor 52A is electrically connected to the wiring GL, one of the source and the drain of the transistor 52A is electrically connected to the wiring SL, and the other of the source and the drain of the transistor 52A is electrically connected to the gate of the transistor 52B and one electrode of a capacitor 53. One of the source and the drain of the transistor 52B is electrically connected to the wiring ANO and the other of the source and the drain of the transistor 52B is electrically connected to the anode of the light-emitting device 61. The other electrode of the capacitor 53 is electrically connected to the anode of the light-emitting device 61. The cathode of the light-emitting device 61 is electrically connected to the wiring VCOM.

A pixel circuit 51B illustrated in FIG. 42B has a structure in which the transistor 52C is added to the pixel circuit 51A. In addition, the wiring V0 is electrically connected to the pixel circuit 51B.

A pixel circuit 51C illustrated in FIG. 42C is an example of the case where a transistor in which a pair of gates are electrically connected to each other is used as each of the transistor 52A and the transistor 52B of the pixel circuit 51A. A pixel circuit 51D illustrated in FIG. 42D is an example of the case where such transistors are used in the pixel circuit 51B. Thus, the current that can flow through the transistor can be increased. Note that although the transistor in which a pair of gates are electrically connected to each other is used for each of the transistors here, one embodiment of the present invention is not limited thereto. A transistor that includes a pair of gates electrically connected to different wirings may be used. When, for example, a transistor in which one of gates is electrically connected to a source is used, the reliability can be increased.

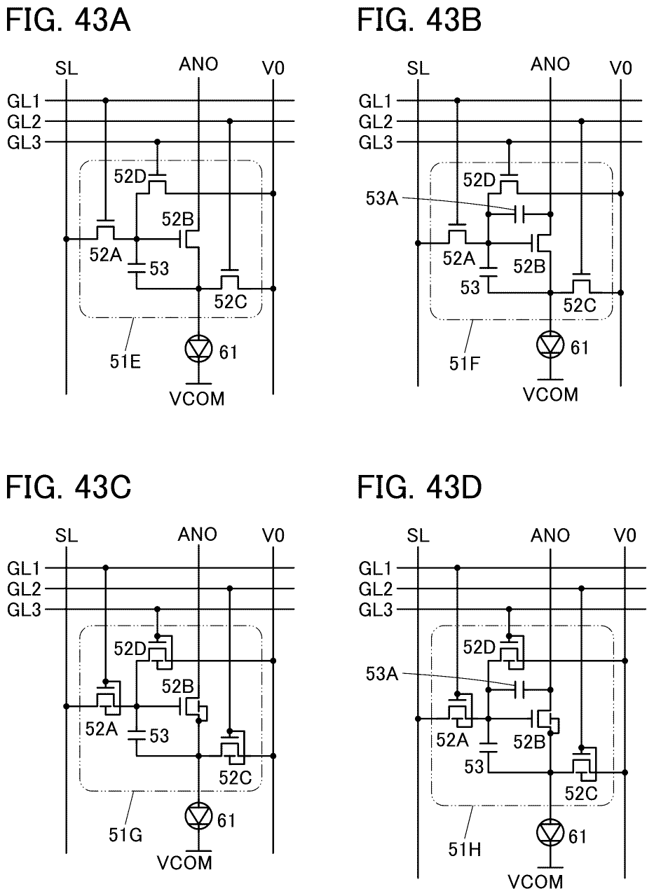

A pixel circuit 51E illustrated in FIG. 43A has a structure in which a transistor 52D is added to the pixel circuit 51B. The wiring GL1, the wiring GL2, and a wiring GL3 functioning as gate lines are electrically connected to the pixel circuit 51E. Note that in this embodiment and the like, the wiring GL1, the wiring GL2, and the wiring GL3 are collectively referred to as the wiring GL in some cases. Thus, the wiring GL is not limited to one wiring and includes a plurality of wirings in some cases.

A gate of the transistor 52D is electrically connected to the wiring GL3, one of a source and a drain of the transistor 52D is electrically connected to the gate of the transistor 52B, and the other of the source and the drain of the transistor 52D is electrically connected to the wiring V0. The gate of the transistor 52A is electrically connected to the wiring GL1, and the gate of the transistor 52C is electrically connected to the wiring GL2.

When the transistor 52C and the transistor 52D are turned on at the same time, the source and the gate of the transistor 52B have the same potential, so that the transistor 52B can be turned off. Thus, a current flowing to the light-emitting device 61 can be blocked forcibly. Such a pixel circuit is suitable for the case of using a display method in which a display period and a non-lighting period are alternately provided.

A pixel circuit 51F illustrated in FIG. 43B is an example of the case where a capacitor 53A is added to the pixel circuit 51E. The capacitor 53A functions as a storage capacitor.

A pixel circuit 51G illustrated in FIG. 43C and a pixel circuit 51H illustrated in FIG. 43D are respectively examples of the cases where transistors each including a pair of gates are used in the pixel circuit 51E and the pixel circuit 51F. A transistor in which a pair of gates are electrically connected to each other is used as each of the transistor 52A, the transistor 52C, and the transistor 52D, and a transistor in which one of gates is electrically connected to a source is used as the transistor 52B.

### Modification Example 1

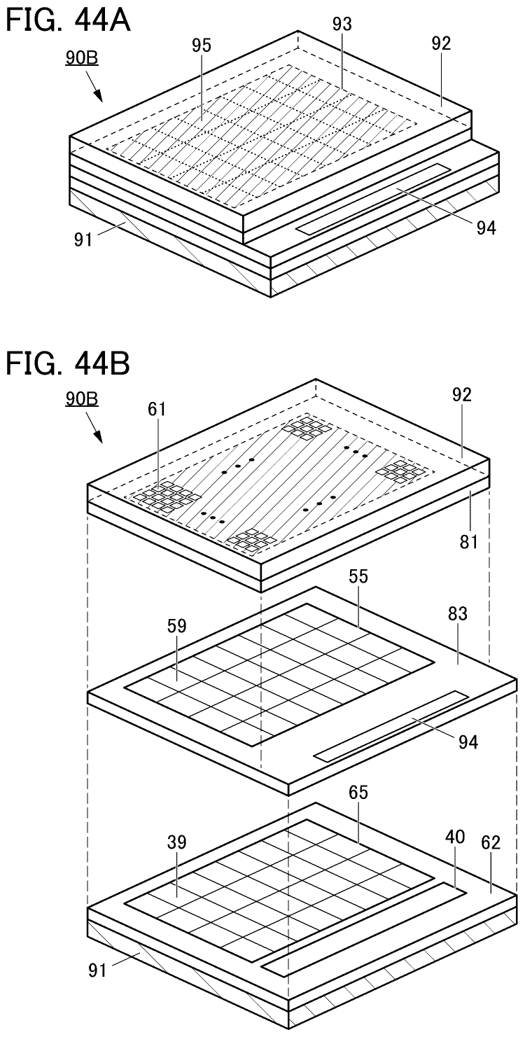

FIG. 44A and FIG. 44B are perspective views of the display apparatus 90B, which is a modification example of the display apparatus 90A. FIG. 44B is a perspective view for illustrating structures of layers included in the display apparatus 90B. Description is made mainly on portions different from those of the display apparatus 90A to reduce repeated description.

In the display apparatus 90B, the driver circuit 65 and the pixel circuit group 55 including the plurality of pixel circuits 51 overlap with each other. In the display apparatus 90B, the pixel circuit group 55 is divided into the plurality of sections 59 and the driver circuit 65 is divided into a plurality of sections 39. The plurality of sections 39 each include the source driver circuit 66 and the gate driver circuit 33.

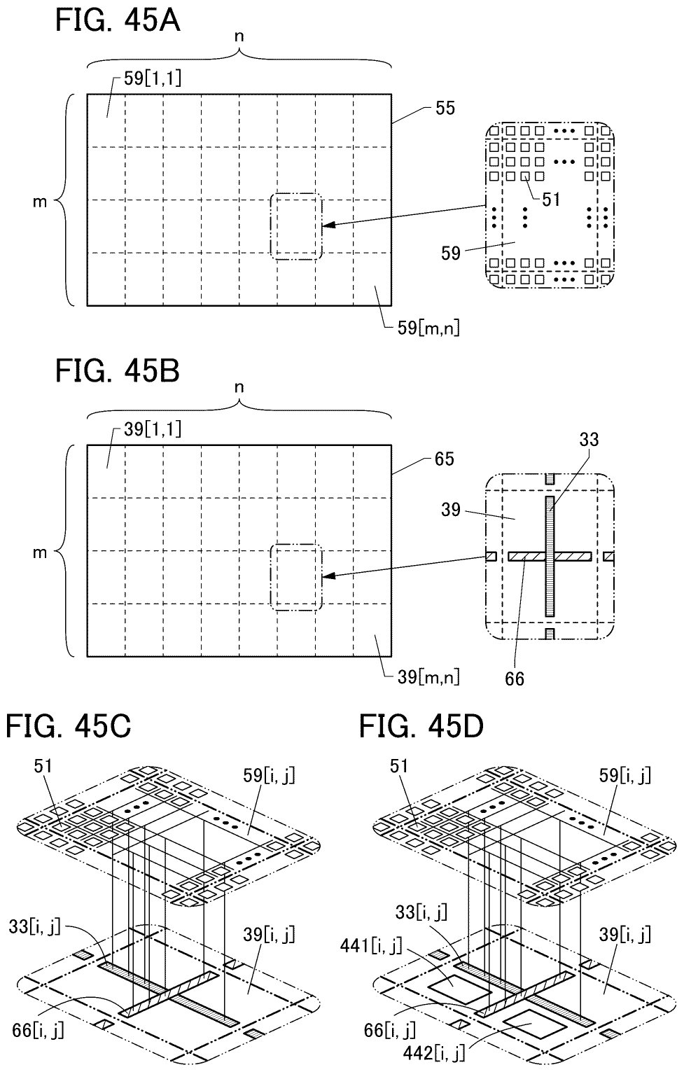

FIG. 45A illustrates a structure example of the pixel circuit group 55 included in the display apparatus 90B. FIG. 45B illustrates a structure example of the driver circuit 65 included in the display apparatus 90B. The sections 59 and the sections 39 are each arranged in a matrix of m rows and n columns (m and n are each an integer greater than or equal to 1). In this specification and the like, the section 59 in the first row and the first column is denoted by a section 59 [1,1], and the section 59 in the m-th row and the n-th column is denoted by a section 59 [m,n]. Similarly, the section 39 in the first row and the first column is denoted by a section 39 [1,1], and the section 39 in the m-th row and the n-th column is denoted by a section 39 [m,n]. FIG. 45A and FIG. 45B illustrate a case where m is 4 and n is 8. That is, the pixel circuit group 55 and the driver circuit 65 are each divided into 32 sections.

The plurality of sections 59 each include the plurality of pixel circuits 51, a plurality of wirings SL, and a plurality of wirings GL. In each of the plurality of sections 59, one of the plurality of pixel circuits 51 is electrically connected to at least one of the plurality of wirings SL and at least one of the plurality of wirings GL.

One of the sections 59 and one of the sections 39 are provided to overlap with each other (see FIG. 45C). For example, a section 59 [i,j] (i is an integer greater than or equal to 1 and less than or equal to m, and j is an integer greater than or equal to 1 and less than or equal to n) and a section 39 [i,j] are provided to overlap with each other. A source driver circuit 66 [i,j] included in the section 39 [i,j] is electrically connected to the wiring SL included in the section 59 [i,j]. A gate driver circuit 33 [i,j] included in the section 39 [i,j] is electrically connected to the wiring GL included in the section 59 [i,j]. The source driver circuit 66 [i,j] and the gate driver circuit 33 [i,j] have a function of controlling the plurality of pixel circuits 51 included in the section 59 [i,j].

When the section 59 [i,j] and the section 39 [i,j] are provided to overlap with each other, a connection distance (wiring length) between the pixel circuit 51 included in the section 59 [i,j] and each of the source driver circuit 66 and the gate driver circuit 33 included in the section 39 [i,j] can be made extremely short. As a result, the wiring resistance and the parasitic capacitance are reduced, and thus time taken for charging and discharging can be reduced and high-speed driving can be achieved. Moreover, power consumption can be reduced. Furthermore, the size and weight of the display apparatus can be reduced.

In addition, the display apparatus 90B includes the source driver circuit 66 and the gate driver circuit 33 in each of the sections 39. Thus, the display portion 93 can be divided into the sections 59 corresponding to the sections 39, and image rewriting can be performed. For example, in the display portion 93, image rewriting can be performed only in a section where an image has been changed and image data can be retained in a section with no change, so that power consumption can be reduced.

In this embodiment and the like, one of the sections of the display portion 93 that are divided so as to correspond to the sections 59 is referred to as a sub-display portion 95. Thus, the sub-display portion 95 is also one of the display portion 93 divided into the sections 39. The display portion 93 includes a plurality of sub-display portions 95. The display portion 93 can also be regarded as being formed of a plurality of sub-display portions 95. In the display apparatus 90B described with reference to FIG. 44 and FIG. 45, the display portion 93 is divided into 32 sub-display portions 95 (see FIG. 44A). Each of the sub-display portions 95 includes the plurality of pixels 230 illustrated in FIG. 41 and the like. Specifically, each one of the sub-display portions 95 includes the plurality of light-emitting devices 61 and one of the sections 59 including the plurality of pixel circuits 51. Each one of the sections 39 has a function of controlling the plurality of pixels 230 included in one sub-display portion 95.

In the display apparatus 90B, driving frequency at the time of displaying an image can be set freely for each of the sub-display portions 95 by the timing controller 44 included in the functional circuit 40. The functional circuit 40 has a function of controlling operations in the plurality of sections 39 and the plurality of sections 59. In other words, the functional circuit 40 has a function of controlling driving frequency and operation timing of each of the plurality of sub-display portions 95 arranged in a matrix. In addition, the functional circuit 40 has a function of adjusting synchronization between the sub-display portions.

A timing controller 441 and an input/output circuit 442 may be provided in each of the sections 39 (see FIG. 45D). For the input/output circuit 442, an I2C (Inter-Integrated Circuit) interface can be used, for example. The timing controller 441 included in the section 39 [i,j] is denoted as a timing controller 441 [i,j] in FIG. 45C and FIG. 45D. Furthermore, the input/output circuit 442 included the section 39 [i,j] is denoted as an input/output circuit 442 [i,j].

The functional circuit 40 supplies setting signals for the scan direction and driving frequency of the gate driver circuit 33 [i,j] and operation parameters, such as the number of pixels in image data reduced for decreasing a resolution (the number of pixels where image data rewriting is not performed at the time of image data rewriting), to the input/output circuit 442 [i,j], for example. The source driver circuit 66 [i,j] and the gate driver circuit 33 [i,j] operate in accordance with the operation parameters.

In the case where the sub-display portions 95 each include a light-receiving element described later, the input/output circuit 442 outputs information obtained by photoelectric conversion by the light-receiving element to the functional circuit 40.

In the display apparatus 90B in the electronic device of one embodiment of the present invention, the pixel circuit 51 and the driver circuit 65 are stacked and the driving frequency is different in each of the sub-display portions 95 in accordance with the motion of the user's gaze, whereby low power consumption can be achieved.

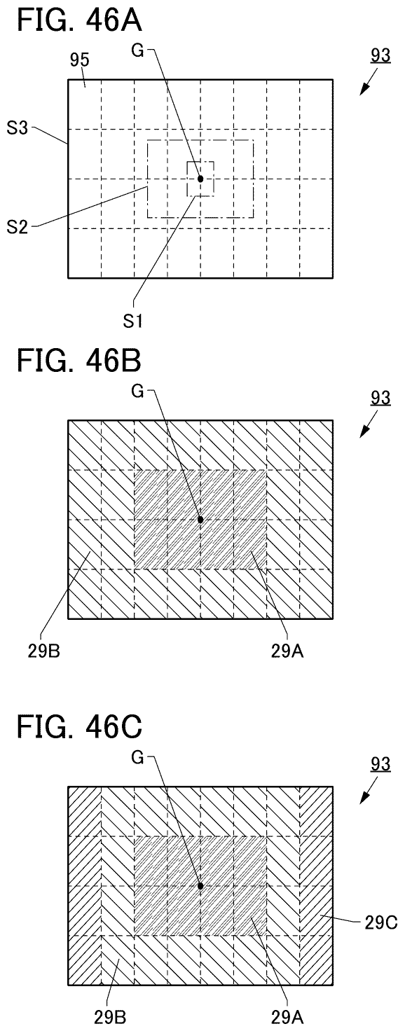

FIG. 46A illustrates the display portion 93 including the sub-display portions 95 in four rows and eight columns. FIG. 46A also illustrates the first region S1 to the third region S3 with the gaze point G as a center. The arithmetic portion 103 distributing each of the plurality of sub-display portions 95 to either a first section 29A overlapping with the first region S1 and the second region S2 or a second section 29B overlapping with the third region S3. In other words, the arithmetic portion 103 distributes each of the plurality of sections 39 to either the first section 29A or the second section 29B. In this case, the first section 29A overlapping with the first region S1 or the second region S2 includes a region overlapping with the gaze point G. Furthermore, the second section 29B includes the sub-display portions 95 positioned outside the first section 29A (see FIG. 46B).

The operations of the driver circuits (the source driver circuit 66 and the gate driver circuit 33) included in each of the plurality of sections 39 are controlled by the functional circuit 40. For example, the second section 29B is a section overlapping with the third region S3 including the above-described stable visual field, inducting visual field, and supplementary visual field, and is hard for the user to discern. Thus, a reduction in practical display quality perceived by a user (hereinafter also referred to as “practical display quality”) is small even when the number of times of image data rewriting per unit time (hereinafter also referred to as “image rewriting frequency”) at the time of displaying an image is smaller in the second section 29B than in the first section 29A. In other words, a reduction in practical display quality is small even when driving frequency of the sub-display portion 95 included in the second section 29B (also referred to as “second driving frequency”) is lower than driving frequency of the sub-display portions 95 included in the first section 29A (also referred to as “first driving frequency”).

A decrease in the driving frequency can result in a reduction in power consumption of the display apparatus. On the other hand, a decrease in the driving frequency reduces the display quality. In particular, the display quality in displaying a moving image is reduced. According to one embodiment of the present invention, the second driving frequency is made lower than the first driving frequency; thus, power consumption can be reduced in a section where the visibility by the user is low and the reduction of the practical display quality can be suppressed. According to one embodiment of the present invention, both display quality maintenance and a reduction in power consumption can be achieved.

The first driving frequency can be higher than or equal to 30 Hz and lower than or equal to 500 Hz, preferably higher than or equal to 60 Hz and lower than or equal to 500 Hz. The second driving frequency is preferably lower than or equal to the first driving frequency, further preferably lower than or equal to a half of the first driving frequency, still further preferably lower than or equal to one fifth of the first driving frequency.

A section of the sub-display portions 95 overlapping with the third region S3 that is outside the second section 29B may be set as a third section 29C (see FIG. 46C), and driving frequency of the sub-display portions 95 included in the third section 29C (also referred to as “third driving frequency”) may be made lower than the driving frequency in the second section 29B. The third driving frequency is preferably lower than or equal to the second driving frequency, further preferably lower than or equal to a half of the second driving frequency, still further preferably lower than or equal to one fifth of the second driving frequency. By significantly lowering the image rewriting frequency, power consumption can be further reduced. Note that rewriting of image data may be stopped if necessary. By stopping rewriting of image data, power consumption can be further reduced.

In the case where such a driving method is employed, a transistor with an extremely low off-state current is suitably used as a transistor included in the pixel circuit 51. For example, an OS transistor is suitably used as the transistor included in the pixel circuit 51. An OS transistor has an extremely low off-state current and thus can achieve long-term retention of image data supplied to the pixel circuit 51. It is particularly suitable to use an OS transistor as the transistor 52A.

In some cases, an image whose brightness, contrast, color tone, or the like is greatly different from that of the previous image is displayed as in the case where a video scene displayed on the display portion 93 is changed, for example. Such a case causes a mismatch of the timing at which an image is changed between the first section 29A and a section whose driving frequency is lower than that of the first section 29A. This might cause a great difference in the brightness, contrast, color tone, or the like between the sections, leading to the loss of the practical display quality. In such a case where a video scene is changed, image data rewriting can be performed in the sections other than the first section 29A at a driving frequency which is the same as that of the first section 29A once, and then the driving frequency of the sections other than the first section 29A can be decreased.

Furthermore, in the case where the fluctuation amount of the gaze point G is judged to be exceeding a certain value, image data rewriting may be performed in the sections other than the first section 29A at a driving frequency which is the same as that of the first section 29A, and in the case where the fluctuation amount is judged to be less than or equal to the certain value, the driving frequency of the sections other than the first section 29A may be decreased. In the case where the fluctuation amount of the gaze point G is judged to be small, the driving frequency of the sections other than the first section 29A may be further decreased.

In the case where the display apparatus 90B does not include a frame memory, which is a memory device for temporarily retaining image data, or includes one frame memory for the entire display portion 93, each of the second driving frequency and the third driving frequency needs to be an integral submultiple of the first driving frequency.

When the plurality of sub-display portions 95 are provided with respective frame memories, each of the second driving frequency and the third driving frequency can be set to a given value without limitation to an integral submultiple of the first driving frequency. When the second driving frequency and the third driving frequency are set to given values, the degree of freedom in setting the driving frequencies can be increased. As a result, a reduction in the practical display quality can be small.

Note that sections set for the display portion 93 are not limited to the three sections of the first section 29A, the second section 29B, and the third section 29C. The display portion 93 may include four or more sections. When a plurality of sections are set for the display portion 93 and the driving frequencies of the sections are gradually lowered, a reduction in the practical display quality can be smaller.

The above-described upconversion processing may be performed on an image to be displayed on the first section 29A. When an image obtained by the upconversion processing is displayed on the first section 29A, the display quality can be increased. The above-described upconversion processing may be performed on an image to be displayed on the sections other than the first section 29A. When an image obtained by the upconversion processing is displayed on the sections other than the first section 29A, a reduction in the practical display quality that occurs in the case where the driving frequencies of the sections other than the first section 29A are lowered can be smaller.

Note that the upconversion processing of an image to be displayed on the first section 29A may be performed using an algorithm with high accuracy, and the upconversion processing of an image to be displayed on the sections other than the first section 29A may be performed using an algorithm with low accuracy. A reduction in the practical display quality that occurs in the case where the driving frequencies of the sections other than the first section 29A are lowered can be smaller also in such a case.

In the case where the resolution of image data is higher than the resolution of the display portion 93, or in the case where high-speed rewriting and low power consumption have a priority, for example, downconversion processing may be performed on an image displayed on the sections other than the first section 29A in accordance with the purpose or the like. For example, high-speed rewriting and low power consumption can be achieved by rewriting an image displayed on the sections other than the first section 29A every several rows, every several columns, or every several pixels.

The resolutions of images displayed on the sections other than the first section 29A including a gaze point are lower than the resolution of an image displayed on the first section 29A, enabling a reduction in the load at the time of generation of a video signal (rendering). The processing is also referred to as foveated rendering. With a combination of the reduction of a driving frequency of the sections other than the first section 29A and the foveated rendering, much lower power consumption can be achieved while a decrease in display quality is suppressed.

When image data rewriting performed in each of the sub-display portions 95 is performed concurrently in all of the sub-display portions 95, high-speed rewriting can be achieved. In other words, when image data rewriting performed in each of the sections 39 is performed concurrently in all of the sections 39, high-speed rewriting can be achieved.

In general, while pixels in one row are selected by a gate driver circuit, a source driver circuit writes image data to all of the pixels in one row concurrently in the case of line sequential driving. In the case where the display portion 93 is not divided into the sub-display portions 95 and has a resolution of 4000×2000 pixels, for example, image data needs to be written to 4000 pixels by the source driver circuit while the pixels in one row are selected by the gate driver circuit. In the case where the frame frequency is 120 Hz, one frame period is approximately 8.3 msec. Accordingly, the gate driver circuit needs to select pixels in 2000 rows in approximately 8.3 msec, and the time for selecting a gate line of one row, that is, the time for writing image data to each pixel is approximately 4.17 usec. In other words, it becomes more difficult to ensure sufficient time for rewriting image data as the resolution of the display portion increases or as the frame frequency increases.

The display portion 93 of the display apparatus 90B described as an example in this embodiment is divided into four sections in the row direction. Thus, the time for writing image data to each pixel in one sub-display portion 95 can be four times as long as that of the case where the display portion 93 is not divided. According to one embodiment of the present invention, the time for rewriting image data can be easily ensured even in the case where the frame frequency is 240 Hz or 360 Hz; thus, a display apparatus with high display quality can be provided.

Since the display portion 93 of the display apparatus 90B described as an example in this embodiment is divided into four sections in the row direction, the length of the wiring SL electrically connecting the source driver circuit and the pixel circuit becomes one fourth. Accordingly, each of the resistance value and parasitic capacitance of the wiring SL becomes one fourth, whereby the time required for writing (rewriting) image data can be shortened.

In addition, the display portion 93 of the display apparatus 90B described as an example in this embodiment is divided into eight sections in the column direction; thus, the length of the wiring GL electrically connecting the gate driver circuit and the pixel circuit becomes one eighth. Accordingly, each of the resistance value and parasitic capacitance of the wiring GL becomes one eighth, whereby degradation and delay of a signal can be reduced and the time for rewriting image data can be easily ensured.

With the display apparatus 90B of one embodiment of the present invention, sufficient time for writing image data can be easily ensured, and thus high-speed rewriting of a display image can be achieved. Thus, a display apparatus with high display quality can be provided. In particular, a display apparatus that excels in displaying a moving image can be provided.

Here, a mode is described in which the display apparatus 90 of one embodiment of the present invention is employed for a thin client. In recent years, the thin client in which main arithmetic processing is performed on a server and limited processing is performed on a client side has been attracting attentions. As a thin client execution method, a network boot method, a server base method, a blade PC method, a virtual desktop (VDI) method, and the like are proposed.

In any of the methods, a large amount of data is transmitted from a server to a client in a thin client, so that power consumption at the time of transmitting data is increased. With the use of an electronic device including the display apparatus 90 of one embodiment of the present invention as a client, power saving during data transmission can be achieved.

The display apparatus 90B according to one embodiment of the present invention is described as the example in which the display portion 93 is divided into the 32 sub-display portions 95. However, the division number of the display portion 93 of one embodiment of the present invention may be 16, 64, 128, or the like, without limitation to 32. As the division number of the display portion 93 increases, a reduction in practical display quality perceived by the user can be smaller.

At least part of the structure examples, the drawings corresponding thereto, and the like described as an example in this embodiment can be combined with any of the other structure examples, the other drawings, and the like as appropriate.

### Embodiment 6

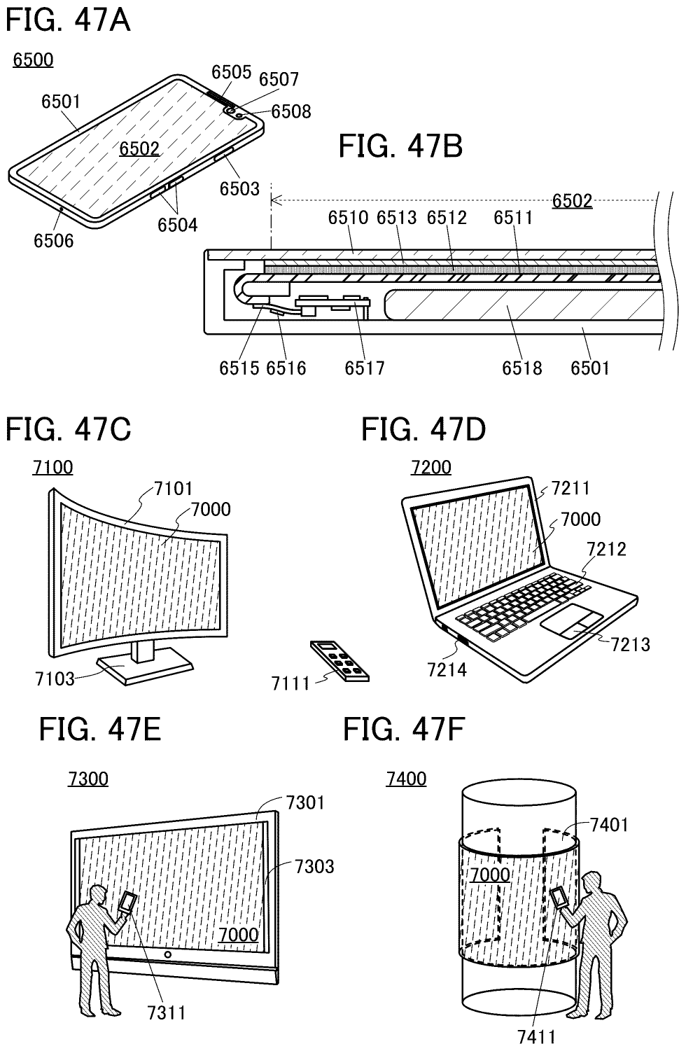

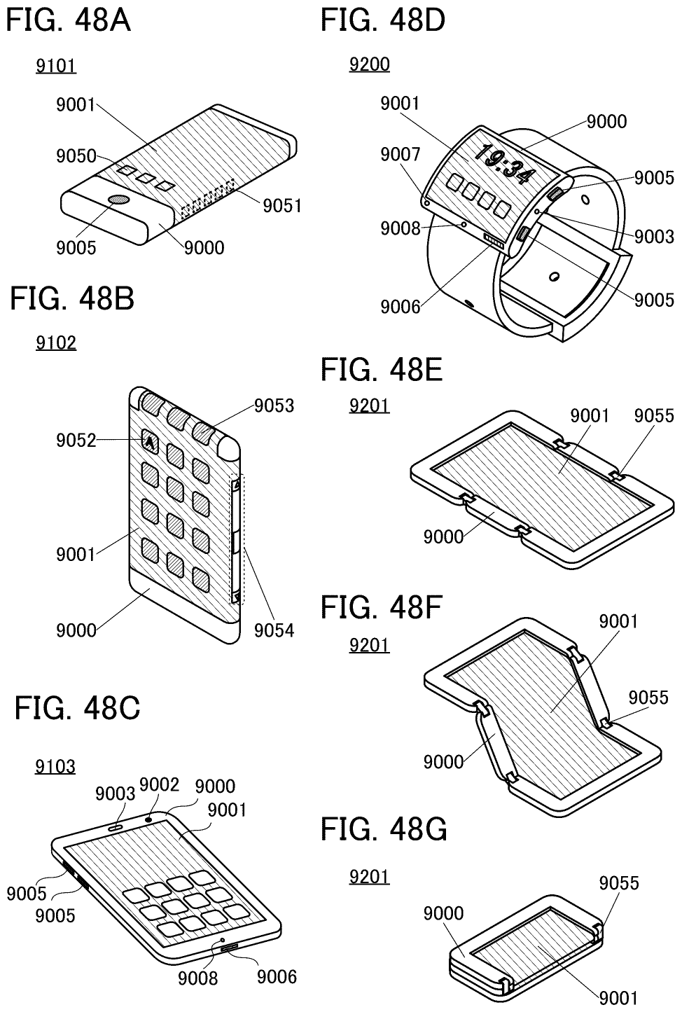

In this embodiment, electronic devices of embodiments of the present invention will be described with reference to FIG. 47 and FIG. 48.

Electronic devices of this embodiment each include the display apparatus of one embodiment of the present invention in a display portion. The display apparatus of one embodiment of the present invention can be easily increased in definition and resolution. Thus, the display apparatus of one embodiment of the present invention can be used for a display portion of a variety of electronic devices.

The semiconductor device of one embodiment of the present invention can also be applied to any other portion of an electronic device than a display portion. For example, the semiconductor device of one embodiment of the present invention is preferably used for a control portion or the like of an electronic device, leading to lower power consumption.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display apparatus of one embodiment of the present invention can have higher definition, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The resolution of the display apparatus of one embodiment of the present invention is preferably as high as HD (number of pixels: 1280× 720), FHD (number of pixels: 1920×1080), WQHD (number of pixels: 2560×1440), WQXGA (number of pixels: 2560× 1600), 4K (number of pixels: 3840× 2160), or 8K (number of pixels: 7680× 4320). In particular, the resolution is preferably 4K, 8K, or higher. The pixel density (definition) of the display apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display apparatus having one or both of such high resolution and high definition can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data recorded in a recording medium.

An electronic device 6500 illustrated in FIG. 47A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 47B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be provided. Since the display panel 6511 is extremely thin, the battery 6518 with high capacity can be mounted while an increase in thickness of the electronic device is inhibited. Moreover, part of the display panel 6511 is folded back so that a connection portion with the FPC 6515 is provided on the back side of a pixel portion, whereby an electronic device with a narrow bezel can be provided.

FIG. 47C illustrates an example of a television device. In a television device 7100, a display portion 7000 is incorporated in a housing 7101. Here, a structure in which the housing 7101 is supported by a stand 7103 is illustrated.

The display apparatus of one embodiment of the present invention can be used for the display portion 7000.

Operation of the television device 7100 illustrated in FIG. 47C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may include a display portion for displaying information output from the remote controller 7111. With operation keys or a touch panel provided in the remote controller 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 47D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 47E and FIG. 47F illustrate examples of digital signage.

Digital signage 7300 illustrated in FIG. 47E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 47F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in FIG. 47E and FIG. 47F.

A larger area of the display portion 7000 can increase the amount of information that can be provided at a time. The larger display portion 7000 attracts more attentions, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 47E and FIG. 47F, it is preferable that the digital signage 7300 or the digital signage 7400 can work with an information terminal 7311 or an information terminal 7411, like a user's smartphone, through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). In this way, an unspecified number of users can join in and enjoy the game concurrently.

Electronic devices illustrated in FIG. 48A to FIG. 48G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display apparatus of one embodiment of the present invention can be used for the display portion 9001 in FIG. 48A to FIG. 48G.

The electronic devices illustrated in FIG. 48A to FIG. 48G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data recorded in a recording medium. Note that the functions of the electronic devices are not limited to the above-described functions, and the electronic devices can have a variety of functions. The electronic devices may each include a plurality of display portions. The electronic devices may each be provided with a camera or the like and have a function of taking a still image or a moving image and storing the taken image in a recording medium (an external recording medium or a recording medium incorporated in the camera), a function of displaying the taken image on the display portion, or the like.

The electronic devices illustrated in FIG. 48A to FIG. 48G are described in detail below.

FIG. 48A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 48A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 48B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 48C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 48D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 48E to FIG. 48G are perspective views illustrating a foldable portable information terminal 9201. FIG. 48E is a perspective view of an opened state of the portable information terminal 9201, FIG. 48G is a perspective view of a folded state thereof, and FIG. 48F is a perspective view of a state in the middle of change from one of FIG. 48E and FIG. 48G to the other. The portable information terminal 9201 is highly portable in the folded state and is highly browsable in the opened state with a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate.

### Embodiment 7

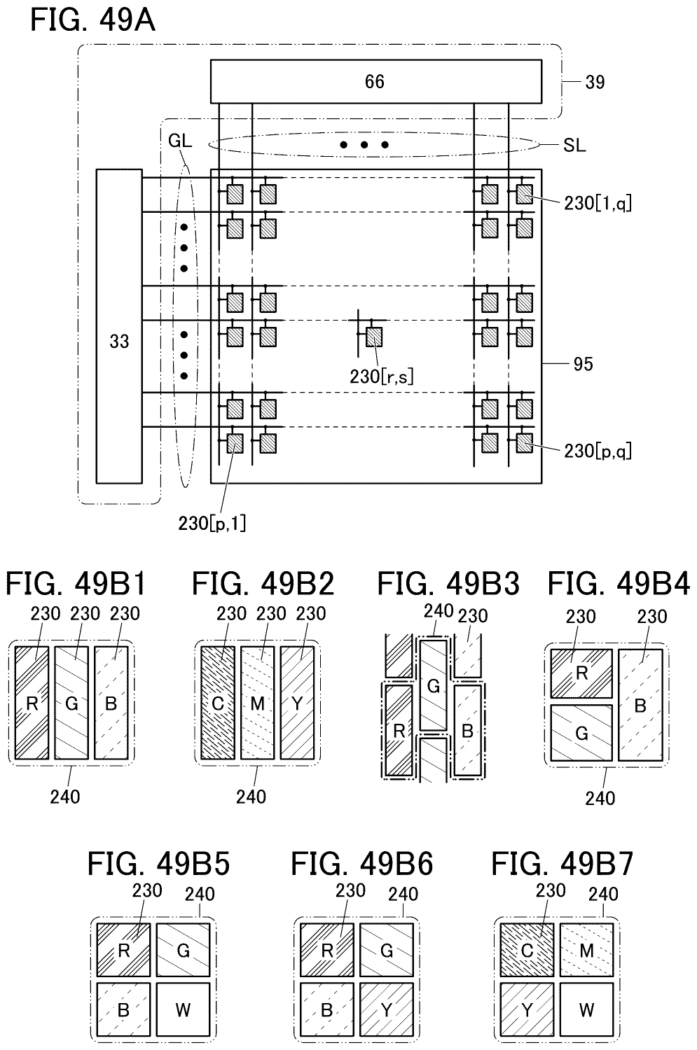

In this embodiment, a structure example of the sub-display portion 95 including the plurality of pixels 230 arranged in a matrix of p rows and q columns (p and q are each an integer greater than or equal to 2) will be described. FIG. 49A is a block diagram illustrating the sub-display portion 95. The sub-display portion 95 is electrically connected to the source driver circuit 66 and the gate driver circuit 33 which are provided in the section 39.

In FIG. 49A, the pixel 230 in the p-th row and the first column is denoted as a pixel 230 [p,1], the pixel 230 in the first row and the q-th column is denoted as a pixel 230 [1,q], and the pixel 230 in the p-th row and the q-th column is denoted as a pixel 230 [p,q].

A circuit included in the gate driver circuit 33 functions as, for example, a scan line driver circuit. A circuit included in the source driver circuit 66 functions as, for example, a signal line driver circuit.

For example, OS transistors may be used as the transistors included in the pixels 230 and Si transistors may be used as the transistors included in a driver circuit. The off-state current of an OS transistor is low, so that power consumption can be reduced. Since a Si transistor has a higher operation speed than an OS transistor, a Si transistor is suitably used in a driver circuit. The display apparatus may include OS transistors as both the transistors included in the pixels 230 and the transistors included in a driver circuit. The display apparatus may include Si transistors as both the transistors included in the pixels 230 and the transistors included in a driver circuit. Alternatively, the display apparatus may include Si transistors as the transistors included in the pixels 230 and OS transistors as the transistors included in a driver circuit.

Both a Si transistor and an OS transistor may be used as the transistors included in the pixels 230. Both a Si transistor and an OS transistor may be used as the transistors included in a driver circuit.

In FIG. 49A, p wirings GL are arranged substantially parallel to each other and the potentials thereof are controlled by the gate driver circuit 33, and q wirings SL are arranged substantially parallel to each other and the potentials thereof are controlled by the source driver circuit 66. For example, the pixels 230 arranged in the r-th row (r represents a given number and is an integer greater than or equal to 1 and less than or equal to p in this embodiment and the like) are electrically connected to the gate driver circuit 33 through the wiring GL of the r-th row. The pixels 230 arranged in the s-th column (s represents a given number and is an integer greater than or equal to 1 and less than or equal to q in this embodiment and the like) are electrically connected to the source driver circuit 66 through the wiring SL of the s-th column. In FIG. 49A, the pixel 230 in the r-th row and the s-th column is denoted as a pixel 230 [r,s].

Note that the number of the wirings GL electrically connected to the pixels 230 included in one row is not limited to one. Furthermore, the number of the wirings SL electrically connected to the pixels 230 included in one column is not limited to one. The wiring GL and the wiring SL are examples, and wirings connected to the pixels 230 are not limited to the wiring GL and the wiring SL.

The pixel 230 that controls red light, the pixel 230 that controls green light, and the pixel 230 that controls blue light are arranged in a stripe manner, collectively serve as one pixel 240, and the amount of light emission (emission luminance) from each of the pixels 230 is controlled, so that full color display is performed. In other words, each of the three pixels 230 functions as a subpixel. That is, three subpixels control the emission amount or the like of red light, green light, and blue light (see FIG. 49B1). Note that the colors of light controlled by the three subpixels are not limited to a combination of red (R), green (G), and blue (B) and may be cyan (C), magenta (M), and yellow (Y) (see FIG. 49B2).

By using the pixels 240 arranged in a matrix of 1920×1080, the display portion 93 can perform full-color display with a so-called 2K resolution. For example, by using the pixels 240 arranged in a matrix of 3840× 2160, the display portion 93 can perform full-color display with a so-called 4K resolution. For example, by using the pixels 240 arranged in a matrix of 7680×4320, the display portion 93 can perform full-color display with a so-called 8K resolution. By increasing the number of pixels 240, the display portion 93 that can perform full-color display with 16K or 32K resolution can also be provided.

Alternatively, three pixels 230 constituting one pixel 240 may be arranged in a delta arrangement (see FIG. 49B3). Specifically, three pixels 230 constituting one pixel 240 may be arranged such that the lines connecting the center points of the three pixels 230 form a triangle. Note that the arrangement of the pixels 230 is not limited to a stripe arrangement and a delta arrangement. The pixels 230 may be arranged in a zigzag arrangement, an S-stripe arrangement, a Bayer arrangement, or a PenTile arrangement.

The three subpixels (pixels 230) do not necessarily have the same area. In the case where the emission efficiency, reliability, and the like vary depending on emission colors, the subpixel area may be changed depending on the emission color (see FIG. 49B4).

Four subpixels may collectively function as one pixel. For example, a subpixel that controls white light may be added to the three subpixels that control red light, green light, and blue light (see FIG. 49B5). The addition of the subpixel that controls white light can increase the luminance of a display region. Alternatively, a subpixel that controls yellow light may be added to the three subpixels that control red light, green light, and blue light (see FIG. 49B6). Further alternatively, a subpixel that controls white light may be added to the three subpixels that control cyan light, magenta light, and yellow light (see FIG. 49B7).

When the number of subpixels functioning as one pixel is increased and subpixels that control light of red, green, blue, cyan, magenta, yellow, and the like are used in an appropriate combination, the reproducibility of halftones can be increased. Thus, display quality can be improved.

The display apparatus of one embodiment of the present invention can reproduce the color gamut of various standards. For example, the display apparatus of one embodiment of the present invention can reproduce the color gamut of the PAL (Phase Alternating Line) standard and the NTSC (National Television System Committee) standard for TV broadcasting; the sRGB (standard RGB) standard and the Adobe RGB standard widely used for display apparatuses used in electronic devices such as personal computers, digital cameras, and printers; the ITU-R BT.709 (International Telecommunication Union Radiocommunication Sector Broadcasting Service (Television) 709) standard for HDTV (High Definition Television, also referred to as Hi-Vision); the DCI-P3 (Digital Cinema Initiatives P3) standard for digital cinema projection; the ITU-R BT.2020 (REC.2020 (Recommendation 2020)) standard for UHDTV (Ultra High Definition Television, also referred to as Super Hi-Vision); and the like.

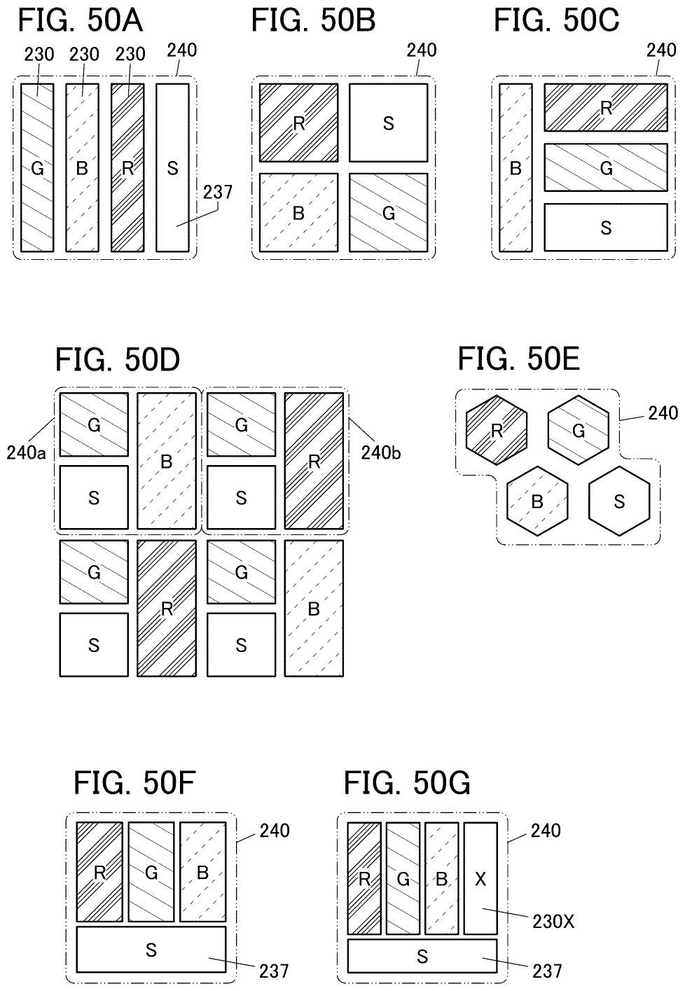

A pixel 237 including a light-receiving element in one pixel 240 may be provided. In the pixel 240 illustrated in FIG. 50A, a pixel 230(G) exhibiting green light, a pixel 230(B) exhibiting blue light, a pixel 230(R) exhibiting red light, and a pixel 237(S) including a light-receiving element are arranged in a stripe pattern. Note that in this specification and the like, the pixel 237 is also referred to as an “imaging pixel”.

A light-receiving element included in the pixel 237 is preferably an element that detects visible light and is further preferably an element that detects one or more of blue light, violet light, bluish violet light, green light, yellowish green light, yellow light, orange light, red light, and the like. The light-receiving element included in the pixel 237 may be an element that detects infrared light.

The pixel 240 illustrated in FIG. 50A employs a stripe arrangement. In the case where the pixel 237 including a light-receiving element detects light of a specific color, the pixel 230 exhibiting light of the color is preferably disposed to be adjacent to the pixel 237, whereby detection accuracy can be increased.

Three pixels 230 and one pixel 237 are arranged in a matrix in the pixel 240 illustrated in FIG. 50B. Although FIG. 50B illustrates an example in which the pixel 230 exhibiting red light is adjacent to the pixel 237 including a light-receiving element in the row direction and the pixel 230 exhibiting blue light is adjacent to the pixel 230 exhibiting green light in the row direction, one embodiment of the present invention is not limited to the example.

The pixel 240 illustrated in FIG. 50C has a structure in which the pixel 237 is added to an S-stripe arrangement. The pixel 240 in FIG. 50C includes one vertically oriented pixel 230, two horizontally oriented pixels 230, and one horizontally oriented pixel 237. Note that the vertically oriented pixel 230 may be any one of R, G, and S, and there is no limitation on the arrangement order of the horizontally oriented subpixels.

FIG. 50D illustrates an example in which a pixel 240a and a pixel 240b are alternately arranged. The pixel 240a includes the pixel 230 exhibiting blue light, the pixel 230 exhibiting green light, and the pixel 237 including a light-receiving element. The pixel 240b includes the pixel 230 exhibiting red light, the pixel 230 exhibiting green light, and the pixel 237 including a light-receiving element. The pixel 240a and the pixel 240b function as one pixel 240. Although FIG. 50D illustrates the pixel 240a and the pixel 240b each including the pixel 230 exhibiting green light and the pixel 237, one embodiment of the present invention is not limited thereto. When the pixel 240a and the pixel 240b each include the pixel 237, the definition of pixels for imaging can be increased.

The layout illustrated in FIG. 50E is preferable because the aperture ratio of each subpixel can be increased. In FIG. 50F, an example in which the top surface shapes of the pixels 230 and the pixel 237 are hexagonal is illustrated.

The pixel 240 illustrated in FIG. 50F is an example in which the pixels 230 are arranged horizontally in one line and the pixel 237 is placed beneath the pixels 230.

The pixel 240 illustrated in FIG. 50G is an example in which the pixels 230 and a pixel 230X are arranged horizontally in one line and the pixel 237 is placed beneath the pixels 230 and the pixel 230X.

As the pixel 230X, for example, the pixel 230 that exhibits infrared light (IR) can be used. That is, the pixel 230X includes the light-emitting device 61 that emits infrared light (IR). In that case, the pixel 237 preferably includes a light-receiving element that detects infrared light. For example, while an image is displayed by the pixel 230 emitting visible light, the pixel 237 can detect reflected light of infrared light emitted from a subpixel X.

A plurality of pixels 237 may be provided in one pixel 240. In that case, light detected by the plurality of pixels 237 may have the same wavelength range or different wavelength ranges. For example, part of the plurality of pixels 237 may detect visible light and another part may detect infrared light.

The pixel 237 is not needed to be provided in all the pixels 240. The pixel 240 including the pixel 237 may be provided for every certain number of pixels.

By using the pixel 237 or using the pixel 237 and the sensor 97 described above, for example, information for personal authentication using a fingerprint, a palm print, an iris, a retina, a shape of a blood vessel (including the shape of a vein and a shape of an artery), face, or the like can be detected. Furthermore, by using the pixel 237 or using the pixel 237 and the sensor 97, the number of blinks, eyelid behavior, pupil size, body temperature, pulse, oxygen saturation in blood, or the like of the user may be measured, so that the user's fatigue level, health condition, and the like can be detected.

The electronic device can be operated using the motion of gaze, the number of blinks, the rhythm of blinks, and the like of the user. Specifically, by using the pixel 237 or using the pixel 237 and the sensor 97, information on the motion of gaze, the number of blinks, the rhythm of blinks, and the like of the user are detected, and one or more combinations of these information may be used as an operation signal of the electronic device. For example, it is possible to use a blink as a clicking of a mouse. When the motion of a gaze and a blink are detected, the user can perform an input operation of the electronic device with holding nothing in his/her hand. Thus, the operability of the electronic device can be improved.

When a plurality of imaging pixels (the pixels 237) are provided in the display apparatus 90 of the glasses-type electronic device 150 described in Embodiment 5, the plurality of imaging pixels can be used as the gaze detection portion 84. Thus, the number of components of the electronic device can be reduced. Accordingly, improvement in productivity, reductions in weight and costs, and the like of the electronic device can be achieved.

### Structure Example of Light-Emitting Device

The light-emitting device 61 that can be used in the display apparatus according to one embodiment of the present invention will be described.

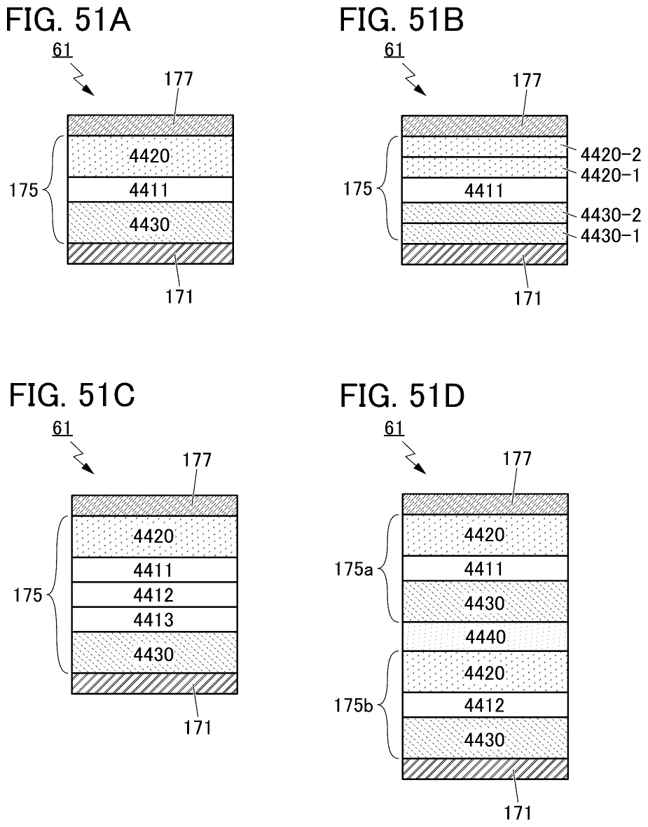

As illustrated in FIG. 51A, the light-emitting device 61 includes an EL layer 175 between a pair of electrodes (a conductive layer 171 and a conductive layer 177). The EL layer 175 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which are provided between the pair of electrodes, can function as a single light-emitting unit, and the structure in FIG. 51A is referred to as a single structure in this specification and the like.

FIG. 51B illustrates a modification example of the EL layer 175 included in the light-emitting device 61 illustrated in FIG. 51A. Specifically, the light-emitting device 61 illustrated in FIG. 51B includes a layer 4430-1 over the conductive layer 171, a layer 4430-2 over the layer 4430-1, the light-emitting layer 4411 over the layer 4430-2, a layer 4420-1 over the light-emitting layer 4411, a layer 4420-2 over the layer 4420-1, and the conductive layer 177 over the layer 4420-2. In the case where the conductive layer 171 is an anode and the conductive layer 177 is a cathode, for example, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, in the case where the conductive layer 171 is a cathode and the conductive layer 177 is an anode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layered structure, carriers can be efficiently injected to the light-emitting layer 4411, and the efficiency of the recombination of carriers in the light-emitting layer 4411 can be enhanced.

Note that the structure in which a plurality of light-emitting layers (the light-emitting layer 4411, a light-emitting layer 4412, and a light-emitting layer 4413) are provided between the layer 4420 and the layer 4430 as illustrated in FIG. 51C is also an example of the single structure.

The structure in which a plurality of light-emitting units (an EL layer 175a and an EL layer 175b) are connected in series with an intermediate layer (charge-generation layer) 4440 therebetween as illustrated in FIG. 51D is referred to as a tandem structure or a stack structure in this specification and the like. The tandem structure enables a light-emitting device capable of high luminance light emission.

In the case where the light-emitting device 61 has the tandem structure illustrated in FIG. 51D, the EL layer 175a and the EL layer 175b may emit light of the same color. For example, the EL layer 175a and the EL layer 175b may both emit green light.

Note that full-color display can be performed by using the light-emitting device 61 emitting red light (R), the light-emitting device 61 emitting green light (G), and the light-emitting device 61 emitting blue light (B) as subpixels and constituting one pixel with these three subpixels. In the case where the display portion 93 includes three kinds of subpixels of R, G, and B, each light-emitting device may have a tandem structure. Specifically, the EL layer 175a and the EL layer 175b in the subpixel of R each contain a material capable of emitting red light, the EL layer 175a and the EL layer 175b in the subpixel of G each contain a material capable of emitting green light, and the EL layer 175a and the EL layer 175b in the subpixel of B each contain a material capable of emitting blue light. In other words, the light-emitting layer 4411 and the light-emitting layer 4412 may contain the same material. When the EL layer 175a and the EL layer 175b emit light of the same color, the current density per unit emission luminance can be reduced. Thus, the reliability of the light-emitting device 61 can be increased.

The emission color of the light-emitting device can be red, green, blue, cyan, magenta, yellow, white, or the like depending on the material that constitutes the EL layer 175. Furthermore, the color purity can be further increased when the light-emitting device has a microcavity structure.

The light-emitting layer may contain two or more light-emitting substances that emit light of red (R), green (G), blue (B), yellow (Y), orange (O), or the like. The light-emitting device that emits white light preferably contains two or more kinds of light-emitting substances in the light-emitting layer. To obtain white light emission, two or more light-emitting substances are selected such that their emission colors mixed to be white. For example, when the emission color of a first light-emitting layer and the emission color of a second light-emitting layer have a relationship of complementary colors, it is possible to obtain a light-emitting device which emits white light as a whole. The same applies to a light-emitting device including three or more light-emitting layers.

The light-emitting layer preferably contains two or more light-emitting substances that emit light of R (red), G (green), B (blue), Y (yellow), O (orange), or the like. Alternatively, the light-emitting layer preferably contains two or more light-emitting substances that each emit light containing two or more of spectral components of R, G, and B. In addition, as the light-emitting substance, a substance that emits near-infrared light can be used.

Examples of a light-emitting substance include a substance that emits fluorescent light (a fluorescent material), a substance that emits phosphorescent light (a phosphorescent material), and a substance that exhibits thermally activated delayed fluorescence (a thermally activated delayed fluorescence (TADF) material). As a light-emitting substance, not only organic compounds but also inorganic compounds (e.g., quantum dot materials) can be used.

At least part of the structure examples, the drawings corresponding thereto, and the like described in this embodiment can be combined with the other structure examples, the other drawings corresponding thereto, and the like as appropriate.

[Reference Numerals]

ANO: wiring, BSL: bus wiring, BW: bus wiring, C31: capacitor, C41: capacitor, GL: wiring, INV:
inverter circuit, LAT: latch circuit, LIN: terminal, MPG: conductive layer, MTCK: transistor,
ROUT: terminal, SL: wiring, SMP: terminal, SNCL: wiring, Tr31: transistor, Tr33: transistor,
Tr35: transistor, Tr36: transistor, Tr41: transistor, Tr43: transistor, Tr45: transistor, Tr47:
transistor, VCOM: wiring, 10A: semiconductor device, 10B: semiconductor device, 10:
semiconductor device, 20A: transistor, 20a: transistor, 20B: transistor, 20b: transistor, 20:
transistor, 21a: semiconductor layer, 21b: semiconductor layer, 21: semiconductor layer, 22: gate
insulating layer, 23: gate electrode, 24a: source electrode, 24b: drain electrode, 26a: extending
portion, 26b: extending portion, 26c: extending portion, 28a: bent portion, 28b: bent portion, 29A:
first section, 29B: second section, 29C: third section, 30: opening, 31: insulating layer, 32:
insulating layer, 33: gate driver circuit, 34: level shifter, 35: amplifier circuit, 36: inspection circuit,
37: video generation circuit, 38: video distribution circuit, 39: section, 40: functional circuit, 41:
memory device, 42a: color irregularity correction, 42b: upconversion, 42: GPU, 43: EL correction
circuit, 44: timing controller, 45: CPU, 46: sensor controller, 47: power supply circuit, 48:
temperature sensor, 49: luminance correction circuit, 50A: display apparatus, 50B: display
apparatus, 51A: pixel circuit, 51B: pixel circuit, 51C: pixel circuit, 51D: pixel circuit, 51E: pixel
circuit, 51F: pixel circuit, 51G: pixel circuit, 51H: pixel circuit, 51: pixel circuit, 52A: transistor,
52B: transistor, 52C: transistor, 52D: transistor, 52: transistor, 53A: capacitor, 53: capacitor, 54:
channel formation region, 55: pixel circuit group, 59: section, 61: light-emitting device, 62: layer,
63: transistor, 64: channel formation region, 65: driver circuit, 66: source driver circuit, 67:
digital-analog converter circuit, 71: element layer, 73: element layer, 75: element layer, 77: wiring
layer, 80: input/output circuit, 81: layer, 83: layer, 84: gaze detection portion, 85: communication
portion, 86: wearing portion, 87: cushion, 88: lenses, 89: output terminal, 90_L: display apparatus,
90_R: display apparatus, 90A: display apparatus, 90B: display apparatus, 90: display apparatus,
91: substrate, 92: substrate, 93: display portion, 94: terminal portion, 95: sub-display portion, 97:
sensor, 99A: earphones, 99B: earphones, 100A: transistor, 100B: transistor, 100: transistor, 101:
motion detection portion, 102: substrate, 103: arithmetic portion, 104: conductive layer, 105:
housing, 106: insulating layer, 107: adhesive layer, 108f: metal oxide film, 108: semiconductor
layer, 109: input terminal, 110a: insulating layer, 110af: insulating film, 110b: insulating layer,
110b1: insulating layer, 110bf: insulating film, 110c: insulating layer, 110cf: insulating film, 110:
insulating layer, 111: pixel electrode, 112A: conductive layer, 112a: conductive layer, 112b:
conductive layer, 112bf: conductive film, 113a: first layer, 113b: second layer, 113c: third layer,
114: common layer, 115: common electrode, 116: conductive layer, 118a: mask layer, 119:
substrate, 121: insulating layer, 123: insulating layer, 125: insulating layer, 126a: conductive layer,
126b: conductive layer, 126c: conductive layer, 127: insulating layer, 128: layer, 129a: conductive
layer, 129b: conductive layer, 129c: conductive layer, 130B: light-emitting device, 130G: light-
emitting device, 130R: light-emitting device, 130: light-emitting device, 131: protective layer,
137: metal oxide layer, 139: film, 140: connection portion, 141: opening, 143: opening, 145:
opening, 146a: extending portion, 146b: extending portion, 146c: extending portion, 146: opening,
147f: insulating film, 147: insulating layer, 148a: bent portion, 148b: bent portion, 149f: insulating
film, 149: insulating layer, 150: electronic device, 151: substrate, 152: substrate, 157: resist mask,
159a: resist mask, 159b: resist mask, 159: resist mask, 162: display portion, 164: circuit portion,
165: conductive layer, 171: conductive layer, 172: FPC, 173: IC, 175a: EL layer, 175b: EL layer,
175: EL layer, 177: conductive layer, 182a: conductive layer, 182b: conductive layer, 182c:
conductive layer, 195: insulating layer, 200A: transistor, 200B: transistor, 200C: transistor, 200D:
transistor, 200E: transistor, 200: transistor, 204: conductive layer, 208A: semiconductor layer,
208: semiconductor layer, 210: pixel, 212a: conductive layer, 212b: conductive layer, 216:
conductive layer, 230B: pixel, 230G: pixel, 230R: pixel, 230X: pixel, 230: pixel, 231: first driver
circuit portion, 232: second driver circuit portion, 233: insulating layer, 234: conductive layer,
235: insulating layer, 236: wiring, 237: pixel, 238: wiring, 240a: pixel, 240b: pixel, 240: pixel,
247: insulating layer, 249: insulating layer, 300: transistor, 310: substrate, 312: element isolation
layer, 313: semiconductor region, 314a: low-resistance region, 314b: low-resistance region, 315:
insulating layer, 316: conductive layer, 317: insulating layer, 320: insulating layer, 322: insulating
layer, 324: insulating layer, 326: insulating layer, 328: conductive layer, 330: conductive layer,
350: insulating layer, 352: insulating layer, 354: insulating layer, 356: conductive layer, 441:
timing controller, 442: input/output circuit, 500: display module, 501: printed wiring board, 502:
terminal portion, 503: wire, 504: FPC, 505: connection portion, 512: insulating layer, 514:
conductive layer, 574: insulating layer, 581: insulating layer, 592: insulating layer, 594: insulating
layer, 596: conductive layer, 598: insulating layer, 599: insulating layer, 4411: light-emitting layer,
4412: light-emitting layer, 4413: light-emitting layer, 4420: layer, 4430: layer, 6500: electronic
device, 6501: housing, 6502: display portion, 6503: power button, 6504: button, 6505: speaker,
6506: microphone, 6507: camera, 6508: light source, 6510: protection member, 6511: display
panel, 6512: optical member, 6513: touch sensor panel, 6515: FPC, 6516: IC, 6517: printed circuit
board, 6518: battery, 7000: display portion, 7100: television device, 7101: housing, 7103: stand,
7111: remote controller, 7200: laptop personal computer, 7211: housing, 7212: keyboard, 7213:
pointing device, 7214: external connection port, 7300: digital signage, 7301: housing, 7303:
speaker, 7311: information terminal, 7400: digital signage, 7401: pillar, 7411: information
terminal, 9000: housing, 9001: display portion, 9002: camera, 9003: speaker, 9005: operation key,
9006: connection terminal, 9007: sensor, 9008: microphone, 9050: icon, 9051: information, 9052:
information, 9053: information, 9054: information, 9055: hinge, 9101: portable information
terminal, 9102: portable information terminal, 9103: tablet terminal, 9200: portable information
terminal, 9201: portable information terminal

1. A semiconductor device comprising:
a first insulating layer;
a second insulating layer over the first insulating layer; and
a transistor over the first insulating layer,
wherein the transistor comprises:
a source electrode over the second insulating layer;
a drain electrode over the second insulating layer;
a semiconductor layer;
a gate insulating layer over the source electrode, the drain electrode and the semiconductor layer; and
a first gate electrode over the gate insulating layer,
wherein the second insulating layer comprises an opening reaching the first insulating layer,
wherein the semiconductor layer is in contact with a side surface of the second insulating layer in the opening, a side surface of the source electrode, and a side surface of the drain electrode,
wherein the first gate electrode overlaps with the opening layer, and
wherein the gate insulating layer is in contact with the first insulating layer in a bottom portion of the opening.

2. A semiconductor device comprising:
a first insulating layer;
a second insulating layer over the first insulating layer; and
a transistor over the first insulating layer,
wherein the transistor comprises:
a source electrode over the second insulating layer;
a drain electrode over the second insulating layer;
a semiconductor layer;
a gate insulating layer over the source electrode, the drain electrode and the semiconductor layer; and
a first gate electrode over the gate insulating layer,
wherein the second insulating layer comprises an opening reaching the first insulating layer,
wherein the semiconductor layer comprises:
a first region in contact with a side surface of the second insulating layer;
a second region in contact with a side surface of the source electrode; and
a third region in contact with a side surface of the drain electrode in the opening,
wherein the first region is between the second region and the third region,
wherein the first gate electrode overlaps with the opening layer, and
wherein the gate insulating layer is in contact with the first insulating layer in a bottom portion of the opening.

3. (canceled)

4. The semiconductor device according to claim 1, wherein the semiconductor layer is in contact with one or both of a top surface of the source electrode and a top surface of the drain electrode.

5. (canceled)

6. The semiconductor device according to claim 1, wherein the semiconductor layer is in contact with a top surface of the second insulating layer.

7. The semiconductor device according to claim 1,
wherein the transistor further comprises a second gate electrode,
wherein the second gate electrode is covered with the second insulating layer, and
wherein a part of the second insulating layer is between a side surface of the second gate electrode and the semiconductor layer.

8. The semiconductor device according to claim 7, wherein a third insulating layer is between the first insulating layer and the second gate electrode.

9. The semiconductor device according to claim 1, wherein a contour shape of the opening is any of a circular shape, an elliptical shape, a quadrangular shape with rounded corners, a regular polygonal shape, a polygonal shape other than the regular polygonal shape, a concave polygonal shape, a polygonal shape with rounded corners, and a closed curve in which a straight line and a curve are combined.

10. The semiconductor device according to claim 1,
wherein the opening comprises a plurality of extending portions and at least one or more bent portions,
wherein each of the plurality of extending portions has a shape extending in one direction in a top view, and
wherein one of the plurality of extending portions and another of the plurality of extending portions are connected to each other through any of at least one or more of the bent portions.

11. A semiconductor device comprising:
a first insulating layer;
a second insulating layer over the first insulating layer;
a first transistor over the first insulating layer; and
a second transistor over the first insulating layer,
wherein the first transistor comprises:
a first source electrode over the second insulating layer;
a first drain electrode over the second insulating layer;
a first semiconductor layer;
a gate insulating layer over the first source electrode, the first drain electrode and the first semiconductor layer; and
a first gate electrode over the gate insulating layer,
wherein the second insulating layer comprises a first opening reaching the first insulating layer,
wherein the first semiconductor layer is in contact with a side surface of the second insulating layer in the first opening, a top surface of the first insulating layer in the first opening, a side surface of the first source electrode, and a side surface of the first drain electrode,
wherein the first gate electrode overlaps with the first opening,
wherein the second transistor comprises:
a second source electrode;
a second drain electrode;
a second semiconductor layer;
the gate insulating layer over the second source electrode, the second drain electrode and the second semiconductor layer; and
a second gate electrode over the gate insulating layer,
wherein the second source electrode and the second drain electrode are positioned at different levels,
wherein the second insulating layer comprises a second opening reaching one of the second source electrode and the second drain electrode,
wherein the other of the second source electrode and the second drain electrode is provided over the second insulating layer,
wherein the second semiconductor layer is in contact with a side surface of the second insulating layer in the second opening, a top surface of one of the second source electrode and the second drain electrode, and a side surface of the other of the second source electrode and the second drain electrode, and
wherein the second gate electrode overlaps with the second opening.

12. The semiconductor device according to claim 11, wherein the first semiconductor layer is in contact with one or both of a top surface of the first source electrode and a top surface of the first drain electrode.

13. The semiconductor device according to claim 11, wherein the gate insulating layer is in contact with the first insulating layer in a bottom portion of the first opening.

14. The semiconductor device according to claim 11, wherein the first semiconductor layer is in contact with a top surface of the second insulating layer.

15. The semiconductor device according to claim 11, wherein a contour shape of the first opening is any of a circular shape, an elliptical shape, a quadrangular shape with rounded corners, a regular polygonal shape, a polygonal shape other than the regular polygonal shape, a concave polygonal shape, a polygonal shape with rounded corners, and a closed curve in which a straight line and a curve are combined.

16. The semiconductor device according to claim 11,
wherein the first opening comprises a plurality of extending portions and at least one or more bent portions,
wherein each of the plurality of extending portions has a shape extending in one direction in a top view, and
wherein one of the plurality of extending portions and another of the plurality of extending portions are connected to each other through any of the at least one or more bent portions.

17. The semiconductor device according to claim 1, wherein the semiconductor layer is in contact with a top surface of the first insulating layer in the opening.
